(19) United States
(12) Patent Application Publication
(10) Pub. No.: US 2015/0140211 A1
(43) Pub. Date: May 21, 2015

(54) Scalable 2D-Film CVD Synthesis

(71) Applicant: CVD Equipment Corporation, Central Islip, NY (US)

(72) Inventors: Karlheinz Strobl, Mount Sinai, NY (US); Leonard Rosenbaum, Greenport, NY (US)

(21) Appl. No.: 14/547,362

(22) Filed: Nov. 19, 2014

Related U.S. Application Data
(60) Provisional application No. 61/921,633, filed on Dec. 30, 2013.
(60) Provisional application No. 61/906,405, filed on Nov. 19, 2013.

(51) Int. Cl. C01B 31/04; C23C 16/458; C23C 16/455; C23C 16/46

(52) U.S. Cl. CPC C01B 31/0453; C23C 16/46; C23C 16/463; C23C 16/4583; C23C 16/455
USPC 427/249.6; 118/725; 427/255.28

(57) ABSTRACT

This patent relates to 1) primary tool designs for a chemical vapor deposition (CVD) synthesis system in the form of open tray stacks or more readily accessible, quasi-gas-tight enclosure boxes, to 2) system designs for low volume and high volume CVD graphene production, and to 3) methods for CVD graphene and other two-dimensional (2D) film CVD synthesis. Scaling of higher quality CVD 2D-film production is thereby enabled both in substrate size and productivity and at reduced costs. This invention provides a wider process window for CVD Synthesis of 2D films and, particularly of graphene films, thereby allowing increased film quality and/or production throughput.

This application claims the benefit of U.S. Provisional Application No. 61/921,633, filed on Dec. 30, 2013, and U.S. Provisional Application No. 61/906,405, filed on Nov. 19, 2013.

### BACKGROUND OF THE INVENTION

The present invention relates to tooling and system designs for chemical vapor deposition (CVD) systems and CVD synthesis process steps used to synthesize a few atom thick films utilizing growth substrates and, more particularly, to scalable CVD synthesis of graphene and other two-dimensional films.

Those skilled in the art will recognize that there is an on-going interest in the large scale production of uniform, high quality few atom thick films, such as graphene. One current technique for manufacturing graphene and other equivalent few atom thick 2-dimensional films involves synthesizing such films on a catalytically-active growth substrate via the CVD of hydrocarbons (HCs) or other respective precursors.

Copper (Cu) is a preferred substrate material because it is commercially available at low costs in various forms (foil, sheet, bulk), and is easily etched and/or separated from the graphene film by electrolytic means, thus allowing the graphene film to be harvested and transferred to another support material. Moreover, the very low carbon solvability of copper facilitates the manufacture of substantially mono-layer graphene films having properties which are superior to the properties seen in chemically-exfoliated graphene, and which can approach the electrical and electronic quality of cleaved monolayer graphene films.

Prior art CVD graphene production methods typically produce full coverage graphene films that are polycrystalline with grain (i.e., crystal) sizes of typically less than 10 μm on 25 μm thick Cu foil substrates having Cu grain sizes on the order of 100-200 μm. The prior art tools used in these systems typically include a quartz plate that supports one or more substrates during the graphene synthesis or a quartz tube that holds a foil substrate either a) rolled into a cylindrical shape as described in the article “Roll-to-roll production of 30-inch graphene films for transparent electrodes” by Bae. et. all in Nature Nanotechnology, Vol 5, August 2010 or b) folded multiple times over the respective quartz support tube. Optimization of CVD graphene synthesis typically involves the optimization of process parameters, such as temperature profile, carbon precursor species selection, total pressure, total flow, time dependent concentration of hydrogen (H₂) and carbon precursor(s) (HC, etc.) during the graphene growth phase, pre-processing annealing under stable and/or changing atmospheres (argon (Ar), hydrogen (H₂), oxygen (O₂)) and pressures, post-processing under stable and/or changing atmospheres (Ar, H₂, HC, etc.) and pressures, gas purity, and cooling ramp rates.

The prior art has attempted to achieve larger graphene grain sizes via higher processing temperatures, longer annealing and/or graphene growth times, lower concentration of HCs, higher H₂/HC ratios, special surface preparation of the graphene growth surfaces and/or higher purity precursor gas quality and/or by adding an O₂ exposure process step before the annealing or between the annealing and graphene growth process step. At the same time, the prior art has attempted to achieve better quality of graphene via the use of smoother starting substrates, for example, electro-polished and/or chemically-etched Cu foils, single crystal films or wafers, or substrates having larger-sized Cu grains. It is believed that grain boundaries of the catalytically-active material, while not stopping the graphene crystal growth, are still affecting the ultimate quality (conductivity, mobility, etc.) of the quasi-mono-crystalline graphene grains. With this in mind, some processes have attempted to reduce the size and quantity of the bi-layer and/or multilayer regions that typically occur near defects, nano-sized particles, and grain boundaries. Other processes have attempted to reduce the number of active graphene growth seeds and/or the area density of defects, holes, tears, and etched holes in the graphene films.

In prior art CVD graphene or other equivalent few atom 2-dimensional material synthesis systems, single layers of catalytically-active materials (in foil, film or wafer format) are typically used as substrates. Prior art teachings related to increasing the production capacity for a given horizontal tube CVD synthesis system include: 1) rolling a flat Cu foil into a hollow cylinder (increasing production capacity by a factor of 3-4×), or 2) folding it back and forth multiple times (increasing production capacity by a factor of >10-100×), with a simultaneous loss of some quality aspects of the CVD graphene film, e.g., uniformity. Other prior art production scale up efforts have been limited to roll-to-roll CVD graphene synthesis systems that process a single continuous roll of Cu foil.

There are many quality aspects associated with a graphene film grown on a growth surface via CVD. They include: 1) the percentage of monolayer coverage over the whole substrate surface, 2) the flatness, i.e., the amount of macroscopic kinks and/or wrinkles of a foil substrate after the graphene synthesis and the subsequent removal of the foil substrate from the respective support tool; 3) the coverage area of the graphene film, i.e., gaps (where graphene did not grow), voids (etched holes into previously-grown graphene films near nano particles located at the substrate surface), and tears and cracks in the graphene film; 4) the uniformity of the coverage over large area substrates; 5) the average and distribution shape of the sizes of the individual graphene grains; 6) the layer-homogeneity of individual grains (many graphene grains have a bi-layer and/or multi-layer grain “pyramid” near the graphene growth seed location); 7) the crystallographic alignment orientation purity within each individual graphene grain; 8) the flatness and/or wrinkleless of the graphene film on the substrate; 9) the size of the grain-domains of the substrate after annealing; 10) the density and/or elevation of the domain-grain boundaries of the substrate; and 11) the impurities covering the substrate material and/or graphene film. The importance of the uniformity of electrical and optical material quality parameters, such as conductivity, mobility, transparency, scattering and usable area of a given graphene film, are typically very application specific and therefore lead to different cost and volume driven optimum CVD synthesis system and graphene synthesis solutions for the various CVD graphene target applications.

The preliminary quality of a given graphene (or other equivalent few atom thick 2-dimensional material) grain is typically evaluated by optical microscopy, SEM, Raman, AFM, TEM and/or XPS analysis. In particular, measuring the area ratio of the 2D to G line in a Raman spectrum (for a probing laser beam with beam waist size of 0.7-3 μm) of the graphene film provides a good indication of whether the graphene crystal under the focused Raman laser probe is a single layer, bi-layer or multi-layer, or a mixture of the same (within the laser probe area). SEM image analysis and microscope image analysis can be used to determine the grain size of the graphene and of the substrate, and to see the flatness of the graphene film on a local scale. AFM analysis can be used to measure the thickness of discontinuous graphene islands or flakes. TEM analysis can be used to observe the quality of the graphene crystals on a very small scale, and XPS analysis can be used to analyze the stacking types of multi layers. Because the intimate contact between the CVD graphene film and the surface of the substrate typically influences the mobility and Raman signal strength and shape (doping of graphene, background fluorescence signal from the substrate, etc.) of the synthesized CVD graphene film resulting in Raman line shifting and/or shape changes, the absolute Raman based quality determination is typically done after the graphene film has been transferred onto a Si wafer which has preferably been covered with a 250-300 nm thick thermal silicon oxide (SiO₂) layer for Raman signal enhancement. However, a preliminary determination of the number of graphene layers can still be obtained from the 2D/G area ratio while the graphene film is attached to the substrate after performing an appropriate background correction to the raw Raman signal. A more accurate analysis for multi-layer graphene analysis can be done after the graphene film has been transferred to a transparent or reflective substrate for observing the local absorption coefficient over an extended area (a mono layer of graphene absorbs about 2-3% of light over a very broad wavelength range from UV to IR). For example, a single layer typically has a 2D/G ratio≧2, a bi-layer has a 2D/G ratio≈1, and a multi-layer (>2) has a 2D/G ratio<1. Peak ratios may be used instead of area ratio for quick analysis, although area ratios are fundamentally more accurate for this quantitative determination. In addition, the D/G ratio may be used to quickly evaluate the defect level (crystallinity) of the graphene grain under investigation since it is sensitive to crystalline defects in its hexagonal crystal structure, to edges of graphene grains and to wrinkles and strain of the graphene film. If the grains are very small (within an order of magnitude of the beam size of the Raman laser probe), the Raman signal will typically include a mixture of Raman spectra's obtained from more than one graphene grain, and from defective graphene grain boundary regions. Also, when the graphene grain grows over a Cu grain, it can do so in a less than perfect manner. Raman mapping over larger areas can, for example, can be used to map the boundaries of larger sized graphene grains by monitoring the change in D/G ratio (sensitive to edges) when scanning a micro Raman laser across an extended surface area.

Those skilled in the art will appreciate that the ability to provide full coverage of large size graphene grains with minimal gaps/voids and/or defects on substrates greater than 100 mm would be highly desirable in many potential commercial applications. Although progress has been made in the last few years to improve individual quality parameters (that affect the usability of a given CVD graphene film for a given application), no practical system solution has yet been presented that allows one to reproducibly manufacture larger-sized substrates (>100 mm) at low cost and with full coverage of higher quality (>10 μm grain size) CVD graphene film. For example, although the growth of large, isolated graphene grains (over 5 mm in size) has been demonstrated by multiple research groups, the portion of the substrate covered with such larger sized, higher quality grains is typically very small (<30%). Full coverage of small (<10 μm) grain graphene over a large Cu-foil size (762 mm diagonal) has been demonstrated with certain prior art systems (Cu foil rolled into a cylindrical form). However, due to the small graphene grain size, the multi-layer mixture and other defects, the quality (conductivity and/or transmission in this case) of the resulting graphene film is general not suitable for commercial applications. In other words, many graphene quality process innovations that improve one or more of the various process quality aspects have only been demonstrated on small size substrates (<100 mm) with limited reproducibility. The prior art tooling and CVD graphene or equivalent few atoms thick 2-dimensional material synthesis systems have simply not yet allowed for the scaling up of many process innovations and/or for the reproducibility of film property improvements.

Some of the lack of progress in this area has been caused by the material limitations of the substrate itself. For example, although Cu has a melting point of 1085° C., it exhibits strong sublimation at temperatures below its melting point, and particularly at lower pressures. If the HC partial pressures are too low, the graphene coverage of the substrate is typically incomplete. In order to get higher graphene area coverage, higher growth rates and/or higher processing temperatures are needed. This, in turn, causes increased loss of Cu from the substrate foil which thereafter may be deposited in the form of a low density Cu film onto the colder parts of the interior of the CVD synthesis chamber. When opening the synthesis chamber to remove the processed substrate samples, these deposited Cu films become partially oxidized. As the process gas flows over these loosely-coated areas in the subsequent process run, CuₓO_{y}/Cu, CuₓO_{y} and/or Cu nano particles may be dislodged and transported by the process gas stream onto the substrate surface, thereby polluting the catalytically-active growth surface with additional catalytically-active sites. To minimize such pollution, regular system maintenance is required wherein the tooling hardware is removed and cleaned (etched, flame polished, etc.). Depending on the type of CVD systems used (cold wall, hot wall, low pressure CVD (LPCVD), atmospheric pressure CVD (APCVD), roll to roll (RTR), resistively heated, IR heated, etc.), this Cu evaporation (sublimation) effect causes different problems. Although this Cu evaporation effect can be managed to some extent by frequent system maintenance, lower process temperatures, higher process pressures, it has nonetheless made it difficult to economically scale-up to larger size substrates, and has put restrictions on the available process parameters.

Another problem encountered in the prior art is that the Cu foil, especially at higher process temperatures, can become bonded to the plate holding the substrate, which is typically made of quartz. This, in turn, can result in the mechanical distortion of the Cu foil during cool down due to the 50× difference in the linear thermal expansion coefficient between Cu and quartz. Thus, even though higher quality graphene has been demonstrated in recent years on smaller-sized substrates, creating the same quality of graphene on larger-sized substrates (>100 mm) has not yet been achieved, due at least in part to mechanical distortion/wrinkling of the substrate.

One recent attempt to address the shortcomings of the prior art is disclosed in US Patent Application 2013/0089666. In particular, this application is directed to an apparatus and method for large scale graphene sheet production that utilizes a quasi-enclosed quartz substrate enclosure which includes one open side entry access port, and a cap made from bended Cu foil disposed over such access port. A Cu foil substrate is inserted through the access port into the quartz enclosure from the side. The application teaches that the imperfect mechanical seal between the quartz enclosure and the cap allows sufficient process gases to diffuse into the inside of the holder to effect graphene growth. Although this application suggests that graphene films with larger grain size can be manufactured using the disclosed tooling, such tooling has several significant drawbacks nonetheless. The design of the narrow enclosure increases the difficulty of loading/unloading larger-sized Cu foils without kinking/wrinkling. This would be particularly true in any automated process. Moreover, at higher process temperatures, the design of the substrate holder would likely result in increased localized bonding of the Cu foil to the quartz enclosure, thus increasing the difficulty of removing the substrate foil without kinking/wrinkling. In addition, the disclosed apparatus and method do not address the desire to run the synthesis process at higher temperatures and/or the desire to fine tune the various process parameters. Finally, the disclosed apparatus and method do not address the desire for parallel processing and/or the ability to readily load/unload the substrate.

### SUMMARY OF THE INVENTION

It is a first objective of this invention to manufacture CVD graphene on a catalytically-active metal foil substrate without kinking/wrinkling of the metal foil substrate, and without local bonding of the metal foil substrate to the substrate-holding tool.

It is a second objective of this invention to provide a CVD system operating at higher process temperatures for improved graphene growth on Cu foil substrates, without causing significant Cu film deposits on the interior colder parts of the process chamber and/or without the risk of polluting the substrates—either during the same or subsequent process runs.

It is a third objective of this invention to provide a CVD system for growing larger substrate material grains on a substrate utilizing the same or shorter annealing time intervals, and with reduced system maintenance needs and/or reduced pollution risk for subsequent process runs.

It is a fourth objective of this invention to provide a CVD system capable of providing uniform graphene growth over larger-sized substrates of various catalytically-active materials and/or high quality CVD graphene growth over larger substrate areas.

It is a fifth objective of this invention to improve the quantity of high quality graphene that can be manufactured in a single batch on substrates utilizing a CVD system having a given tube diameter and volume.

It is a sixth objective of this invention to reduce the maintenance down time for CVD systems, in particular for LPCVD-based systems.

It is a seventh objective of this invention to improve the quantity and or quality of CVD graphene manufactured with both LPCVD and APCVD Synthesis systems.

It is an eight objective of this invention to lower the production cost and/or increase the quality and/or production quantity of graphene manufactured by a CVD system.

It is a ninth objective of this invention to improve the graphene production throughput of higher quality graphene for a given CVD system.

It is a tenth objective of this invention to enable the design of high volume production CVD systems capable of growing graphene on substantially flat and wrinkle free Cu foil.

It is an eleventh objective of this invention to enable the growth of graphene on Cu foil with a CVD system with minimal exposure of the Cu foil to silicon-based material.

It is a twelfth objective of this invention to enable the cost efficient manufacturing of CVD graphene with large size, high quality graphene grains.

It is a thirteenth objective of this invention to provide quality/productivity improvements for substrates other than Cu foil.

It is a fourteenth objective of this invention to provide a CVD system capable of increasing the grain size of a Cu substrate and of other catalytically-active materials during CVD synthesis, and the growth of a film thereon.

It is a fifteenth objective of this invention to provide a batch process CVD synthesis system that is able to process at least one continuous roll of substrate in foil format.

It is a sixteenth objective of this invention to provide a CVD system capable of growing two-dimensional films, i.e., films having a thickness on the order of a few atoms, other than graphene.

These and other objects of the present invention are accomplished via the CVD synthesis systems (CVD Systems) disclosed herein, as well as by the CVD synthesis (CVD Synthesis) processes utilizing and/or taking advantage of the primary tools described herein. The term two-dimensional (2D) film is intended to include films having a thickness on the order of a few atoms, and may be formed of materials that can be manufactured by CVD processes on a substrate surface such as, for example, graphene, BN, WS₂, and MoS₂. For industrial production scale up, one of the preferred substrates of the present invention is a Cu foil. The term substrate as used herein is intended to encompass all suitably-sized substrate materials, including rolls, sheets, stripes, wafers, thin film coated wafers or the like, and whether they have polycrystalline, single-crystalline, amorphous, annealed, molten or re-solidified (first molten and then solidified) material structure, and whether it is a single unit or includes multiple units. It is contemplated herein that the primary catalytically-active substrate material includes Cu, nickel, platinum, rhodium iridium, germanium, boron nitrate, magnesium oxide, transition metals, and mixtures or alloys of such materials.

The term CVD Synthesis in the context of this invention is intended to include any precursor gases that contain CVD Synthesis relevant atoms (e.g., argon, hydrogen, carbon, boron and nitrogen, tungsten and sulfur, etc.) or any solid or powder coating or liquid films deposited or laid on top of the substrate that can then be converted into a respective few-atom thick film with a heating and gas/liquid delivery system that is able to sufficiently isolate a respective process chamber from the outside atmosphere and to deliver the required time dependent heat profile and process liquid/gas flows needed to achieve, at a minimum, a partial substrate coverage of mono and/or mufti-layers 2D film islands (less than 30 layers, i.e., less than 10 nm thick film). Typically, CH₄ is used as a preferred carbon-containing HC precursor gas for graphene film deposition, and is typically utilized together with Ar, H₂ and optionally an oxygen-containing gas, e.g., O₂, in one or more process steps. However CₓH_{y} (e.g., C₂H₂, C₂H₄, etc), ethanol, methanol, etc. can also be used. For example, borazine, boron hydrides, ammonium pentaborate, ammonium and other boron and/or nitrogen containing liquid and/or gaseous precursors are typically used to manufacture two-dimensional boron nitrate films by CVD Synthesis. Solid thin films or powder layers of aromatic or polymeric materials and/or liquid layers deposited or laid upon the substrate prior to its insertion in the CVD System are also an option for CVD graphene production in combination with one or more heat and gas treatment process steps (included in the definition of CVD Synthesis for this invention).

The term carbon in the context of this invention is intended to include any other material that is process compatible with the respective CVD Synthesis and has a minimal tendency to bond/stick/and/or wet to the respective few atom thick graphene or graphene like film.

Although graphite and other carbon-based materials are disclosed herein as preferred primary tooling materials for surrounding the substrate, it is contemplated herein that other materials which do not (or minimally) chemically interact/bond/weld with a particular chosen substrate, and which do not detrimentally interact with any of the process gases at the chosen process temperatures may also be utilized to manufacture the respective primary tools, e.g., quartz and carbon-coated quartz. In one preferred embodiment of this invention, the inside surface of the primary tooling components surrounding the substrate is made from quartz, boron nitrite, graphite, carbon-carbon composite, pyrolytic graphite, graphite or pyrolytic carbon with high in-plane conductivity, as well as any other materials that are process compatible with the to be manufactured 2D film(s), and specifically any other materials that have a stable carbon film on their surface, for example carbon-coated quartz. In one preferred embodiment of this invention, carbon film deposition onto a quartz surface is accomplished via the pyrolytic decomposition of HC prior to graphene synthesis, preferably in a different process run and/or system without any substrates present, and with all relevant inner surfaces or substrate contacting surfaces well exposed to the HC process gases. For example, carbon film coating of a quartz surface can be accomplished by CH₄ at pyrolysis temperatures above 900° C., preferably above 1000° C.

Pyrolytic graphite is one of the preferred materials for the primary tooling, with its high thermal conduction plane preferably oriented parallel to the substrate. Alternatively, machined graphite components, which have been sufficiently baked out prior to the synthesis as to not interfere with the quality of the 2D film manufactured, may be used. Carbon-carbon composites, GraFoil® sheets (GrafTech International Holdings, Inc.), preferably purified with a high temperature treatment, can also be used when needed for bottom plates, top plates, or trays. Carbon-carbon composites, when used to manufacture smaller components like screws, nuts, handles, threaded rods, tray frame components, etc., provide for increased durability of these threaded or frequently-handled parts. Optionally, a 0.1-1 mm thick GraFoil® sheet (manufactured by GrafTech International Holdings Inc.) can be used as a gas tight gasket that can be replaced as it wears and that allows some compression on the threads of an interlocking handle and screw. Preferably, if a lid is made from a carbon-containing material, the screws and handle used to build an accompanying enclosure box can be made from graphite or carbon-carbon material to minimize thermal expansion differences.

In one preferred embodiment of this invention, the carbon-based material used to manufacture the enclosure box components is a high purity graphite material that, after machining to shape, has been further baked out prior to CVD graphene processing in H₂ and/or a vacuum for extended periods of time at a temperature above 1000° C. For example, in one experiment, after machining the plate and lid of the enclosure box from regular purity graphite, the finished parts were separated with small graphite blocks to provide gas/vacuum access to all surfaces, and thereafter heated to 1090-1100° C. for a total of 6 hours, which included three 2 hour cycles of a 1 hour bake out in H₂ near atmospheric pressure followed by 1 hour of a vacuum bake out at a H₂ pressure of 1-2 mbar. This post-machining graphite treatment of regular quality graphite was sufficient to show quality improvement during LPCVD Synthesis on Cu foil when utilized as a component of a primary tool used, at a minimum, to support a substrate during CVD Synthesis.

Liners, when used with the primary tools of this invention, are preferably made from the same material or an alloy thereof (e.g., Cu, Cu—Ni, etc.) as the respective catalytically-active substrate (e.g., Cu), but optionally with different thickness and/or purity. A 0.5-2 mm thick Cu sheet (alloy 110, McMaster), stamped and bent to shape, was demonstrated herein as being effective. The increased material thickness of a liner (as compared to the substrate) provides stiffness to the liner to help prevent significant sagging of the outer edges of such liners. Optionally, the liners are surface treated and/or replaced before each run to remove any leftover graphene film which could interfere with the sublimation rate of such liner.

Auxiliary tooling components and related auxiliary functions are also considered part of this invention. For example, such auxiliary tooling may include a locating platform for locating a primary tool including one or more stacked enclosure boxes, or a transfer arm mechanically holding a primary tool (or stack thereof) in a unique reference location within the main reaction zone of the CVD System and which interacts with location features (alignment pins/holes/slots, standoff pins, recessed pockets, etc.) of the primary tool. The auxiliary tooling components for the CVD System may include, among other components, transfer arms, primary tooling support plates, gas injectors, thermal baffles, exhaust gas lines, and/or thermocouple sleeves.

In one embodiment of the present invention, the typical quartz tool used in the prior art as a susceptor to support the substrate during CVD Synthesis is replaced with a plate made from solid graphite, a carbon-based material or a material having a carbon-film surface coating. Simply exchanging the prior art quartz plate primary tool with a carbon material based or covered plate (e.g., graphite) primary tool, as per one embodiment of this invention, provides, at a minimum, an immediate improvement in the physical appearance (flatness, wrinkle-freeness) of the soft annealed Cu foil after graphene synthesis, while also allowing the foil to be more readily removed from its support surface after processing without wrinkling it.

More particularly, the present invention provides a chemical vapor deposition system for synthesizing a two-dimensional film, including: a) a primary reaction chamber; b) a gas delivery and exhaust system for delivering and exhausting at least one process gas to and from the primary reaction chamber; c) a heating system for heating the primary reaction chamber; and d) a primary tool located within the primary reaction chamber, the primary tool including a support plate, the support plate defining a flat planar surface for supporting a substrate thereon, the flat planar surface being exposed to the primary reaction chamber and the process gas flowing therethrough, the support plate being formed from a process compatible inert material having substantial non-wetting material properties when heated near the melting point of the substrate.

The present invention further provides a method for synthesizing a two-dimensional film, the method including the steps of: a) providing a support plate defining a flat planar surface; b) loading a substrate onto the flat planar surface of the support plate to provide a loaded support plate; c) positioning the loaded support plate into the primary reaction chamber of a chemical vapor deposition synthesis system; d) synthesizing a few layer thick film on the surface of the substrate by chemical vapor deposition, the support plate being substantially inert and having substantial non-wetting material properties when heated near the melting point of the substrate; e) removing the loaded support plate from the primary reaction chamber after completion of the synthesis; and f) offloading the substrate from the support plate.

In a further embodiment of the present invention, the primary tool used to support and enclose the substrate during graphene synthesis is a quasi-gas-tight sealed short enclosure box (SEB) that includes a plate with a substrate support area for supporting the substrate, a removable access port in the form of a top removable lid (comprised of at least one component and forming a quasi-gas-tight seal with the plate and allowing for the insertion and removal of the substrate to and from the substrate support area), an optional liner located above and/or surrounding the substrate, optional gas ports, handles and internal and/or external locating features. The interior volume of the SEB formed by the plate and lid form a secondary reaction chamber (SRC) for processing the substrate in a more controlled environment inside of the primary reaction chamber (PRC) of a respective CVD System. The interior surfaces of the SEB which are not covered by the substrate are optionally covered at least partially by a liner. Such optional liners can have a continuous or discontinuous surface, with or without bended taps and/or continuous or interrupted side walls, and can fully or partially cover the walls of the SRC outside the substrate support, and may be mounted to the lid in a manner which considers the different thermal expansion coefficients of the materials. Such a liner is used to create an even more uniform catalytically-active vapor environment in the respective SRC surrounding the substrate, and typically is used to increase the grain size of the substrate and/or 2D film and/or to reduce surface defects. Optionally, at least one gas port can be used to provide increased process gas flow, i.e., above the leakage rate of the quasi-gas-tight seal of the SEB, and optionally at least one handle can be used for easier manipulation of the lid and for ready access to the SRC for loading and unloading the substrate from the plate. Optionally, locating features can be used to locate the substrate on the plate, to separate the liner from the substrate, to locate the lid and/or liner with respect to the plate, to facilitate the transfer of the SEB, and/or to facilitate its spatial registration with an auxiliary transfer tool of a respective CVD Systems and/or substrate loading/unloading station.

The quasi-gas-tight seal of such a primary tool minimizes the escape of subliming substrate and/or liner material vapors from the SRC, which allows the CVD System to operate comfortably up to temperatures within a few degrees of the melting point of the substrate material, i.e., at vapor pressures that are much higher than typical for prior art systems, without significant polluting of the PRC of the CVD Systems and/or dramatically reducing the wrinkling problems commonly found in prior art CVD Systems that operate at process temperatures close to the melting point of a respective substrate. This not only widens up the process operational window for the CVD Synthesis, but can be also be used to shorten the processing time and/or to increase the grain sizes of the annealed substrate, in particular for Cu foils, which in turns helps to improve the overall quality (Raman D/G and 2D/G ratio), the surface flatness of the substrate and other quality aspects of CVD graphene films (e.g., graphene grain sizes of >20-100 μm, as compared to prior art grain sizes of <10 μm) manufactured using CVD Systems. It can also be used to achieve multi centimeter size Cu grains from 75 μm Cu foils.

More particularly, the present invention provides a chemical vapor deposition system for synthesizing a two-dimensional film, including: a) a primary reaction chamber; b) a gas delivery and exhaust system for delivering and exhausting at least one process gas to and from the primary reaction chamber; c) a heating system for heating the primary reaction chamber; and d) a primary tool located within the primary reaction chamber, the primary tool defining a secondary reaction chamber, the primary and secondary reaction chambers communicating via a quasi-gas-tight seal, the primary tool including a short enclosure box for substantially enclosing and supporting a substrate, the box including a support plate defining a support area, the box further including a removable lid sized and configured to contact the support plate about the periphery of the support area to form the quasi-gas-tight seal between the box and the lid whereby the substrate is substantially enclosed therebetween.

The present invention further provides a method for synthesizing a two-dimensional film, the method including the steps of: a) providing a support plate and a lid, both the plate and the lid being formed from a process compatible inert material; b) loading a substrate onto the support plate to provide a loaded support plate; c) covering the loaded support plate with the lid to provide a loaded short enclosure box, the lid being sized and configured to contact the plate about the periphery of the substrate, the plate and the lid forming a quasi-gas-tight seal therebetween; c) positioning the box into the primary reaction chamber of a chemical vapor deposition synthesis system; d) synthesizing a few layer thick film on the surface of the substrate by chemical vapor deposition; e) removing the box from the primary reaction chamber after completion of the synthesis; f) removing the lid from the box; and g) offloading the substrate from the support plate.

In other embodiments, the present invention provides a high volume primary tool used to increase the production capacity of higher quality graphene. In one of the embodiments of this invention a high volume primary tool includes a SEB stack (also referred to herein as a “closed tray stack”) with each individual SEB providing a respective SRC for a respective substrate. Because the height (h) of the SEB can be typically be chosen to be smaller than the diameter d of a respective process tube (h<<d) for a horizontal tube CVD System, multiple SEBs can typically be stacked and thereafter placed inside the process tube. Thus, the total processed growth surface area per batch can be increased (typically by >10×) for a given CVD System. Because each SEB recreates substantially the same process environment for CVD Synthesis, similar quality CVD Synthesis conditions can be expected for all substrates, as long as each SEB obtains the same process temperature and process gas composition for a similar time interval. To speed up the temperature uniformity during heating and cooling for such a SEB stack, convection heating/cooling with inert gases at near atmospheric pressure conditions can be utilized where appropriate.

More particularly, the present invention provides a chemical vapor deposition system for synthesizing a two-dimensional film, including: a) a primary reaction chamber; b) a gas delivery and exhaust system for delivering and exhausting at least one process gas to and from the primary reaction chamber; c) a heating system for heating the primary reaction chamber; and d) a high volume primary tool located within the primary reaction chamber, the high volume primary tool including a short enclosure box stack for substantially enclosing and supporting a plurality of substrates, the stack including a plurality of stackable trays and defining a secondary reaction chamber between each adjacent set of trays, the primary and secondary reaction chambers communicating via a quasi-gas-tight seal.

The present invention further provides a method for synthesizing a two-dimensional film, the method including the steps of: a) providing a plurality of stackable trays, each of the trays defining a substrate support area, each of the trays being formed from a process compatible inert material; b) loading a substrate onto each of the support areas to provide a plurality of loaded trays; c) stacking the loaded trays to provide a loaded short enclosure box stack; c) positioning the stack into the primary reaction chamber of a chemical vapor deposition synthesis system; d) synthesizing a few layer thick film on the surface of each of the substrates by chemical vapor deposition; e) removing the stack from the primary reaction chamber after completion of the synthesis; f) unstacking of the loaded trays; and g) offloading each of the substrates from each of the support areas.

In a still further embodiment of the present invention, the primary tool is in the form of a SEB designed to hold a substrate in a wafer format (e.g., a 200, 300 or 450 mm round or 156 mm×156 mm square wafer) in any orientation. Again, such tools may be stacked (vertically or horizontally) to form a higher capacity primary tool for a respective higher capacity CVD System.

In another embodiment of the present invention, the high volume primary tool used to increase production quantity of graphene includes a quasi-gas-tight sealed tall enclosure box (TEB) including a support plate and a top removable lid having a quasi-gas-tight seal and enclosing an extended secondary reactor chamber (ESRC) volume inside which a stack of trays (tray stack) is located, each with a respective substrate support area and organized in a predetermined spatial relationship (indexed) with respect to one another and to the support plate and with at least one gap allowing process gas exchange from the SRC volume above each tray to the ESRC, and including a quasi-gas-tight sealable and removable access port (either in the form of said lid, or included as part of the lid) that allows for loading and unloading of either the individual trays or of the tray stack into and out of the ESRC. Some of the interior surfaces of the TEB can optionally be covered at least partially by a liner having a continuous or discontinuous surface. Optionally, one or more gas ports are spread over the external surface of the TEB, and one or more handles are provided to facilitate transport of the TEB, lid and/or to open/close the access port. Additionally, optional location features may be provided to restrict movement of the substrates, trays, lid, plate, liner, and/or to support auxiliary tools and/or loading/unloading stations registrations, and/or for transport of the TEB, trays and tray stacks, and/or for the loading and unloading of the substrate to/from each tray. In this manner, each substrate located on a respective tray experiences in parallel the processing environment available in the ESRC, and thereby each substrate experiences substantially the same processing conditions during CVD Synthesis. As a result, a larger quantity of CVD graphene films can be synthesized in one CVD Synthesis batch.

In one preferred embodiment of this invention, the plate is optionally covered with a liner surface with cutouts allowing the reproducible placement of the tray stack on top of the plate. It further includes an access port in the form of a lid surrounding the tray stack and with its bottom surface providing a quasi-gas-tight seal and location registration with a respective groove in the plate. Optionally, the top portion of a respective liner structure is attached to the inside of the lid so that it can be removed together with the lid and thus provide ready access to a tray stack located on the bottom support plate. Alternatively, the lid can be formed from two components, namely a side wall structure and a top lid, with the side wall structure having top and bottom sealing surfaces that form quasi-gas-tight seals with the bottom support plate and the top lid respectively. The tray stack can be removed from the top after removing the respective top lid, and the top lid can have a liner cover and the side wall structure can also have a respective separate liner cover. In this case, the side wall structure is preferably attached to the plate, either in a permanent or semi-permanent way. Alternatively, one or more of the side walls of the side wall structure can be removed to gain quick access to the internally located tray stack. The removable side wall(s) preferably forms a quasi-gas tight seal with the side wall structure when attached. In this case, the side lid and remainder of the side walls may be sealed to the plate in a temporary or semi-permanent manner. In another embodiment of this invention, the cross section of such a TEB is square or rectangular, and one or more of the sides or partial sides forming the respective side wall structure provide the respective access port function.

In further alternative embodiments of this invention the respective TEB is made from two half cylinders that seal together in a quasi-gas tight sealed way (one being the respective access port) with an optional liner, with optional distributed gas ports, and with multiple removable trays that have optional features for locating at least one single (round, square, etc. shaped) substrate in a central location on each respective tray.

More particularly, the present invention provides a chemical vapor deposition system for synthesizing a two-dimensional film, including: a) a primary reaction chamber; b) a gas delivery and exhaust system for delivering and exhausting at least one process gas to and from the primary reaction chamber; c) a heating system for heating the primary reaction chamber; and d) a high volume primary tool located within the primary reaction chamber, the high volume primary tool including an open tray stack for supporting a plurality of substrates, the stack including a plurality of stackable trays which allow substantially unrestricted gas exchanges between the trays; and a tall enclosure box for enclosing the open tray stack thereby forming an extended secondary reaction chamber therein, the primary and extended secondary reaction chambers communicating via a quasi-gas-tight seal therebetween.

The present invention further provides a method for synthesizing a two-dimensional film, the method including the steps: of a) loading a substrate onto either i) at least two individual open support plates and then stacking the plates to form a loaded partially open stack, or ii) at least two different support plates of at least one preassembled partially open stack; b) inserting at least one of the loaded stacks into a tall enclosure box through a respective access port that is subsequently quasi-gas tight sealed; c) positioning the box in a primary reaction chamber of a chemical vapor deposition synthesis system; d) synthesizing a few layer thick film on the surface of the substrates by chemical vapor deposition; e) removing the box from the chamber after completion of the synthesis; f) opening the respective access port of the box; and g) offloading the substrate from each of the plates.

In further embodiments of the present invention, the high volume primary tool used to increase the production capacity of higher quality graphene has the form of at least one long enclosure box (LEB) that encloses, in a quasi-gas-tight sealed manner, an ESRC, and has at least one quasi-gas-tight sealed access port for loading/unloading at least one long substrate, and optionally liner, gas entry ports and/or handles. The substrate includes two opposite long side edges, and a length direction that has either been rolled up into a spiral or is folded forth and back in a serpentine manner along the long direction of the substrate, thus forming multiple substrate layers that are connected on at least one short edge. In either case, each substrate layer is separated from another by at least two similar continuous or discontinuous spacer strips that preferably are in close mechanical contact with only a small portion of the substrate near the respective opposite long edges of the substrate. The LEB can also have optional internal location features to locate the rolled up and/or folded substrate in a predetermined location inside the respective ESRC, and/or an optional external location feature to locate the LEB with respect to an auxiliary transfer arm and/or with respect to the PRC of a respective CVD System.

In one embodiment of this invention, the long substrate inside the LEB is a Cu foil that has a length that is at least 5-100× longer than the inside diameter of the process tube of the respective CVD System. In another embodiment of this invention, the spacer strips provide a low restriction for process gases exchange between the ESRC and the respective SRCs formed between two adjacent layers. In one embodiment of this invention, the thickness of the spacer strips is constant along their length (Archimedes spiral), and in another embodiment the thickness of the strips vary along their length. In a further embodiment, the spacer strip is a composite material, and has a similar thermal expansion to the long substrate. In an additional embodiment, the beginning and end of the long substrate, as well as the auxiliary internal or external support structure holding the rolled and/or folded long substrate, are partially open to allow further process gas exchange between the SRC and the ESRC in the long direction of the substrate. In a further embodiment of this invention, the substrate foil is in intimate contact on one side with a carbon material based sheet or fabric, and both are rolled up and/or folded up with at least two spacer strips on top of the substrate foil. This allows the option to provide a graphene process environment in each respective SRC by eliminating the otherwise automatic liner function of the bottom side of the long substrate and at the same time to provide more mechanical support for a wider foil substrate. In a further embodiment of this invention, mechanical structure is provided to reduce wrinkling of the rolled and/or folded long substrate due to temperature changes during CVD synthesis, e.g., an inner or outer cylindrical support tube that is made from the same material as the long substrate, and with a suitable (inert material, e.g., carbon based) spacer layer and/or strips (as needed) to prevent the long substrate from mechanically contacting the inner or outer support cylinder.

More particularly, the present invention provides a chemical vapor deposition system for synthesizing a two-dimensional film, including: a) a primary reaction chamber; b) a gas delivery and exhaust system for delivering and exhausting at least one process gas to and from the primary reaction chamber; c) a heating system for heating the primary reaction chamber; and d) a high volume primary tool located within the primary reaction chamber, the high volume primary tool including a long enclosure box forming an extended secondary reaction chamber therein, the primary and extended secondary reaction chambers communicating via a quasi-gas-tight seal therebetween; e) a rolled or folded open tray stack, the stack including an inner support tube, and wherein the box includes a pair of opposing pockets for supporting the opposing ends of the support tube whereby the stack is suspended within the box.

The present invention further provides a method for synthesizing a two-dimensional film, the method including the steps of: a) providing at least two strips of spacer rail material; b) providing an extended substrate having a width W, a length L and thickness T, and wherein T<<W<<L; c) creating a rolled self-supported open tray stack from substrate by winding the substrate in its length direction over an internal tubular support in such a manner that at least two spacer rail strips are inserted between each consecutive layer of the stack and located near the edges of the width of the stack; d) positioning the stack into the primary reaction chamber of a chemical vapor deposition synthesis system; e) synthesizing a few layer thick film on the surface of the substrate by chemical vapor deposition, the spacer rail material being substantially open thus permitting substantially uninhibited process gas exchange between the internal and external volume of each stack; and f) removing the at least one stack from the process chamber after completion of the synthesis.

The present invention also provides a method for synthesizing a few atom thick film, the method including the steps of: a) providing at least two strips of spacer rail material; b) providing an extended substrate having a width W, a length L and thickness T, and wherein T<<W<<L; c) creating a folded self-supported open tray stack by alternatively bending a substrate back and forth along its width direction while inserting at least two spacer rail strips between each consecutive layer near the edges of the width of the substrate; d) positioning the stack into the primary reaction chamber of a chemical vapor deposition synthesis system; e) synthesizing a few layer thick film on the surface of at least one substrate by chemical vapor deposition, the spacer rail material being substantially open thus permitting substantially uninhibited process gas exchange between the internal and external volume of each stack; and f) removing the stack from the process chamber after completion of the deposition.

In a further embodiment of this invention, an open rolled tray (spiral wound or folded) is used as a primary tool, and utilizes spacer strips to separate two adjacent substrate layers. While such a primary tool may be less optimal than the LEB solution in that the rolled and/or folded layers are not enclosed inside a quasi-gas-tight enclosure box, this embodiment nonetheless provides an improvement over the prior art.

Together, the primary tools of this invention, with matching and optional auxiliary tools in the form of one or more transfer arms, location platforms, robotic loading/unloading stations, gas injectors, exhaust ports, thermal baffles, internal and/or external thermocouples, heating zone controllers, internal and/or external rotating fans, internal/external gas heat exchangers, external forced air cooling systems, pressure sensors, pressure and/or flow regulation systems, removable furnaces and/or end caps, etc., can be used to increase the batch size capacity, production cost and cycle times of the CVD System, thereby producing higher total quantity and/or higher quantity CVD graphene films on one or more substrates.

In a further embodiment of this invention, a (LPCVD or APCVD) roll-to-roll graphene synthesis system is built utilizing an extended enclosure box (EEB) or an EEB stack, having its longest dimension along the direction of the motion of the substrate foil, and with one foil moving through the SRC of each respective EEB. Such a CVD System can also have one or more gas isolation zones, exhaust ports (one for each gas isolation zone) and/or suitable gas ports added on the sides of each EEB to provide a unique and/or substantially uniform process atmosphere (to minimize depletion of HCs or change of H₂/HC ratio). The plate optionally includes a replaceable liner, which can be replaced to manage mechanical wear and tear (e.g., if the plate surface is made from graphite). Preferably, the front and back of each EEB has optionally adjustable narrow slits and/or gas isolation zones to isolate the respective SRC from the rest of the external reactor chamber so that the distributed gas ports provide the primary gas entrance to the SRC and the slits provide the primary process gas exhaust of the SRC. In a further embodiment of this invention, more than one EEB are placed in series in the direction of the substrate foil motion, with thermal and/or gas isolation zones between each EEB, and with optional different heating control zones for each respective EEB to allow the creating of different temperature profile in each respective EEB, and with the option to provide a thermal gradient along the length of at least one EEB, and with different gas injectors feeding the respective gas ports of each gas isolated EEB to independently optimize the process conditions (gas composition, temperature, pressure) for each EEB to be facilitate the creation of different optimized processing steps (heating up, annealing, cooling, growth, cooling, etc.) in a serial manner as the long substrate foil moves through each subsequently aligned EEB.

More particularly, the present invention provides a roll-to-roll chemical vapor deposition system for synthesizing a two-dimensional film, including: a) a primary reaction chamber; b) a gas delivery and exhaust system for delivering and exhausting at least one process gas to and from the primary reaction chamber; c) a heating system for heating the primary reaction chamber; and d) a primary tool located within the primary reaction chamber, the primary tool defining a secondary reaction chamber, the primary and secondary reaction chambers communicating via a quasi-gas-tight seal, and wherein the primary tool includes an extended enclosure box having an extended support plate defining a direction of travel, the box including an entrance slit and an exit slit to allow passage of a continuous substrate therethrough in the direction of travel.

In a further embodiment of the present invention, the primary tools include one or more stacks of SEBs, TEBs, LEBs and/or EEB located inside a horizontal or vertical CVD System that is surrounded by a horizontal or vertically, optionally movable, heating system (resistive, inductive and/or infrared) that can be optionally opened and/or removed after CVD Synthesis to facilitate the cool down of the CVD System, and with optional internal fans and/or external gas heat exchanging systems to speed up the heating and cooling of the primary tool(s) located inside the primary reaction chamber of such a CVD System.

In a still further embodiment of this invention, the process conditions of the CVD Systems are modified to take advantage of the SEB, TEB LEB, or EEB primary tools of this invention. In one preferred embodiment of this invention, the annealing processing step before the CVD Synthesis step is done at temperatures within 20° C. of the melting point of the Cu-foil, and preferably within 5° C. of the melting point of the Cu-foil to accelerate the growing of large Cu grains, and to reduce the surface roughness of the Cu foil. In another preferred embodiment of this invention, the cooling rate from the annealing process step to the first HC exposure process step is controlled to obtain larger size Cu grains, and the CVD Synthesis step is done at a lower process temperature than the annealing step (for example 900-1050° C.) to reduce the etching of the graphene near catalytically-active nano particles (typically comprising, copper, oxygen, silicon, sulfur, etc.), and/or to lower the size and quantity of multi-layer graphene regions near the graphene growth seeds, and/or to suppress them. In another preferred embodiment of this invention, in combination with one or more SEB, TEB, LEB or EEB, one or more processing steps are added where an oxygen-containing process gas (for example O₂ or H₂O or N₂O, etc.) or process gases with a different gas purity of H₂O and/or O₂, are used to reduce the active graphene seed density before and/or during a key precursor exposure process step (e.g., HC, etc.), thereby allowing the growth of larger-sized single layer CVD graphene grains. In an additional embodiment of this invention, the annealing of the substrate is performed under atmospheric process conditions and the subsequent CVD Synthesis is performed at a lower pressure which results in the growing of larger substrate grains and higher quality 2D films. In a further embodiment of this invention, chemically and/or electro-polished catalytically-active substrates or thin Cu film coated wafer substrates are used as substrate to improve the quality of graphene in combination with the primary tools of this invention.

In an additional embodiment of this invention, the SEB, TEB, LEB or EEB primary tools do not utilize liners. In another embodiment of this invention, H₂ gas is not supplied to the CVD Synthesis system during at least one of the HC exposure process steps, which, for example, minimizes the etching of CVD graphene near catalytically-active particles at the selected elevated CVD graphene process temperatures.

The primary tools of this invention in the form of enclosure boxes (and respective SRCs) thus allow for the substantial isolation of the substrates from the more “polluted” PRC environment, while at the same time allowing for the operation at higher process temperatures and different gas ratios, thus enabling higher growth rates of graphene under various CVD synthesis conditions and increasing quality and/or productivity over prior art systems.

The ability to readily access the inner portion of the SEB, TEB, LEB and EEB, i.e., the SRC and/or ESRC of the respective primary tools (e.g. by simply lifting/removing the lid from the plate) provides significant productivity and quality improvement for larger-sized substrates (>100 mm), especially when the substrate is a thin and easily bendable metal foil. Additional embodiments of the present invention incorporated into the plate and/or support trays and/or holder of the rolled and/or folded long substrate and/or primary tool help to minimize any transport damage (kinking, warping) of the fragile (typically 10-100 μm thick) substrates in foil format and help, even more importantly, with the wrinkle/kink free removal of the soft annealed substrate foils from the respective SRC(s).

It is contemplated that the primary tools of the present invention can be utilized in prior art systems for improved graphene films, and that customized CVD System designs with matching optimized primary tools in accordance with this invention can provide maximum productivity gains.

### BRIEF DESCRIPTION OF THE DRAWINGS

FIG. 1 shows two wrinkled Cu foils locally bonded at multiple points to the top of a quartz substrate holder after a process run in an IR heated LPCVD graphene growth system.

FIG. 2a shows a low resolution SEM image of a Cu foil after a LPCVD graphene growth process, but without flowing HC during the graphene growth process step, utilizing the quartz support tool shown in FIG. 1.

FIG. 2b shows a high resolution SEM image of the Cu foil of FIG. 2a.

FIG. 3a shows a detailed SEM image of the round white particles depicted in FIGS. 2a-2b.

FIG. 3b shows an EDS analysis of one of the round particles of FIG. 3a.

FIG. 4a shows large Cu grains on a Cu foil processed with the primary tool of FIG. 7.

FIG. 4b shows a detailed SEM image of the CVD graphene synthesized utilizing the primary tool of FIG. 7.

FIG. 4c shows a Raman spectra analysis of the transferred CVD graphene film synthesized utilizing the primary tool of FIG. 7.

FIG. 5 shows a primary tool in the form of a graphite plate holding a Cu foil type substrate.

FIG. 6a shows a cross section of a primary tool in the form of a SEB enclosing and supporting a single substrate support area.

FIG. 6b shows a perspective view of the primary tool of FIG. 6a.

FIG. 6c shows an exploded view of the primary tool of FIG. 6a.

FIG. 7a shows a cross section of a primary tool in the form of a SEB with a sealing groove that encloses and supports a substrate support area.

FIG. 7b shows a perspective view of the primary tool of FIG. 7a.

FIG. 7c shows an exploded view of the primary tool of FIG. 7a.

FIG. 8a shows a cross section of a primary tool in the form of a SEB with a sealing groove that encloses and supports a larger size substrate support area.

FIG. 8b shows a perspective view of the primary tool of FIG. 8a.

FIG. 8c shows an exploded view of the primary tool of FIG. 8a.

FIG. 9a shows a cross section of a primary tool in the form of a SEB holding a round substrate in the form of a foil, wafer or coated wafer.

FIG. 9b shows a vertical view of the primary tool of FIG. 9a.

FIG. 9c shows an exploded view of the primary tool of FIG. 9a.

FIG. 10 shows another embodiment of a liner for the SEB primary tool of FIG. 9.

FIG. 11 shows a primary tool in the form of a SEB with the plate and the lid being the same part.

FIG. 12 shows a high volume primary tool in the form of a SEB stack.

FIG. 13 shows a high volume primary tool in the form of a SEB stack built from identical parts functioning as both plates and lids.

FIG. 14 shows a primary tool in the form of a higher density SEB stack utilizing a spacer frame to locate the substrate and define the respective secondary reactor chamber (SRC).

FIG. 15 shows a primary tool in the form of a higher density SEB stack built with “indented” tray parts functioning as both plates and lids.

FIG. 16 shows a primary tool in the form of a higher density SEB stack built from “molded” tray parts functioning as both plates and lids.

FIG. 17 shows an open tray stack using washers as spacer to build and open frame structure.

FIG. 18 shows another open tray stack using an open frame structure.

FIG. 19 shows an open round tray stack with a quick loadable frame structure.

FIG. 20 shows a primary tool in the form of a TEB enclosing and supporting an open tray stack with a top lid functioning as an access port.

FIG. 21a shows a cross section of a primary tool in the form of a TEB with a side access port.

FIG. 21b shows a perspective view of the primary tool of FIG. 21a.

FIG. 21c shows an exploded view of the primary tool of FIG. 21a.

FIG. 22a shows a cross section of a primary tool in the form of a TEB with an open tray stack 550 and with a top lid access port.

FIG. 22b shows an exploded view of the primary tool of FIG. 22a.

FIG. 23a shows a cross section of a primary tool in the form of a TEB holding an open stack of round substrates between two half clamp shells serving as outer enclosure and indexing structure.

FIG. 23b shows an exploded view of the primary tool of FIG. 23a.

FIG. 24a shows an assembled primary tool in the form of a TEB similar to FIG. 23 incorporating a liner.

FIG. 24b shows an exploded view of the primary tool of FIG. 24a.

FIG. 25 shows both a self-supported and supported rolled open tray stack.

FIG. 26 shows a folded open tray stack supported by a tube.

FIG. 27 shows a cross sectional view of multiple LEB designs.

FIG. 28a shows a cross section of a primary tool in the form of an EEB for roll to roll processing of a substrate foil.

FIG. 28b shows a perspective view of the primary tool of FIG. 28a.

FIG. 29 shows a horizontal tube furnace CVD System incorporating a single SEB as the primary tool.

FIG. 30 shows a vertical tube furnace CVD System incorporating two stacked TEBs as the primary tool.

FIG. 31 shows a horizontal tube furnace CVD Systems using an EEB as the primary tool.

FIG. 32 shows a horizontal tube furnace CVD Systems using another EEB as the primary tool.

FIG. 33a shows a cross section view of a roll-to-roll CVD System for multiple substrates in long foil format incorporating multiple EEBs as the primary tool.

FIG. 33b shows a vacuum tight LCVD version of a roll-to-roll CVD System for multiple substrates in long foil format incorporating multiple EEBs as the primary tool.

FIG. 33c shows an APCVD version of a roll-to-roll CVD System for multiple substrates in long foil format incorporating multiple EEBs as the primary tool.

FIG. 34 shows a horizontal tube furnace CVD Systems using an rolled or folded open tray stack as the primary tool

FIG. 35 outlines the process steps for manufacturing a two-dimensional film utilizing a primary tool of this invention inside a respective CVD System.

FIG. 36 outlines the process steps for manufacturing mono-layer graphene films utilizing a primary tool of this invention inside a respective CVD System to create larger size substrate grains.

FIG. 37 outlines the process steps for manufacturing a CVD graphene films utilizing a primary tool of this invention inside a respective CVD System to create larger size graphene grains.

FIG. 38 outlines the process steps for manufacturing a CVD graphene films utilizing a primary tool of this invention inside a respective CVD System to create larger size substrate and/or graphene grains.

### DETAILED DESCRIPTION OF THE INVENTION

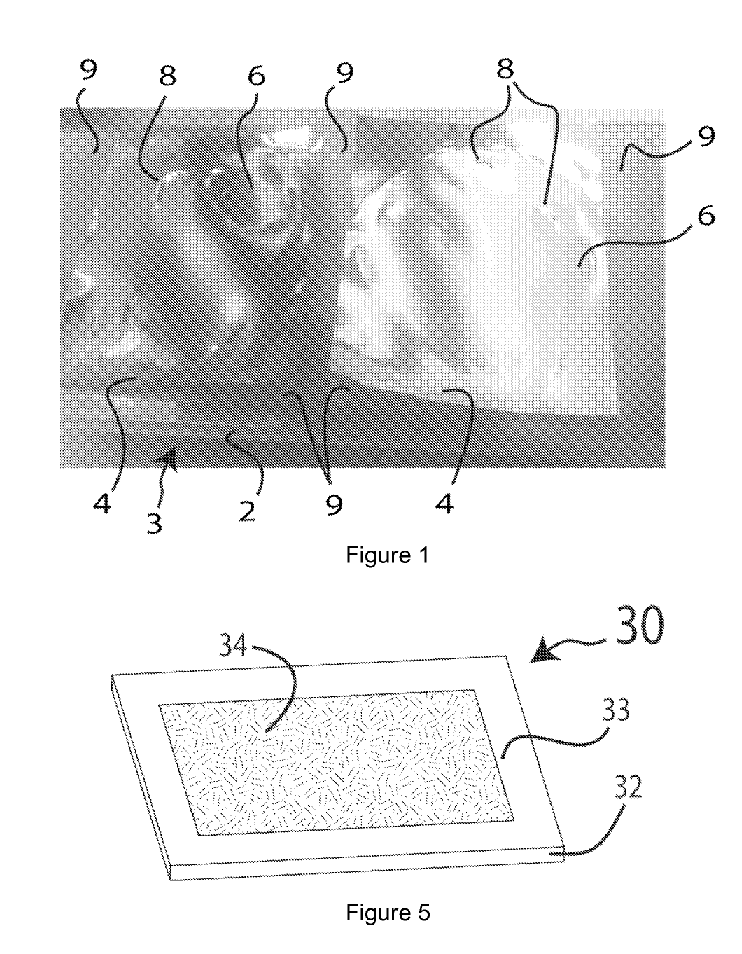

FIG. 1 shows a quartz bottom plate 2, which functions as a Cu foil support plate tool 3 for supporting two 50 mm×50 mm sized 25 μm thick Cu foils 4, after (≈1000-1030° C.) LPCVD graphene processing with a cold wall, infrared heated, horizontal tube LPCVD System, i.e., a CVD System wherein the Cu foils 4 absorb the IR heat, while the remainder of the quartz parts in the reactor stay at a lower temperature, thereby achieving short cycle times. FIG. 1 illustrates how both Cu foils 4 are very wrinkled and locally bonded to the quartz substrate plate 2 at multiple locations 6 after the synthesis process. The differential cooling rate (exaggerated by the cold wall IR system) of the Cu foil and the quartz tool 3, in combination with the local bonding 6 of the Cu foil to the quartz plate 2, causes the Cu foils to become wrinkled and locally distorted. The higher the process temperatures and the longer the growth time used during the graphene deposition process and/or during the pre-annealing of the Cu foil processing step(s), the higher the number of locations 6 of the Cu foil where it bonds to the quartz substrate, and the more wrinkles 8 that can be observed in the finished Cu foil. Similar issues are observed for most resistive-heating LPCVD and APCVD graphene deposition systems utilizing a quartz plate 2 as a primary tool 3 to support the Cu foils 4. It is seen that whenever a Cu foil 4 is in proximity to a quartz structure, there is a likelihood of local bonding during or after CVD Synthesis. In addition, the area below and surrounding the Cu foil 4 shows a deposition of Cu film 9 on the surface of quartz tool 3, which can lead to pollution of the next process run if tool 3 is reused without cleaning Typically, the larger the size of the Cu foils 2, the harder it is to obtain a wrinkle free Cu foil using traditional LPCVD process tooling. To minimize this Cu foil distortion problem, and to obtain some reasonable amount of flat Cu foil after CVD graphene processing, prior art LPCVD Systems have typically been required to operate at lower processing temperatures or utilize shorter processing times, leading ultimately to lower quality graphene (smaller graphene grain size, more defective graphene) and/or longer graphene production times. APCVD graphene processing systems typically have less Cu film depositions 9 below or nearby the Cu foil 4. However, even for an APCVD processing system, the Cu foil can occasionally bond locally to selected support areas and cause foil wrinkling. This especially occurs when larger size Cu foils 4 (>100 mm size) are used together with respective larger size quartz plates 2 as primary tool 3.

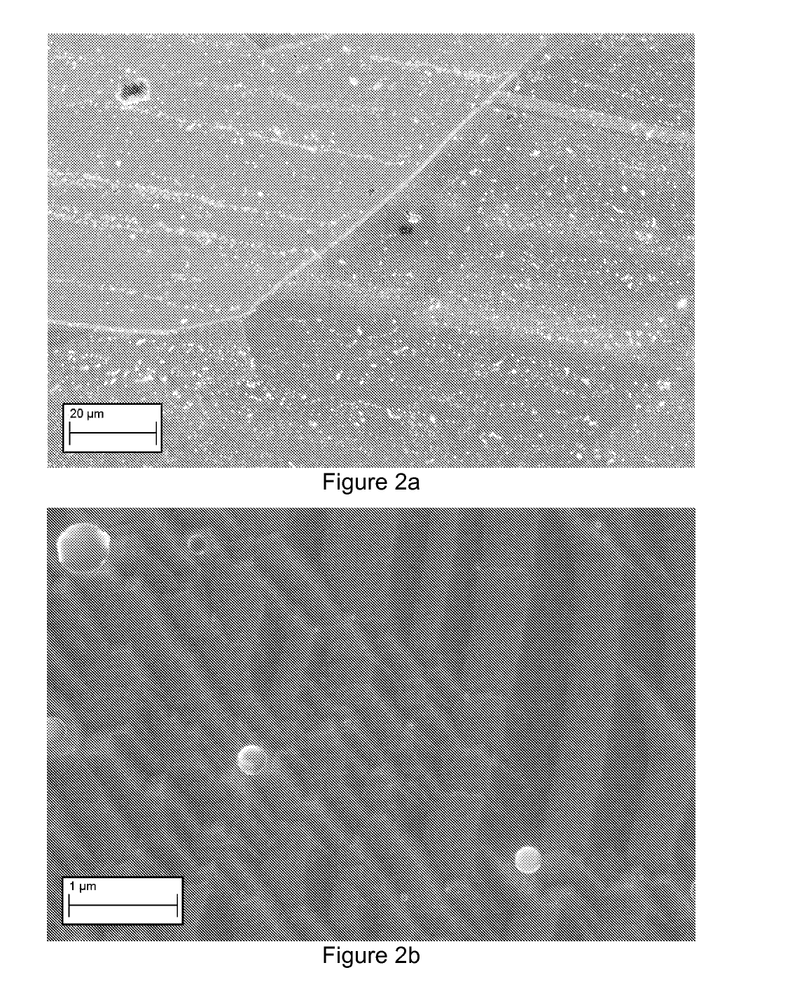

FIGS. 2a and 2b show SEM images at two different magnifications obtained with a resistively heated, horizontal tube furnace CVD System using quartz plate 2 to hold a respective Cu foil in the middle of the respective PRC and by operating a standard LPCVD graphene process, but without flowing CH₄, i.e., without actually making a graphene film. As shown, a high density of round, white particles having a diameter of 10-50 nm were observed for this particular process run, which followed several LPCVD graphene process runs done with the same process tube. After CVD Synthesis, these round white particles typically appear near the center of most of the darker graphene regions (multi-layer graphene), and they form either graphene nucleation and/or graphene etching sites. Due to the high density of these particles, other defects and/or graphene nucleation seeds, the CVD graphene size has typically been limited in prior art CVD Synthesis systems to less than 10 μm, leading to lower quality CVD graphene films.

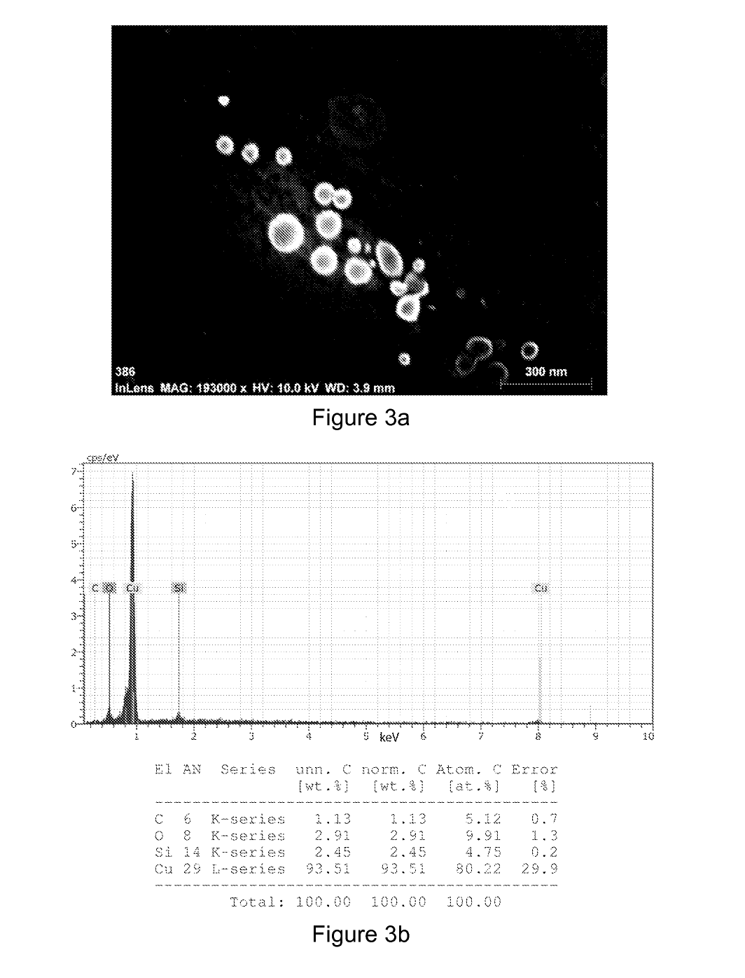

FIG. 3a shows a detailed SEM image of the round white particles depicted in FIGS. 2a-2b. FIG. 3b shows an EDS analysis of one of these round particles indicating that it contains primarily Cu as well as traces of Si and O in the 2-3% range. The respective Si and O content normally is in the 1-20% range, with larger particles typically having higher Si and/or O content.

Cu has a melting point of 1085° C. The higher the processing temperatures, the longer the processing steps, and the lower the pressure of the CVD Synthesis, the more the amount of Cu vapor that sublimes from the Cu foil substrate and deposits onto nearby colder surfaces within the CVD chamber. It has been discovered that when a quartz surface is located proximate a Cu foil (e.g., on top, below or next to the Cu foil), sublimed Cu vapor gets deposited first onto the proximate quartz surface. It is thereafter resublimed, and re-deposited onto another nearby surface site, thereby spreading throughout the process tube enclosing the substrate. The Cu therefore gets deposited and re-evaporated from a hot surface many times during the CVD Synthesis process. The deposited Cu film thickness exhibits a gradient with respect to the distance from the foil. The Cu film deposited near the Cu foil edge and/or underneath the Cu foil can become so thick that it may locally weld the Cu foil substrate to the respective quartz support plate. Each time a Cu atom or cluster is deposited onto a quartz surface there is a probability that the Cu atom alloys with one or more Si atoms of the SiO₂ material forming the respective quartz surface. It is believed that the Cu and Si atoms form an alloy having a lower melting temperature that can then re-evaporate easier/faster than Cu, and which can readily form nano particles (i.e., the round white particles seen in FIGS. 2a-2b) which can then be transported onto the graphene substrate surface. However these re-deposited alloyed Cu nano particles, because of their mixed material composition and the <1085° C. process temperature, are not easily reabsorbed into the Cu foil substrate, but instead tend to move about the surface of the substrate. These nano particles are typically trapped near foil defect sites (left over grooves and ridges and/or HC and metal surface impurities from rolling the Cu foil) and/or near Cu grain boundaries and/or near other surface defect sites (originating from internal material impurities). Locally trapping these nano particles facilitates the fusion (Oswald ripening) of two smaller particles into one larger particle (see FIG. 2).

Depending on the graphene process conditions and the material composition of the nano particles, such particles either become 1) graphene growth seeds, and/or 2) graphene growth defect sites and/or 3) graphene etching sites (voids) where the H₂ in the process gases catalytically etches the graphene near such sites thereby forming nearby hexagonal shaped voids in the graphene film. In addition, each time Cu atoms re-evaporate from a SiO₂ surface there is a chance that SiO₂ and/or Cu—Si—O nano particles get released and put into the gas stream. Some of these particles may be deposited onto the Cu substrate where it is believed that they drift about until they fuse with another such nano particle, thus creating a larger particle (FIG. 2b), which in turn can then become a graphene defect, etching and/or nucleation site. Analysis of these nano particles reveals (see FIG. 3) that they typically include 1-20% of silicon (Si) and/or oxygen (O).

It is believed that at least some of the Si contained in these nano particles is coming from the nearby quartz surfaces, the Si having been separated from it by one or more Cu deposition/re-evaporation cycles. To substantiate this theory, we created the following three different enclosure boxes: Box I) a 50 mm tall quartz top lid was placed over a Cu foil supported by a quartz plate, Box II) a 40 mm tall liner Cu lid was placed over a Cu foil supported by a quartz base plate, and then the 50 mm tall quartz lid was placed over the liner, and Box III) a 5 mm tall liner Cu lid was placed over a Cu foil supported by a graphite plate, and then a 7 mm tall graphite lid was placed over the liner.

After the isolation of the Cu foil from the process tube with any of enclosures I, II or III (even with a clean quartz enclosure I), we observed a noticeable reduction in nano particle count on the respective SEM images. This demonstrates that at least some of these nano particles are originating from the porous Cu/CuₓO_{y} films (deposited in part from previous runs) located near the colder region of the process tube where the gas enters the process chamber and blows over these low density Cu/CuₓO_{y} films. In another experiment, we exchanged the Cu foil substrate for a wafer substrate having a 300 nm Ni film deposited on top of a Si wafer having a 500 nm thermal oxide SiO₂ layer without cleaning and/or replacing the quartz components. After atmospheric pressure CVD Synthesis typical for few layer graphene film to grow on a Ni film substrate, we observed Cu nano particles on the Ni film, confirming our theory that the particles had migrated from the colder areas of the chamber to the substrate via the process gas stream.

The mechanical (also referred to herein as “gravity powered”) seal between the bottom rim of the respective lid and the plate was, on one hand, loose enough to let sufficient process gases inside said enclosures to allow CVD graphene films growth on the Cu foils but, on the other hand, was tight enough to be able to keep many of these alloyed nano particles out. When enclosure II was used (Cu foil resting on a quartz plate and enclosed by a Cu liner), we observed a further reduction in the nano particle surface density. When enclosure III was used, (no direct quartz surface exposure for any Cu vapor subliming from the Cu foil and/or the liner lid), we observed an even cleaner Cu foil substrate (less nano particles) after LPCVD graphene processing.

In addition, after we replaced the quartz plate with the graphite plate (enclosure III), we observed significantly less to no local bonding of the Cu foil to the plate. We also observed that the Cu foil was much flatter and more wrinkle free than we have observed before with quartz support plates operated under similar LPCVD graphene synthesis conditions. We further observed, especially when using a higher than typical temperature annealing process step, e.g., 1050-1080° C., that the Cu foil itself became flatter after CVD Synthesis, even if the starting Cu foil was partially curled in one plane from bending stress induced during its manufacturing operation (e.g., cold rolling).

In all experiments where a lid was used to cover the Cu foil substrate during LPCVD Synthesis, we noticed a dramatic drop in Cu deposition onto the colder surface areas of the respective process chamber, i.e., a substantial portion of the sublimed Cu vapor remained inside the respective enclosure box. At the same, time we also noticed an improvement in graphene film quality (after baking out all graphite parts at 1090-1100° C. for several hours before using them for graphene synthesis).

Because the graphite material used for manufacture of enclosure III had a porous surface, we also tried a SiC-film-coated high purity graphite susceptor with a smooth, non-porous top surface as the support tool (plate) for a Cu foil. As a test, we also built enclosure IV by replacing the graphite plate of enclosure III (which includes a liner lid made from a 0.5 mm thick Cu sheet) with a SiC coated graphite plate. We then operated an LPCVD Synthesis process with enclosure box IV at 5° C. below the experimentally determined system melting temperature of the Cu foil when inside of enclosure box III, i.e., the SEB primary tool made from a graphite plate and lid. To our surprise, and despite not having melted under the same conditions when tested in enclosure box III, we observed that the Cu foil had melted into white ball-shaped particles (50 μm-2 mm) that were heavily bonded to the SiC plate top surface. These white ball-shaped particles bonded so strongly to the SiC surface that the top SiC coating chipped when we tried to remove such particles with a scalpel for analysis. We also observed that part of the lower rim of the Cu liner, i.e., the locations that were in contact with the SiC-coated plate, melted back a few millimeters and that the color near these melted areas was whitish looking, i.e., it no longer had a red-brown Cu-like appearance. An EDS analysis of this part of the lower rim revealed whitish ball-shaped particles having a >10% Si content. We therefore concluded that at temperatures near 1080° C., Cu exhibits a strong ability to absorb the Si from the SiC film, thereby forming a lower temperature alloy.

We conducted a further experiment where we tried to deposit Si nano wires onto a Cu foil that had been previously coated with a 5 nm gold (Au) film via an ebeam system. These test substrates were supported by either a Si-coated quartz plate or a graphite plate. In the same experiments, we also placed a 5 nm Au-film-coated Si wafer near the Cu films. After a Si nanowire process run at a maximum process temperature of 500° C., we observed that the Cu foil was no longer flexible; instead it was rather brittle and ceramic like. We conducted an EDS analysis (Bruker Quantax 200 EDX) at the middle of the cross-section of this brittle new unknown material and found that the middle of the 25 μm thick Cu foil contained about 15% of Si. In other words, the Si vapors from the pyrolysis decomposition of the silane gas (SiH₄) had been deeply absorbed into the Cu foil, thereby forming a Cu—Si alloy, instead of the expected surface film modifications. The nano fibers observed on the Cu foil were also highly irregular and uneven and were analyzed to be primarily an alloy of Si and Cu. The 5 nm Au-film-coated Si wafers in the same process run that were placed next to the Cu foils were covered with normal types of Si nanowires for the chosen CVD process conditions.

Together these experiments demonstrated that Si dissolves easily in Cu, and that under graphene CVD Synthesis process conditions, Cu has an ability to remove Si even from strongly bonded chemicals like SiO₂ and SiC.

We further observed that enclosure III made from graphite acted as a thermal integration sphere that absorbed through its external surface area the non-uniform incident infrared radiation emitted from a resistively heated clamp shell oven surrounding the process tube of the respective CVD Synthesis and re-emitted it (black body radiation) via its internal surface towards the SRC in a more uniform manner. This occurs in part due to the non-isotropic thermal conduction properties of the graphite material used, and in particular, because of its 20× greater in-plane thermal conductivity (as compared to quartz). Therefore, the non-perfectly uniform heating up of the graphite box by visible and infrared radiation emitted by a resistive heating oven surrounding it, lead to a more uniform heating of the internal Cu liner and a therefore even more uniform heating of the inside Cu foil. We did observe further that if the Cu foil accidentally contacted the sidewalls of the inner Cu liner, for example because it had shifted during loading, unwanted tacking/welding could occur (especially at >1050° C. annealing temperatures). The better thermal expansion match between graphite and Cu, coupled with a more uniform temperature change across the substrate resulted in a reduction in the size and quantity of the cracks and/or folds in the graphene film that typically occur during cooling. As a result of using a graphite plate, the Cu foil no longer became wetted/stuck to the support plate, and exhibited a dramatic improvement in flatness.

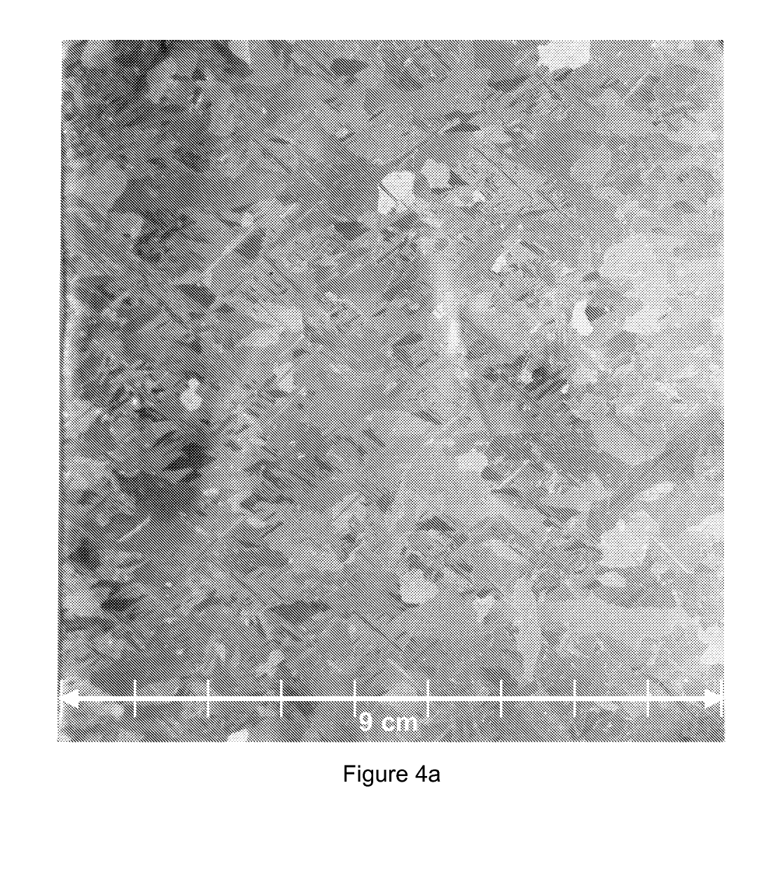

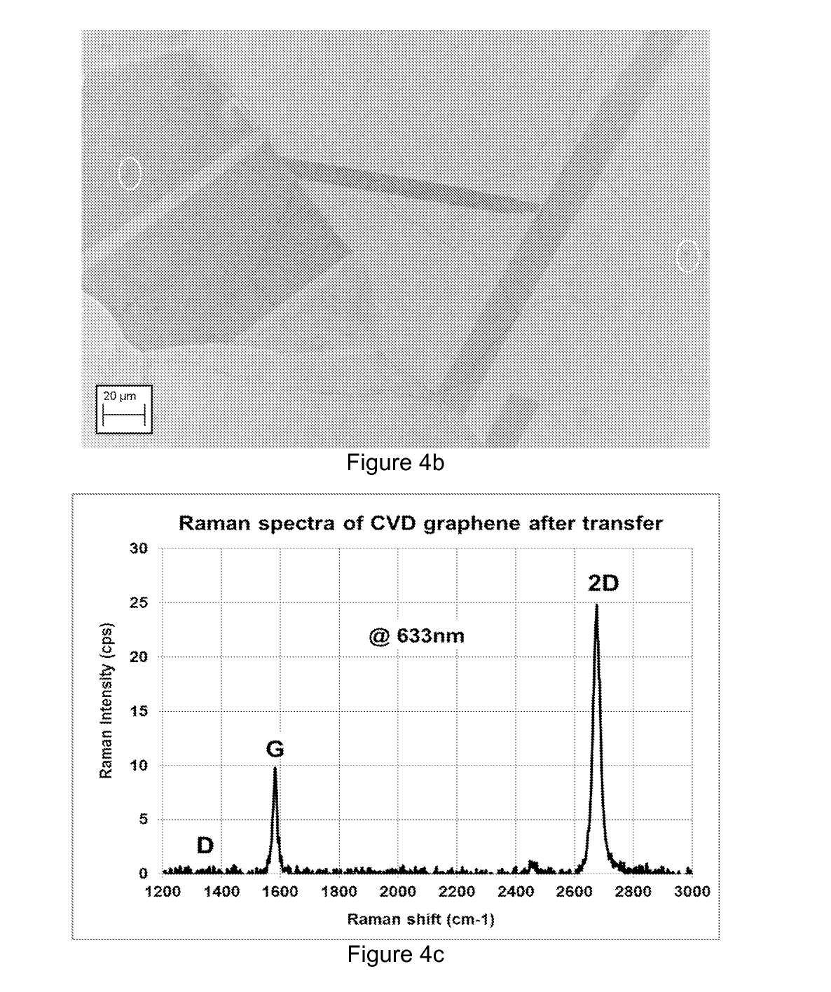

FIG. 4a shows Cu grains up to 2 cm that were obtained using SEB 70 described hereinbelow and by utilizing a low pressure annealing process step during LPCVD graphene synthesis. Even larger Cu grains were obtained by utilizing an APCVD annealing process step. To obtain the Cu grains shown in FIG. 4, a 75 μm thick oxygen rich Cu foil (Cu alloy 110, Mac Master) was annealed for 30 minutes at 5° C. below the melting point of Cu (e.g., at 1080° C.) at 600 mToor inside SEB 70.

FIG. 4b further shows with a low magnification SEM image that the number of multilayers can be significantly reduced, if the CVD Synthesis process is retuned to take advantage of the new process conditions inside the internal reaction chamber. For example, the results shown in FIG. 4b where obtained with a horizontal tube EasyTube 3000 system (manufactured by CVD Equipment Corporation) having a 5 inch process tube that was retrofitted with a primary tool of this invention in the form of SEB 70. SEB 70 was made from baked out machined graphite (standard graphite sheets, McMaster), and included a liner 86 made from a 0.5 mm thick Cu sheet (Cu alloy 110, McMaster). The respective CVD Synthesis process included: 1) annealing an electro-polished 75 um thick Cu foil substrate (Cu alloy 110, Mac Master) at 1050° C. for 30 minutes at 0.6 Torr in 300 sccm of H₂; 2) cooling the Cu foil to 950° C. over a 14 minute interval at 0.6 Torr with 300 sccm of H₂; and 3) growing the CVD graphene at 950° C. in a two-step process with ramping the CH₄ flow from 0-25 sccm over a 15 minute interval at 0.5 Torr and 100 sccm of H₂, and then holding it at 25 sccm of CH₄, 100 sccm H₂ and 0.5 Torr for another 15 minutes. Thereafter, all the hot parts were cooled under 2 slm of argon (Ar) flow at atmospheric pressure conditions until they reached 150C, after which SEB 70 was unloaded, and the substrate removed from the plate. It should be noted that these LPCVD Synthesis process conditions are very similar to typical prior art LPCVD graphene recipes that normally result in less than 10 μm graphene grains and smaller than 100-200 μm Cu grains with a 25 μm thick, oxygen free Cu foil from Sigma Aldrich (#13382, lot # K14X001).

The Raman image shown in FIG. 4c was obtained with a Raman laser system (DXR Raman Microscope manufactured by Thermofisher) at 100× after transferring the graphene film to a Si wafer with an ≈280 nm thick thermal oxide surface layer. The 2D/G≈2.6>2 peak ratio and even bigger (≈3.9) area ratio, together with the low (<2%) D/G peak ratio, show higher than typical quality mono-layer CVD graphene. The 1K× magnification of the SEM image shown in FIG. 4b shows very few white spots, only a few (≈10) multi-layer regions in a 200 μm×300 μm size region (two are highlighted with a white ellipse) and that the estimated CVD graphene grain size (distance between the black edges surrounding the graphene grains) is ≈40-100 μm, i.e. >>10 μm.

The foregoing experiments lead us to the conclusion, that contrary to the prior art systems/processes, the CVD Systems of the present invention (particularly when used to manufacture graphene films) should be designed 1) to eliminate Si-based materials, to the extent possible, 2) to incorporate a quasi-gas-tight enclosure box that surround and support one or more respective substrates, thus providing a substantially isolated secondary processing environment, i.e. a very reproducible controlled SRC for each respective substrate, 3) to allow the primary tool components to take advantage of the non-stickiness/non-wettability of Cu to carbon (at least up the melting point of Cu) and/or design them to provide as much thermal conduction and uniform black body emission towards the SRC as practical and/or to better match the thermal expansion coefficient of the substrate, 4) to provide ready access to the interior of the enclosure box for loading/unloading of the substrate, 5) to provide built-in auxiliary internal and external locating functions when practical for manual and/or machine handling automation, 6) to provide handles where needed to facilitate the manipulation of the various components, 7) to provide distributed gas ports where needed to uniformly control the process environment for larger size SRCs, 8) to provide the option of liners made with the same material (but optional different thickness and/or purity than the substrate) and 9), when needed for productivity gains, to provide a high volume primary tool that increases the total loadable substrate surface by one to two order of magnitudes. Item 9 can be accomplished with this invention by allowing the stacking of multiple substrates on top of each other and/or rolling and/or folding one long substrate in a third dimension (perpendicular to substrate plane).

The balancing of all these design goals leads to primary tools in the form of four primary types of enclosure boxes: a short, a tall, a long and an extended enclosure box, with each type having an optional liner. The short enclosure box (SEB) provides one flat support surface onto which one or more graphene substrate can be loaded up to the maximum available support area. Thus, when multiple SEB's with proper located optional auxiliary gas ports are stacked on top of each other each substrate substantially experiences a similar processing environment in its respective SRC. The tall enclosure box (TEB) encloses an open tray stack in its extended secondary reactor chamber (ESRC) with each tray providing one flat support surface onto which one or more graphene substrates can be loaded and with the volume between two adjacent trays forming a respective SRC for each substrate that is in gas communication with the ESRC, thus assuring that all substrates experience substantially the same processing environment. The long enclosure box (LEB) also has an ESRC that encloses a long substrate surface that has been rolled and/or folded in a direction perpendicular to the substrate surface, and wherein each portion of the substrate is spaced apart from another adjacent substrate portion by at least two spacer strips located near the long edge of each substrate (thus avoiding localized welding and/or variations in the gas rate exchange with the ESRC) and that together, with the gap created between two nearby substrate surfaces, form a respective substantially uniform local SRC that is in gaseous communication with the ESRC along the substrate length and/or through auxiliary optional gas ports built into the at least two spacer stripes. An extended short enclosure box (EEB) facilitates the quality improvement for roll-to-roll CVD System.

One or more of these primary tool design features helps to improve the quality of CVD graphene films for a wide range of CVD Synthesis systems, and allows for an industrial scale up in size, production quantify and/or throughput of CVD graphene films. These design features further enable an improvement in the reproducibility and quality of the manufactured CVD graphene film. In addition, the herein disclosed novel scalable primary tools and CVD Synthesis system designs incorporating and/or taking advantage of such primary tools allow for the graphene process to operate at higher process temperatures than was previously practical, for cold and hot wall, APVD or LPCVD Systems, and for both Cu foils and films and other catalytically-active graphene synthesis materials. This, in turn, now allows CVD Synthesis processes to be fine-tuned for various applications, including electronics, nano MEMS, and membranes as described in U.S. Pat. No. 8,361,321, by enabling, in a practical and industry relevant manner, a wider process operational window for film optimization.

Other primary tools that improve the graphene film production rate and/or quality over prior art, but that do not utilize an enclosure box, are also contemplated and disclosed herein.

### Primary Tools in the Form of a Single Plate Having an Open Substrate Support Area

In the embodiment of the present invention shown in FIG. 5, the primary tool is a support plate 32 (without an enclosure box) made from solid graphite that provides a single substrate support area 33 for supporting one or more flat graphene substrates 34 thereon. Alternatively, it can also be made from a process compatible inert and mechanically-stable-coated material that only minimally wets with substrate 34 during CVD Synthesis, including a support substrate with a carbon coating on its top surface or a coating that converts to a carbon film before, or at a minimum, during the CVD Synthesis process. Preferably plate 32 is made from high purity graphite material with a high in-plane thermal conductivity (with pyrolytic graphite being one of the preferred materials) and/or that has been baked out sufficiently as to not interfere with the quality of the graphene film manufactured during the synthesis process. Equivalently, a carbon coating prevents substrate 34 (especially in a Cu foil form) from locally bonding to plate 32. Thus, changing the material for the primary tool used inside a respective CVD System to graphite (or equivalent minimal wettable materials) improves the typical graphene quality by significantly improving the physical appearance (flatness, wrinkle freeness) of a soft annealed Cu foil after CVD Synthesis, and also allows such foil to easily slide off the base plate onto a transfer plate.

### Primary Tools in the Form of a Short Enclosure Box Enclosing a Single Substrate Support Area

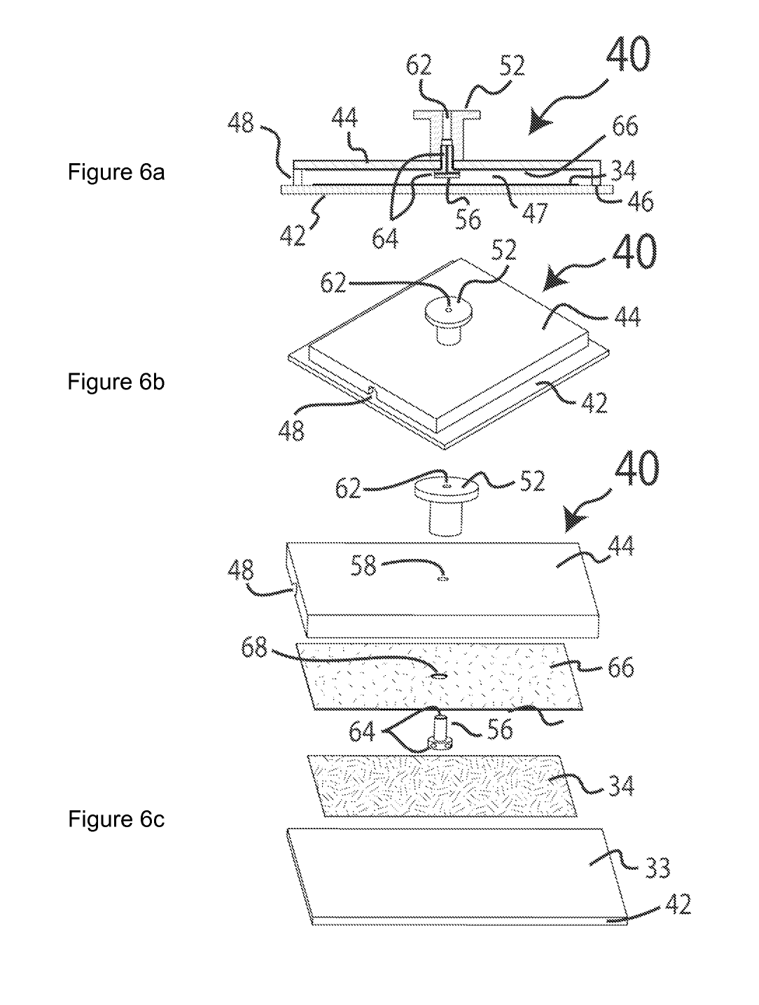

Another embodiment of this invention is shown in FIGS. 6a-6c where the primary tool is in the form of SEB 40, which substantially encloses and supports substrate 34, and includes a support plate 42 having a support area 33 and a removable lid 44. In particular, a seal 46 limits the escape of substrate 34 material vapors from the SRC 47 formed by the plate 42 and lid 44. In another embodiment of this invention, optional locating feature means may be used to facilitate manual or robotic manipulation (lifting, placing, and/or transporting) of lid 44, plate 42, and/or assembled primary tool 40. For example, easy mechanical manipulation of lid 44 (if hot) can be accomplished by adding side or top handles, providing triangular, square, rectangular or dove tail groves along the sides of lid 44, providing threaded holes or dovetail grooves on the top side of lid 44, or by other means that can be machined into lid 44 to enable a sufficiently rigid mechanical connection with a grabbing tool, hand, and/or robotic arm. Alternatively, at least one top screw-on optional handle 52 can be used to allow to move the lid 44 easily. Handle 52 is shown as a simple screw-together handle with no orientation preference that connects to a shoulder screw 56 through a hole 58 in lid 44.

For larger sized primary tools 40, optional gas ports 48 can be machined into lid 44 and, in certain applications, may be matched with auxiliary tooling for gas delivery (e.g., quartz injectors) and gas removal (e.g., quartz exhaust line). One or more gas ports 48 may be machined into lid 44 as needed to increase the gas flow exchange between the inside and outside of SRC 47 if, for example, the seal 46 is too tight for a particular CVD Synthesis process. More than one gas port may also be needed if primary tool 40 is very large, at least in one dimension, as compared to the height of lid 44. Alternatively, handle 52 may include a gas port 62, which communicates with at least one gas port 64 in screw 56, thus allowing a controlled atmosphere exchange between SRC 47 and the PRC. It is contemplated herein that gas ports 48 can be located at pre-selected locations across lid 44 to affect a desired gas flow exchange.

In an additional embodiment of the present invention, the inside of lid 44 is covered with a liner 66 which is optionally held against lid 44 via shoulder screw 56 which extends through a quasi-centered hole 68 formed near the middle of liner 66. The dimensions of inner liner 66 are preferably less than the inside area of lid 44 to accommodate for the lower linear thermal expansion of the lid 44 with respect to liner 66. For example, the linear thermal expansion ratio between Cu and graphite is 2-3 times. Alternatively, the interior surface of lid 44 may be provided with a vacuum deposited thin (<2 μm thick) high purity coating of the same material as substrate 34, provided the deposited coating is capable of surviving the heating cycle and related stresses induced by the different linear thermal expansion coefficients between such coating and the material of lid 44. The inner surface of lid 44 may be roughened to increase the bonding strength of the deposited coating.

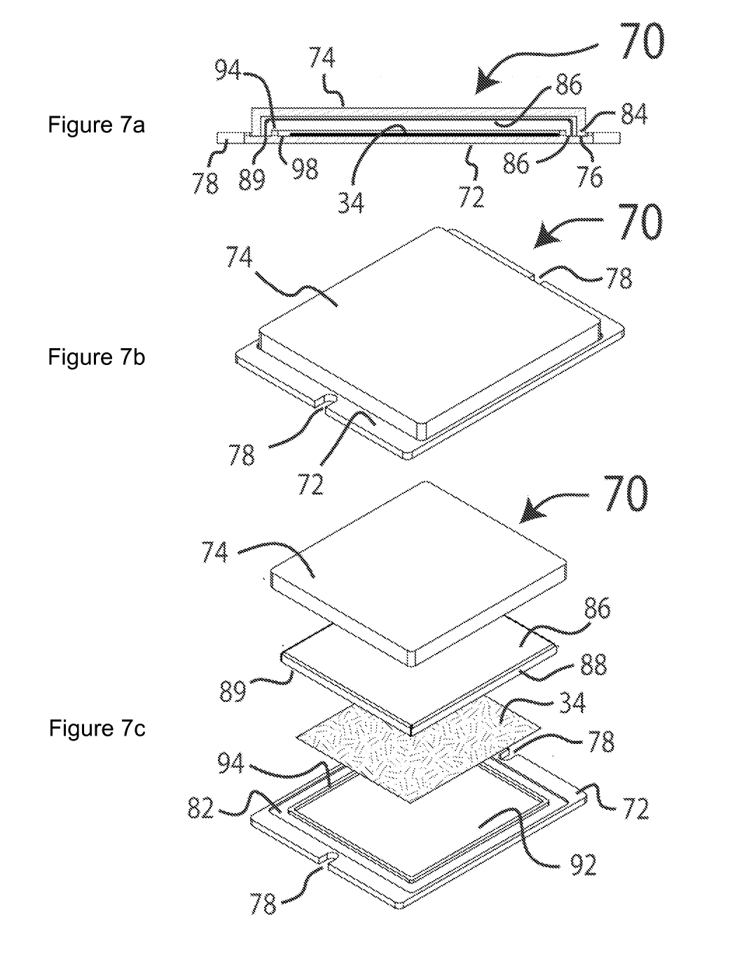

FIGS. 7a-7c shows another embodiment of this invention wherein the primary tool is in the form of the SEB 70 and includes a support plate 72 and a removable lid 74, together forming a quasi-gas-tight seal 76. As needed, lid 74 may be provided with one or more handles, and/or one or more gas ports, as discussed hereinabove with respect to SEB 40.

To aid with the reproducible placement of removable primary tool 70 into the PRC of the respective CVD system, locating features 78 can be added to plate 72, for example, notches 78 which are formed/cut into plate 72. Locating features 78 (e.g., notches, slots, holes, pins) preferentially mechanically engage with matching locating features provided on a support plate located inside a PRC of a respective CVD System, or on an auxiliary transfer arm. To prevent lid 74 from sliding off plate 72 during transport of primary tool 70, optional locating features can be added to the plate 72. As shown in FIG. 7, a countersunk groove 82 may be used to provide this additional locating feature function. In one embodiment of this invention, the bottom of groove 82 and the bottom of rim 84 of lid 74 are machined sufficiently smooth to form a quasi-gas-tight seal 76. The tightness of this seal can, in part, be controlled by the selection of the width of rim 84 and in part by the smoothness of groove 82 and/or the mating surface of rim 84.

An optional liner 86 is shown in FIG. 7. Liner 86 can be folded to form continuous or discontinuous sidewalls 88 having a rim 89. Rim 89 preferably rests within groove 82 inside of rim 84. It is to be understood that the sidewalls 88 can also be discontinuous tabs instead of one or more semi-continuous walls, and that either of these features can also provide mechanical support to reduce the ability of liner 86 to sag and mechanically contacting substrate 34. This implementation of the invention allows full enclosure of substrate 34 with the same material, thereby providing a very uniform vapor environment of sublimed catalytically-active material while also preventing external impurity particles from reaching the substrate surface. It also allows for liner 86 to be a stand-alone part that is self-supporting. This design allows for scale up in size of primary tooling 70 because it reduces the likelihood of liner of sagging, and additionally creates an even more uniform processing environment for substrates that are scaled up in size to greater than 100 mm.

To increase productivity of a given CVD Synthesis process utilizing primary tool 70, it is desirable to prevent optional liner 86 from mechanically contacting substrate 34 at any point during the synthesis process because they can “weld” together, thereby causing mechanical distortions and/or loss of usable area. If substrates 34 are thin foils (10-100 μm), then it is also desirable to reduce/eliminate any impact between the substrate 34 and the side walls 88 or lid 74 during transport. Therefore, in another embodiment of this invention, substrate 34 is optionally confined locally on plate 72 to prevent the substrate from sliding on a substrate support surface 92 of plate 72 during transport of primary tool 70. Plate 72 preferably includes a raised lip 94 on the inside of the groove 82 that can be utilized to perform the same locating function without creating any quality loss during the synthesis process. The smooth continuous walls provided by lip 94 reduce the likelihood of kinking if the substrate contacts such walls during transport of primary tool 70. It is contemplated herein that instead a discontinuous structure can be utilized on plate 72 to locate substrate 34.

In one embodiment of this invention, lip 94 has a height of approximately 0.1-10 mm, preferably a height of 0.5-5 mm, more preferably a height of 0.5-3 mm, and most preferably a height of 1-2 mm. A gap 98 of at least 2-6 mm is provided between the inner edge of lip 94 and the edge of substrate 34, e.g., a 10-150 μm thick Cu or Platinum foil. Preferably, this gap 98 primarily extends in the direction of the long axis of the respective horizontal tube CVD Synthesis system, and preferably also only on one side only of substrate 34. To prevent kinking of substrate 34, the gap between the edge of substrate 34 and the inner wall of lip 98 is greater than the difference in linear thermal expansion at the elevated CVD Synthesis conditions by at least 0.1 mm, more preferably at least 0.5 mm, and most preferably by at least lmm. Gap 98 facilitates the wrinkle-free loading and unloading of the softened substrate after graphene processing, by allowing for the insertion of a flexible and stiff thin plastic or metal sheet underneath the substrate 34 to lift it out of support area 92 surrounded by lip 94. Optionally, additional features can be added to lip 94 and/or support area 98. For example, a small shallow groove in the area 98 near an inner edge of lip 94 can be provided that allows for insertion of a small hook to lift substrate 34 sufficiently in a kink free manner to enable the insertion of the support sheet thereunder. Gas jet or push pin ports can also be used to provide the lift needed to slide a support sheet under substrate 34. Alternatively, a shallow slope can be added to one side (or at least to a portion) of lip 94 so that a suitable tilt of plate 72 allows the substrate to slide out of area 92 without kinking, or the insertion of a narrow support strip underneath substrate 34. In a different alternative embodiment of this invention, a suitably sized, permanent or removable strip with one side sloped can be inserted at location 98 after sliding substrate 34 to the opposite side of support area 92 whereby substrate 34 can then slide over the installed sloped surface and onto a support tray without kinking. In a further implementation of this invention, a countersunk groove is provided in area 98 and is optionally filled with a removable insert tile cut to tight tolerance so that the surface height of area 98 is constant. Such a respective tile can then subsequently be partially raised to provide an in-situ ramp for sliding of substrate out of area 98.

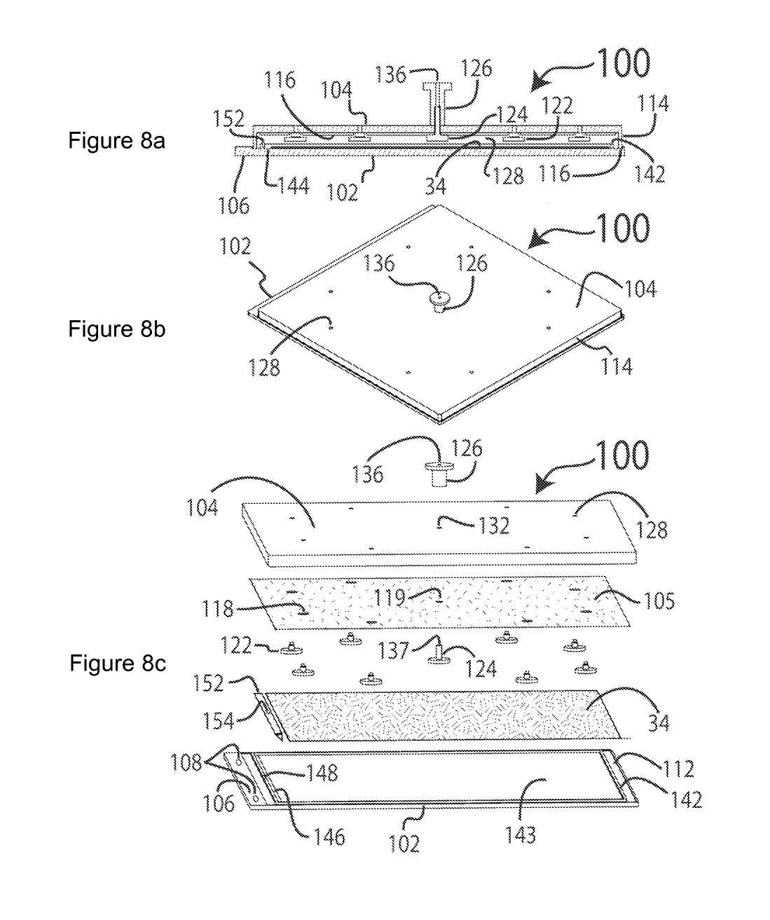

FIGS. 8a-8c show a further embodiment of this invention wherein the primary tool is in the form of the SEB 100 and includes a support plate 102 and a removable lid 104 supporting and enclosing a substrate 34. Plate 102 may include an extended section 106, for example in the long axis of the respective CVD Synthesis system. In this extended section 106, one or more locating features 108 can be added for easy placement onto an auxiliary tool support arm which moves SEB 100 from a loading location to the PRC, and/or as a mechanical interface for a robotic arm. Two elongated holes 108 are provided in the extended section 106, and sized to engage matching alignment pins located on a respective auxiliary transfer arm. The long slot direction of holes 108 accommodates the thermal expansion perpendicular to two transfer arms (e.g., needed to support the higher weight of the larger sized primary tool for a 300 or 450 mm square substrate 34). Other means for locating plate 102 can also be used. In this manner a maximum flat substrate capacity size is achieved for a given sized horizontal tube furnace CVD System.

An optional groove 112 machined into plate 102 provides sufficient location registration for lid 104 during transport, and provides the sealing surface for the quasi-gas-tight seal 116 with the bottom of sidewalls 114 of lid 104. A liner 105 can optionally be located inside lid 104. As discussed hereinabove, liner 105 is preferably designed to reduce any likelihood of sagging during CVD Synthesis. FIG. 8c shows an embodiment of this invention wherein liner 105 has multiple holes 118 which surround a smaller center hole 119, as well as locating/fastening shoulder screws 122 and/or a handle assembly including counter shoulder screw 124 and handle 126. Given the different thermal expansion of lid 104 and liner 105, appropriately oversized holes 118 need to be cut into liner 105 to allow for its different linear thermal expansion. Suitably sized graphite shoulder screws 122 that screw into respective counter sunk or through threaded holes 128 of the lid 104 allow for the liner 105 to freely expand and contract sideways during thermal cycling, thereby preventing it from buckling. The tighter center hole 119 is preferably used to locate liner 105 at the center of lid 104 through its center hole 132, and it is secured in place with shoulder screw 124 and handle 126. In this way, both lid 104 and liner 105 can be moved together with minimal chance of damaging (bending) of the soft annealed liner 105. The shoulder screws 112 and 124 should preferably form quasi-gas-tight seals with lid 104. When additional gas ports are desired, either a central gas port hole 136 and 137 can be made through the handle assembly 124 and 126 to allow a controlled amount of gas into either the spacing between liner 105 and the inner part of lid 104 or directly into SRC 128. Alternatively, additional distributed gas ports can be made through holes in the respective shoulder screws 122 to achieve a more distributed gas entry/exit system. This again can be beneficial when the longest dimension of lid 104 is many times larger than the gap between the substrate 34 and the inner top surface of lid 104. Additional gas ports can be provided as needed across the surface of lid 104. Alternatively, side handles can be added to the lid 104 to minimize the chance of accidental breakage of shoulder screw 124 during transport of heavier, larger lids.

The centering of substrate 34 on plate 102 is shown in FIG. 8a as being done by a raised lip 142 that surrounds a substrate support area 143. Alternatively, lip 142 is selected to be tall enough to nearly reach the bottom part of liner 105. Liner 105 is sized so that in the cold process stage its edges preferably overlap lip 142. An optional clearance on the order of 1-2 mm is typically sufficient in the assembled stage of primary tool 100 depending of the positional location tolerance of lid 104 with respect to lip 142. In this manner, the edges of liner 105 can be prevented from sinking and/or buckling, and the usage of some of the auxiliary mounting means 122 can be reduced or even totally eliminated for small to medium size substrates 34. Alternatively, groove 112 can be replaced with a flat sealing surface, and the location reference of lid 104 to plate 102 can be accomplished via rim 142.

To facilitate the wrinkle free removal of a substrate 34 in form of a metal foil, preferentially in the long direction of a process tube of a respective horizontal tube CVD System, a gap 144 is provided along one wall of lip 142. This wall is optionally formed with a shallow slope 146 on the inside thereof, and at least one locating hole 148 along it. A removable locating bar 152 and locating pin 154 are used to prevent movement of substrate 34 during transport and CVD Synthesis. Bar 152 is removed prior to the removal of the substrate 34 from support area 143 after CVD Synthesis. In this manner, shallow slope 146 is exposed, and can be used to slide the processed substrate 34 over lip 142 and onto a suitable support tray without wrinkling and/or kinking. Alternatively, lip 142 can be made removable, or can be discontinuous to allow access to the underside of substrate 34 via a gas jet or other mechanical means (pin, wire, sheet, foil, etc.) to facilitate lifting of the processed substrate 34 without bending or kinking it.

In another embodiment of this invention, liner 105 is discontinuous and formed of multiple smaller sections (e.g., hexagonal, square or rectangular) with a sufficient gap between them to prevent contact with one another during multiple thermal expansion cycles, but still provide sufficient exposed liner area to be beneficial to a given CVD Synthesis. These sections are either individually mounted by centered graphite shoulder screws 122, or similar fastening structure. In this manner, the size limitation of primary tool 100 is avoided, and can be scaled to match any CVD System available (limited only by the available process tube size).

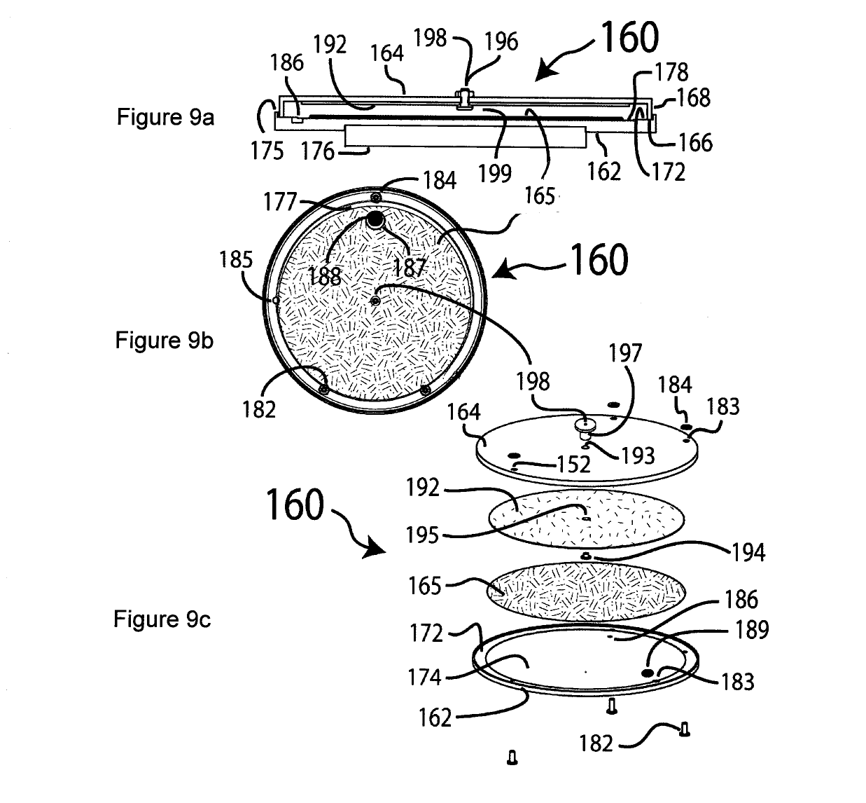

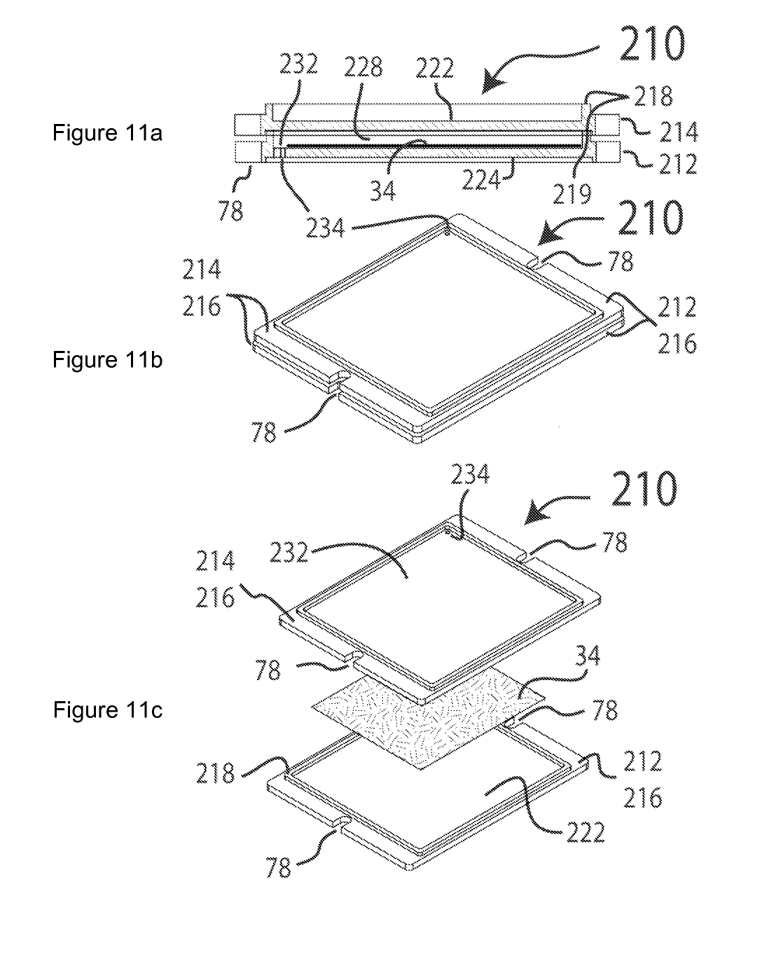

FIGS. 9a-9c show another embodiment of this invention wherein the primary tool is in the form of SEB 160 and includes a plate 162 and an access port in the form of a removable lid 164. Plate 162 and lid 164 support and enclose an optional round-shaped substrate 165 and have a quasi-gas-tight seal 166. For example, such a round substrate 165 can come in the form of a several hundred nm thick Cu or Ni film (e.g., 200-1,000 nm, typically 300-500 nm) that has been deposited on top of a SiO₂ layer (e.g., 500 nm) grown on a 0.15-1 mm thick Si wafer with a wet thermal oxidation process. For example, such substrates 150 can be made with e-beam, ion-assisted e-beam, sputter or electro deposition, or other deposition techniques. Optional additional adhesion layers are deposited between the thermal SiO₂ layer and the respective catalytically-active metal film. For example, a 2-10 nm thick Cr and/or Ti film may be used to increase the adhesion between the metal film and the SiO₂ layer. The SiO₂ barrier layer is necessary to prevent the metal film (e.g., Cu) from alloying with the Si material of the Si wafer. Ion-assisted and/or glow discharge substrate surface cleaning may be done before the thin film deposition of catalyst layer. Oxygen and/or Ar-plasma assisted thin film deposition may be done thereafter to increase the density of the deposited film. Other plasma-assisted gas processing steps can be used to change the hydrophobicity and/or hydrophilicity of the surface of substrate 34 prior to deposition of the catalyst layer.

Rim 168 of lid 164 contacts plate 162 at a mating surface 172, thus forming a quasi-gas-tight seal 166. Plate 162 can have a countersunk substrate support area 174 at its center or such area 174 may be surrounded by a raised lip, which locates substrate 165. A lip 175 can be used to locate the rim 168 on plate 162. An optional locating feature 176 (not detailed in FIG. 9) can optionally be attached to the back side of plate 162 (e.g., a T-shaped bar can be attached to plate 162), either by welding (for example, if made from quartz) or by screws going into blind holes on the back size of the plate 162 (if made from graphite or other material). The area 174 is preferably oversized, resulting in a gap 178, which allows for unblocked thermal expansion of substrate 165 during the heating and cooling process steps. The incorporation of locating feature 176 (e.g., a mounting bracket) allows SEB 160 to have any orientation, including vertical.

FIG. 9b shows SEB 160 mounted with location feature 176 in a vertical orientation. Plate 162 and lid 164 are in this case held together by three screws 182, holes 183 and matching nuts 184 so that the orientation change of SEB 160 does not change the quasi-gas-tight seal 166. As FIG. 9b shows, round substrate 165 slides towards bottom screws 182, and the offset 177 is the cold stage asymmetric location of substrate 175 in area 174. In addition, an optional locating feature 185 (e.g., a shoulder screw to allow for thermal expansion) that connects to a matching feature 186 (e.g., a threaded blind hole) in plate 162 is used to locate the substrate 175 in area 174 so that it is not displaced if SEB 160 is vertically oriented. FIG. 9b also shows the additional functionality of this invention where the round substrate 165 is a flexible foil that can be hung vertically thorough a hole 187 in the foil, for example through a locating feature 188 (pin) with matching hole (locating feature) 189 in plate 162.

SEB 160 is shown in FIGS. 9a and 9b with a flat liner 192 that is secured to the center of lid 164 via holes 193, 195, a screw 194, and a nut 196 that can also be replaced by a handle 197 (FIG. 9c) for easy manipulation of lid 164 and of liner 192. Handle 197 can also include a gas port 198 to allow, together with additional optional distributed gas ports, the controlled entry of gases inside SRC 199 enclosed by plate 162 and lid 1604. As discussed above, various location features can be used to prevent liner 192 from contacting (sinking) onto substrate 165.

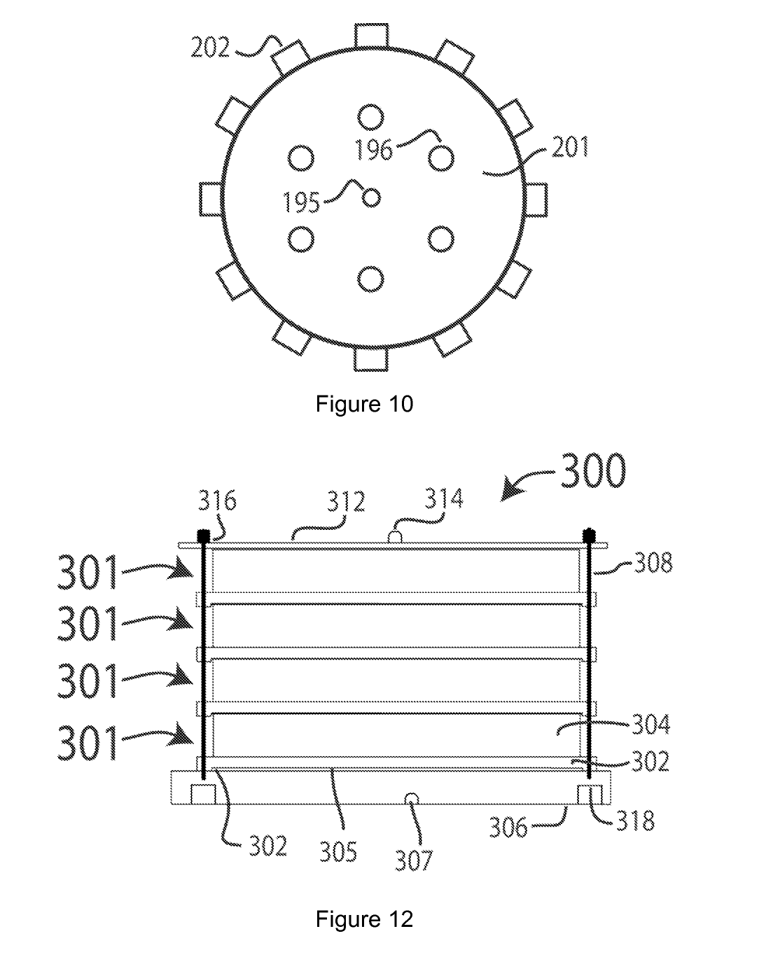

FIG. 10 shows a different embodiment of this invention wherein liner 192 is replaced by liner 201 that is cut from a sheet, e.g., Cu sheet, in such a manner that mechanical discontinuous side walls, i.e. support tabs 202, are formed after bending them 90° to form “legs” or stand-offs to prevent the sinking of the edges of liner 201 onto substrate 165. Additional optional mounting holes 196 are also shown that can be used to support the flat section of liner 201 from sagging during the CVD Synthesis if the distance between the center support hole 195 and the corner of the tabs 202 is too large to support the weight of the soft annealed liner.

FIGS. 11a-11c show another preferred embodiment of this invention wherein the primary tool is in the form of SEB 210, and includes a plate 212 and a lid 214, which are actually identical components having the form of the dual function tray 216. Tray 216 has on its top side a raised lip 218 enclosing the countersunk substrate support area 222, and on its bottom side a countersunk pocket 224 that is slightly larger than the external dimensions of lip 218 so that one tray 216 can be stacked on top off another tray 216 and with lip 218 of one tray 216 forming a quasi-gas-tight seal 219 with the top surface of the countersunk pocket 224 of another tray 216, so that essentially both trays 216 are horizontally aligned with each other, and together form a quasi-gas-tight sealed SRC 228 surrounding substrate 34.

In an alternative embodiment of this invention (not shown in FIG. 11), a liner is placed on the inside of lip 218 over an additional shorter and smaller secondary rim structure (e.g., multiple posts) which at least partially encloses the area 222 and isolates the substrate 34 from contacting any parts of such liner. Such a liner can be self-standing, i.e., resting on legs made from bent continuous or discontinues sidewalls and/or side tabs (see FIG. 10), and/or can have a corrugated top surface or other stiffening structure along its top surface so that it does not sag onto the substrate 34 after CVD Synthesis, and/or can simply rest on the secondary rim.

Experiments conducted with graphite versions of primary tool 210 with a 2 mm tall lip 218 showed higher quality CVD graphene growth on Cu-foil (despite not using a liner) when compared to the foils shown in FIG. 1. CVD Synthesis quality improvements over prior art CVD Systems were also obtained by using a quartz-based tray 216 with Cu-foils. In another embodiment of this invention, one tray 216 is closed with a flat top plate with lip 218 of tray 216 forming a quasi-gas-tight seal with the bottom surface of respective top plate.

While certain concepts are specifically addressed with respect to the embodiment of FIG. 11, it is to be understood that such concepts can be applied to the other SEB discussed herein. The size of substrate 34 with respect to the lateral dimensions of SRC 228 are preferably chosen to accommodate the thermal expansion difference between trays 216 and substrate 34, and the wrinkle free removal of the substrate. For example, for a 300 mm long substrate, the thermal expansion difference between the substrate and the tray (including manufacturing tolerances) require a difference between support area 222 and substrate 34 of 4-7 mm in each direction, which is typically sufficient for wrinkle free removal of the substrate when lip 218 has a height on the order of 0.5-4 mm. On the other hand, if substrate 34 is too short to have a thermal expansion on the order of 5 mm, then in another embodiment of this invention, the lip 218 is preferably at least 4-7 mm larger in one direction than the long direction of the substrate 34 to allow wrinkle free removal of the substrate 34.

An optional small hole 234 (e.g., 1-5 mm diameter) may be drilled through tray 216 or plate 212, e.g., near one of the inside corners of the rim 218 so that a small pin, wire or gas jet (continuous or pulsed) can be activated from underneath the plate 212 to gently lift one edge of the processed substrate 34 sufficiently high above lip 218 so that it can be picked up with a support sheet (“shovel”) and removed. Alternatively (not shown in FIGS. 11a-11c), several small blind holes can be made close to the inside edge of lip 218, for example along one side, or along two neighboring sides, or along all sides of lip 218 to lift the substrate 34 with an air flow from underneath where it can then be picked up by a side moving paddle, perforated screed, etc.

In a further embodiment of this invention, a flipper plate with a non-stick surface (e.g., Teflon or equivalent PTFE material) can be positioned over the plate 212. Flipping both together in the horizontal axis allows substrate 34 to land on the flipper plate without wrinkling or kinking, thus allowing empty plate 212 to be removed. If top CVD graphene material access is desired, a transport plate can be moved into proximity to the upside down substrate 34 (now positioned on the flipper plate) and by performing another flipping operation, the substrate 34 lands on the transport plate in the desired orientation. Preferably, some location features (a countersunk area, a lip surrounding a part of the substrate, etc.) are built into such a flipper and/or transport plate to prevent the substrate from sliding/moving during the flipping and/or transfer operation. Such an offloading method, which is enabled by the readily removable lid and/or accessible open tray, enables an optional robotic offloading of any size flat substrate from a respective support surface area without kinking, and therefore enables unlimited scalability of the substrate size (only limited by a given size process chamber for a respective CVD System).

FIGS. 11a-11c show an additional external locating feature, namely notches 78, that can be used to secure SEB 210 to a respective transfer auxiliary tool and/or to facilitate robotic handling and/or stacking of tray 216. They can also be used for tying multiple trays 216 together into a single block and for other proposes as desirable for manufacturing productivity increases. The gap between trays 216 allows for easy grasping of the top tray with a specialized tool, Such a gap can optionally be increased in selected areas around the edges of the tray outside of lip 218 for easier and quicker separation and loading/offloading of top tray 216.

With respect to primary tool 210, the height of lip 218 controls the height of SRC 228, and it is preferably chosen to be 0.25-10 mm taller than the top surface of the substrate 34 located on area 222, to minimize both the height of the SEB 210 and therefore of the volume of SRC 228 so that any subliming vapors from the substrate 34 have to fill only a small cavity and thereby have a relatively higher quantity of catalytically-active material in gas form nearby the surface of substrate 34 than possible with the prior art open primary tools. The height of SRC 228 is preferably also chosen to allow substrates 34 which are not perfectly flat to sit inside the SRC 228 without contacting the top part of the pocket 224 to minimize any possible local contamination and/or degradation of graphene quality/type uniformity across the substrate. Cu foils, for example, even after they have been cut from a roll, sometimes still have some bow, so that a taller SRC 228 could be designed to allow contact-free processing of such bowed substrates.

### Primary Tools in the Form of an SEB Stack Enclosing Multiple Substrate Support Areas

This portion of the specification is directed to additional embodiments of the present invention wherein the primary tool is in the form of a SEB stack. Given that a SEB is typically much shorter than it is wide or tall, vertical and/or horizontal stacking multiple SEBs allows a better utilization of a round process tube volume of a given CVD System. When used as a primary tool for a respective CVD System, an optimized SEB stack can therefore achieve a productivity gain of 5-10× over a single SEB. Because each SEB is quasi-gas-tight sealed, each respective substrate support area is exposed to substantially identical processing conditions. SEB stacks enable the manufacturing of CVD graphene films and other equivalent few atomic layer thick materials in parallel. This enables processing of multiple substrates in the same batch, thereby increasing the productivity of a given CVD Synthesis system.

FIG. 12 shows a further embodiment of this invention with a primary tool in the form of SEB stack 300, which includes a vertically aligned stack of SEBs 301, each having a plate 302 and a lid 304. Plate 302 is shown with an optional countersunk pocket 305, preferably sized to receive and mechanically register with lid 304, thus preventing one SEB 301 from sliding with respect to another SEB 301 during transport and CVD synthesis. Pocket 305 can be formed with a tapered edge 302 or with a sharp corner. The tapered pocket style allows for tighter self-alignment tolerances of the SEB stack, and in one embodiment of this invention all pockets 305 are formed with a tapered edge 302 having an angle in the 92°-140° range.

Horizontally aligned stacks which, for example can be accomplished with minor design changes from SEB 160, are also contemplated herein.

SEB stack 300 is shown in FIG. 12 positioned on an optional support plate 306. Plate 306 is preferably provided with locating features 307 to provide easy registration with auxiliary tools of a respective CVD System, for example, for robotically transporting a stack 300 into and out of its PRC, and/or to locate the stack 300 onto a respective transfer arm, and/or to be able to stack multiple SEB stacks 300 on top off or next to each other. Rods 308 (or other equivalent parts) may be used to engage with the respective locating features of SEBs 301 (e.g., alignment notches 78), and to hold SEB stack 300 together during transport and processing. Rods 308 are preferably connected at one end to plate 306 and at the other end to a top support plate 312 with screws or nuts or handle 316. Support plate 312 may also include a locating feature 314. SEB stack 300 is especially suitable for fast robotic loading/unloaded of many substrates simultaneously to/from the CVD System, and for transport to/from a respective loading station. If multiple SEB stacks 300 are to be stacked on top of each other to enable a higher batch size, it is preferred that the plate 306 has respective cutouts 318 and location features to interact properly and securely with the opposite end of SEB stack 300. Cutouts 318 and location features 307 and 314 are preferably designed to take into account the thermal expansion of each component of SEB stack 300.

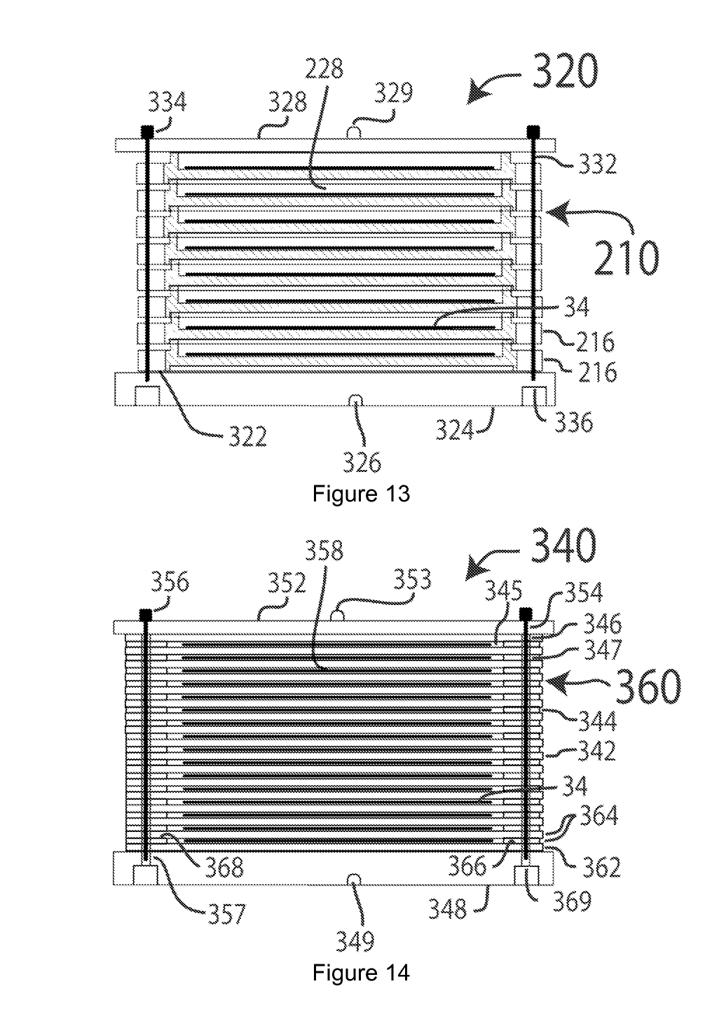

FIG. 13 shows another embodiment of this invention, wherein the primary tool is in the form of SEB stack 320 that is primarily assembled from a series of dual functional, self-stacking, low profile trays 216, with two adjacent trays 216 forming SEB 210 with respective SRC 228 for each respective substrate 34. Because less height is needed for a given size SRC than with the SEB 301 design, a higher density SEB stack 320 can be made that is able to process more substrates for a given process tube, and that has less weight and mass per SEB than the SEBs 301 used for SEB stack 300. These primary tool design choices therefore allow targeted applications to be pursued without any significant or permanent changes to the CVD System, and typically without being required to choose between quality and productivity.

In another embodiment of this invention, as shown in FIG. 13, a SEB stack 320 is assembled from a multitude of SEBs 210 (see also FIGS. 11a-11c) with each tray 216 functioning as a plate and as a lid for two adjacent SRCs 228, except for the first and last one. The resulting SEB 320, while typically oriented in a vertical direction, can be oriented in any direction the substrate 34 inside each respective SRC 228 can handle. For vertical operation, additional locating features can be added to the respective tray 216, e.g., to either secure a wafer style rigid substrate in each SRC 228 or by providing a hole through each tray allowing to push a rod through the vertical SEB stack, one SEB stack at the time, to allow the hang-mounting of round foils or wafers with a punched out or core drilled out hanging hole 187 (see FIG. 9 or equivalent) for each SRC and the sequential loading/unloading of a horizontal oriented SEB stack 320 having a round, square, rectangular, etc. substrate then viewed from the top side. An optional locating plate 324 with optional locating features 326 can be used on which all the trays 216 can be stacked. The last tray 216 can either be left empty or sealed by a top plate 328 with optional locating features 329. Plates 324 and 328 provide quasi-gas-tight seal with respect to any respective push holes 234 in trays 216 and have optional locating features 326 and 329 to provide easy registration with the auxiliary tools of a respective CVD System, for example for transport robotically into and out of the PRC of a CVD System and/or to locate it (manually or robotically) onto a respective locating support mechanism inside the process tube. Rods 332 (or other equivalent structure) may be used to engage the respective locating features of trays 216 (e.g., alignment notches 78), and hold SEB stack 320 together during transport and processing. Rods 332 are preferably connected at one end to plate 324 and at the other end to a support plate 328 with screws or nuts or handle 334. If multiple SEBs 320 are to be stacked on top of each other to form a primary tool with a larger batch size, it is preferred that plate 324 includes cutouts 336 and/or location features 326 that interact properly and securely with the opposite end of SEB stack 320 which includes components 334, 328, and 329.

FIG. 14 shows a high density SEB stack 340 of this invention wherein flat trays 342 (no raised lips or pockets) stacked on top of each other are separated by a flat spacer frame 344. Each tray 342 has a respective flat substrate support area holding at least one substrate 34. The spacer frame 344 has a center cutout 345 that is larger than the substrate 34 (large enough to allow for thermal expansion of the substrate 34). Both trays 342 and spacer frames 344 have one or more cooperating locating features 346 and 347 (holes, slots, notches, etc.) outside cutout area 345. The resulting alternating stack is then sandwiched by a bottom support plate 348 (with optional locating features 349) and a top support plate 352 (with optional locating features 353). These plates 348 and 352 are preferably held together by at least two rods or bars 354 that go through respective locating features 346 and 347, and through locating features 357 in support plate 348, and are secured with screws, nuts and or handles 356, thus holding the whole vertical array of trays 342 and spacer frames 344 together in a predetermined aligned spatial arrangement, thereby forming SEB stack 340. The SRC 358 of the respective SEB 360 that surrounds each substrate 34 is defined by a tray 342 acting as a plate 362, and the combination of spacer frame 344 and adjacent tray 342 acting as respective lid 364. In other words, the height of SRC 358 is solely determined by the height of the chosen spacer frame 344. The quasi-gas-tight seal for SEB 360 is formed in this case by the top and bottom surfaces of two trays 344 sandwiching a spacer frame 344, and can be controlled by the flatness and width of the respective overlapping contact areas 366 and 368 and by the pressure applied through the nuts 356.

In one preferred embodiment of this invention, the thin sheet material(s) used to manufacture trays 342 and/or spacer frame 344 is selected from a list including a quartz sheet, carbon film coated quartz sheet, carbon-carbon composite sheet, a graphite sheet, a 100-1000 μm thick GRAFOIL® sheet, an eGraf™ SPREADERSHIELD™, an eGraf™ HITEMR™ thermal interface material (manufactured by GrafTech International Holding Inc.), a 20-200 μm thick pyrolytic graphite sheet (PGS) manufactured by Panasonic), and a nano carbon sheet (ncSheet™ manufactured by CVD Equipment Corporation). The thickness and sheet material of trays 342 and spacer frames 344 do not have to be identical and can be optimized for a given CVD graphene manufacturing task and substrate size. Preferably, the additional location features 369 and 349 cooperate with location features 353 and 356 to allow stacking of such SEB stack 340 when needed.

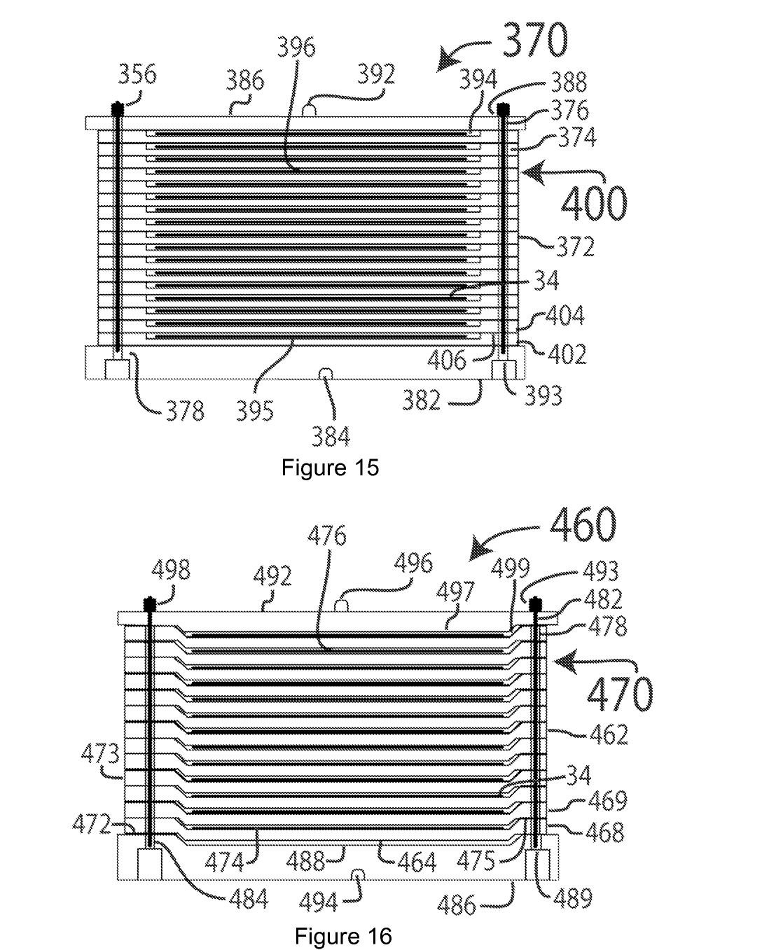

FIG. 15 shows another embodiment of this invention in the form of high density SEB stack 370, which is assembled from a stack of countersunk trays 372 with locating features 374. The resulting stack is then optionally sandwiched between a bottom support plate 382 (with optional locating features 384) and a top support plate 386 (with optional locating features 392). Plates 382 and 386 are preferably held together by at least two rods or bars 376 that go through respective locating features 374, and through locating feature 378 in support plate 382, and are secured with screws, nuts and or handles 388, thus holding the whole vertical array of trays 372 together in a predetermined aligned spatial arrangement, thereby forming SEB stack 370. Preferably, the additional location features 393 and 384 cooperate with location features 356 and 392 to allow stacking of multiple SEB stacks 370 when needed. Each tray 372 has a countersunk oversized pocket 394 with a bottom surface having a substrate support area 395 holding one or more substrates 34. A respective SRC 396 is limited by pocket 394 and the bottom surface of the adjacent tray 372. Each individual SEB 400 is therefore formed by a first tray acting as a plate 402 and an adjacent tray acting as a lid 404. The overlapping surface areas between the two adjacent trays form the respective quasi-gas-tight seal 406. Trays 372 are preferably made from GRAFOIL® material that has a high in-plane thermal conductivity and is compressible to form the countersunk pocket 394. In an alternative embodiment of this invention, trays 372 are manufactured from carbon-carbon-composite in a net shape. Because trays 372 can manufactured with a relatively small height dimension (e.g., 100-3000 μm) a high density SEB stack 370 can thus be achieved.

FIG. 16 shows another embodiment of this invention in the form of a high density SEB stack 460, which includes a vertical stack of trays 462 that is similar to the embodiment shown in FIG. 15 except that the bottom surface 464 of trays 462 is lower than the bottom surface 472 of its outer edge flange 473. Again the wall thickness of the countersunk pocket holding the substrate 34 is less than the wall thickness of flange 473 thereby defining a substrate-supporting pocket 474 between each adjacent stacked tray 462. An SRC 476 is defined between the bottom surface of pocket 474 and the bottom surface of the adjacent tray 462. Each individual SEB 470 is therefore formed by a first tray acting as a plate 467 and an adjacent tray acting as the lid 468. The overlapping top 475 and bottom 472 surfaces of flange 472 of the two adjacent trays 462 form the respective quasi-gas-tight seal 469. By changing the thickness of the edge flange 473 the volume of SRC 476 can be varied as desired.

The stack of trays 462 is preferably sandwiched between a bottom support plate 486 and a top support plate 492 with optional locating features 494 and 496. The stack is preferably held together by at least two rods or bars 482 that go through respective locating features 478 and that cooperate with locating feature 484 in support plate 486 and are secured with screws, nuts and or handles 498, thus holding the whole vertical array of trays 462 together in a predetermined spatial arrangement, thereby forming SEB stack 460. Preferably, the additional features 489 and 494 cooperate with features 496 and 498 to allow stacking of such SEB stack 460 when needed. A transition area 499 between area 474 and 475 is preferably sloped for easier manufacturing of the respective trays 462, and to provide automatic self-centering of the stacked trays 462. In one embodiment of this invention, trays 462 are fabricated from a carbon-carbon composite material or machined from graphite and purified with respective high temperature treatment and the wall thickness of flange 473 is between 0.5 and 10 mm.

### Primary Tools in the Form of a Open Tray Stack Enclosing Multiple Substrate Support Areas

This portion of the specification is directed to additional embodiments of the present invention wherein the primary tool is in the form of an open stack of trays, with each tray providing a flat substrate support area suitable for loading one or more substrates. This implementation of this invention enable further production capacity increases for a given CVD Synthesis.

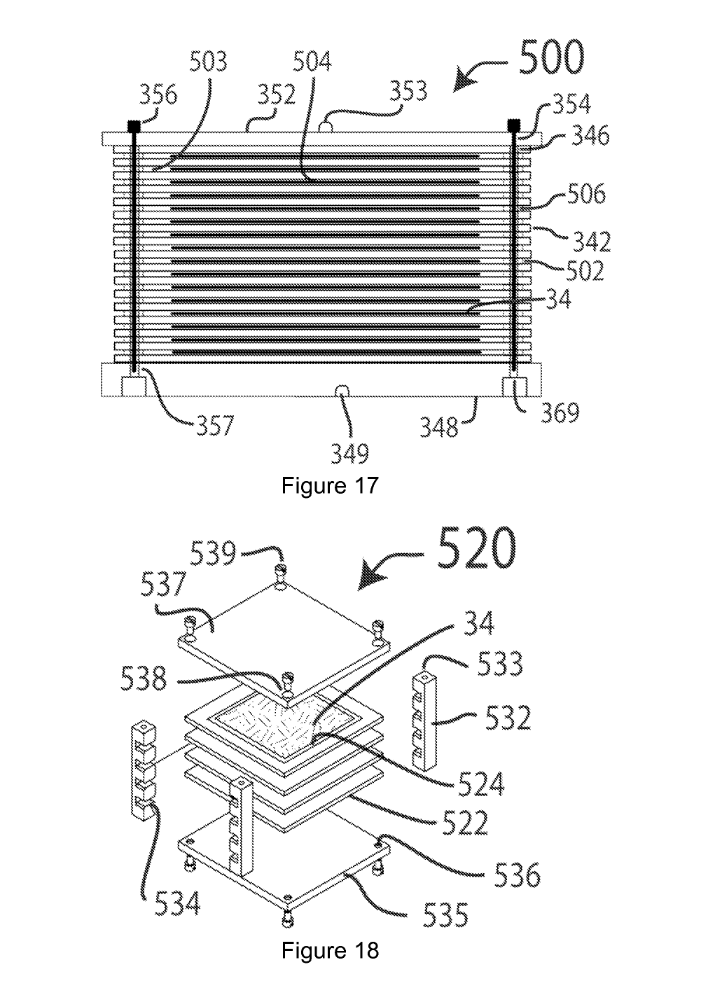

FIG. 17 shows an open tray stack 500 that is similar to the SEB stack shown FIG. 14, but wherein small spacer washers 502 are used to separate trays 342, with each tray 342 having a flat substrate support area supporting at least one substrate 34. One or more gaps 503 between the various spacer washers 502 laying on the same tray 342 allow substantially unrestricted gas exchange between the outside environment of tray stack 500 and an open SRC 504 defined as the volume between two adjacent trays 342 enclosed by the washers 502 separating them. In other words, each substrate 34 in each SRC 504 is connected to the outside process environment of the tray stack 500 trough one or more gaps 503 in parallel, and is therefore simultaneously exposed to similar process gas environment. This design thus provides one of the highest packing densities of substrates 34 (with minimum tooling weight) for a given process volume. The height of washer 502 separating each tray 342 is preferably chosen to provide a uniform process gas environment through gaps 503 across the whole substrate 34. Washers 502 preferably have a height of approximately 0.03-10 mm. Larger-sized substrates 34 may require thicker and/or stiffer trays 342 and thicker washers 502 to obtain uniform CVD Synthesis across the substrates 34. The insides of washers 502 perform a location function by enclosing substrate 34 to limit inadvertent sliding on tray 342. In one preferred embodiment of this invention, the material used to manufacture trays 342 and spacer washers 502 is a discussed for stack 340 in FIG. 4. Spacer washers 502 can also be made from a porous material thereby increasing the process gas exchange between SRC 504 and the outside process environment of tray stack 500.

Tray stack 500 preferably includes rods or bars 354, which extend through locating features 346 located on trays 342, and through apertures 506 of washers 502. One end of rod 354 cooperates with locating features 357 provided on plate 348, while the other end cooperates with screws, nuts or handles 356 and plate 352 to provide an open tray stack 500 with each tray 342 having a at least one predetermined gap 503. Optionally, the height of each gap 503 varies in a predetermined manner along the stack to improve process uniformity for each SRC 504. Screws or nuts or handles 356 may also be used to compress open tray stack 500 to control the height of the gaps 503 between each tray 342 pair.

FIG. 18 shows an exploded view of an open tray stack 520, which includes a stack of trays 522. Each tray 522 includes a substrate support area 524 where at least one substrate 34 is located. Area 524 may be defined by a surrounding lip, or may be countersunk into the surface of tray 522. The trays 522 may be spatially arranged via an open frame structure, which includes spacer bars 532 having treads 533 and multiple horizontal slots 534 (at least one for each tray 522), a base support plate 535 having apertures 536, and a top support plate 537 having apertures 538. Screws 539 (or other temporary or permanent connecting means, for example welding) may be used to connect plates 535 and 537 via spacer bars 532 as to form an open rigid frame structure into (from) which trays 522 can be easily inserted (removed), thus providing a predetermined spatially-arranged open tray stack 520. The gap formed between each pair of adjacent trays 522 and between each adjacent bar 532 allows parallel process gas exchange to the external environment of the tray stack 520 for each substrate 34.

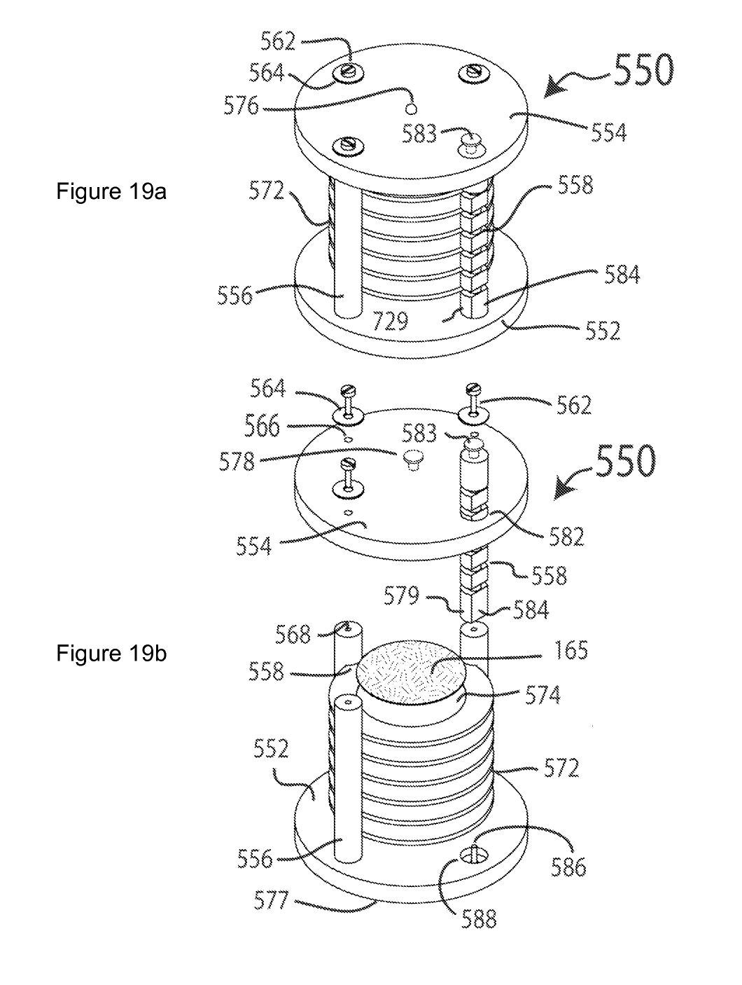

FIGS. 19a-19b show a round open tray stack 550, which includes a bottom support plate 552, a top plate 554, three spacer bars 556 having slots 558, and a removable non-round rod 579 also with slots 558. Bars 556 are preferably secured to plates 552 and 554 in at least a semi-permanent way (welded if made from quartz, or if made with graphite or other not easily weldable material, secured with screws 562 and optional washers 564 through apertures 566 in plates 554 and 552 into threads 568 of bars 556), thus forming an open shelf holder with predetermined shelf spacing gaps into which trays 572 can be inserted, and with trays 572 having optional lips or countersunk pockets 574 for locating substrates 165. FIG. 19 shows the example of round trays 572 and substrates 165, but other types, e.g., polygonal shaped trays, can be used equivalently. Plate 554 has an optional locating feature 576 on its top side, which cooperates with a matching optional locating features 577 positioned at the bottom of support plate 552. Locating feature 576 can also take the form of handle 578. The loaded trays 572 are secured by rod 579, which is removable, and enters/exits plate 554 through hole 582 and which has an optional top handle 583. Rod 579 includes a flat side 584 that allow it to be inserted from the top next to a loaded tray stack and is optionally located at plate 552 via a locating pin 586 and countersunk hole 588 (or equivalent mechanical structure). Rotating the fully inserted rod 579 180° allows it to lock the trays 572 in place during transport and synthesis. The gap between rod 579 and adjacent rod 556 or two adjacent rods 556 and between two adjacent trays 572 form a respective gap through which each substrate 165 is in parallel communication with the process gas environment outside of open tray stack 500.

### Primary Tools in the Form of a TEB Stack Enclosing Multiple Substrate Support Areas

This portion of the specification is directed to additional embodiments of the present invention wherein the primary tool is in the form of a single TEB that encloses and supports an open stack of trays. Each TEB is a quasi-gas-tight sealed enclosure box with an access port for loading/unloading the open tray stack, surrounding and supporting at least one open tray stack in open communication with the ESRC of the respective TEB so that all the substrates have parallel access to the ESRC (as compared to a SEB stack wherein each substrate support area is individually sealed in a quasi-gas-tight manner). This design enables further production capacity increases, and/or uniformity increases in the outcome of the CVD Synthesis.

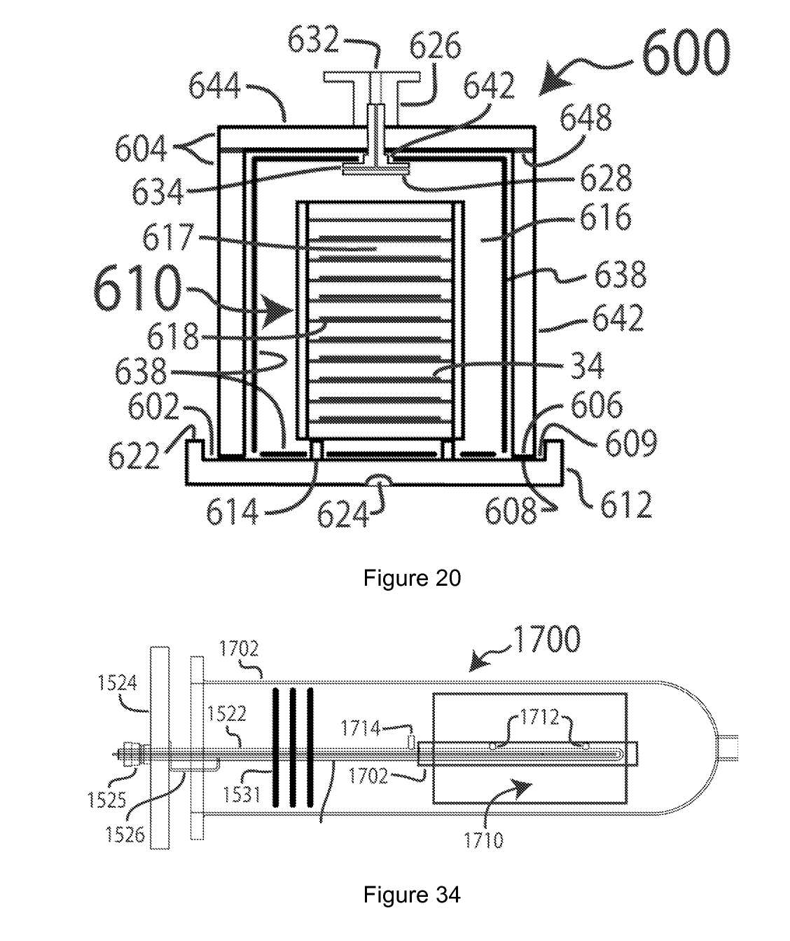

FIG. 20 shows another embodiment of this invention, wherein the primary tool in the form of a TEB 600 has an access port in the form of a removable tall lid 604. Lid 604 includes a bottom rim 606 that forms a quasi-gas tight seal 608 with a mating surface 609 of a bottom support plate 612, thereby allowing for the ready and repeatable loading (and unloading) of an open tray stack 610 to (from) plate 612 having a reference location feature 614. The inside volume of TEB 600 forms ESRC 616, which is in parallel communication through a gap 617 with each substrate 34 located on trays 618 of tray stack 610. Lid 604 is optionally located with respect to plate 612 via one or more locating features, e.g., lip 622 to facilitate transportation of TEB 600. Plate 612 preferably includes locating feature 624 to facilitate registration of TEB 600 with an auxiliary transfer arm and/or loading/unloading station. An optional handle 626 can be welded to lid 614 or attached to lid 614 through a screw 628 to facilitate the manipulation of lid 604. An optional gas port 632 can be included in handle 624, with at least one internal gas channel 634, to allow controlled gas exchange with reduced exposure to eternal nano particles between the inside and outside of TEB 600, i.e., between the PRC of a respective CVD Systems and ESRC 616. For a larger size TEB 600, additional gas ports can be distributed over the outside surface of lid 604, with or without nano particle filters as needed for obtaining a more uniform process outcome for each substrate 34. One example of such optional nano particle filters is a porous nano carbon paper manufactured by CVD Equipment Corporation from either 100% mm long vertical aligned carbon nano tubes (CNT) and/or from a mixture of CNTs with other nano carbon material, e.g., exfoliated graphite, chemical or gas phase derived graphene, activated carbon, carbon fibers, etc.

FIG. 20 also shows an optional liner 638, which encloses ERIC 616. One portion of liner 638 is shown attached to plate 612 with cutouts for location features 614 to provide more thermal isolation from plate 612 for a more uniform thermal distribution throughout stack 610. The other portion of the liner 638 is shown as a single part that substantially encloses the inner walls of lid 604 and is mounted to lid 604 with a shoulder screw 628 (or other fastening means) with sufficient clearance cut-out 642 near the shoulder screw to minimize warpage of liner 638 during thermal cycling due to the difference thermal expansion between liner 638 material and the material used to form lid 604. In this manner, liner 638 stays is protected during handling of lid 604 and of tray stack 610. Because space saving is less of an issue with TEB primary tooling designs than with SEB primary tooling designs, appropriate mechanical structure can be chosen to provide sufficient stiffness and durability to liner 638 when moving lid 604 and loading and unloading the stack 610 repeatedly. Liner 638 provides an additional quantity of catalytic material that is available in gas form in parallel to all substrates 34 during CVD Synthesis without polluting the PRC of a CVD System in any significant manner.

An additional option is shown in FIG. 20 wherein lid 604 (and optionally the top portion of liner 638) is assembled from at least two parts, i.e., a side wall structure 642 and a top plate 644, with both components 642 and 644 sealing together at the respective mating surfaces with the quasi-gas-tight seal 645. In a further embodiment of this invention, an access port is formed by removing top plate 644 from sidewall structure 642. This enables thereafter lifting or lowering tray stack 610 with respect to plate 612 while the side wall structure remains attached to plate 612 and the respective bottom seal 608 remains intact. If a liner 638 is used, only the portion of the liner attached to top plate 644 is removed and the portion covering the side wall structure 642 stays in place.

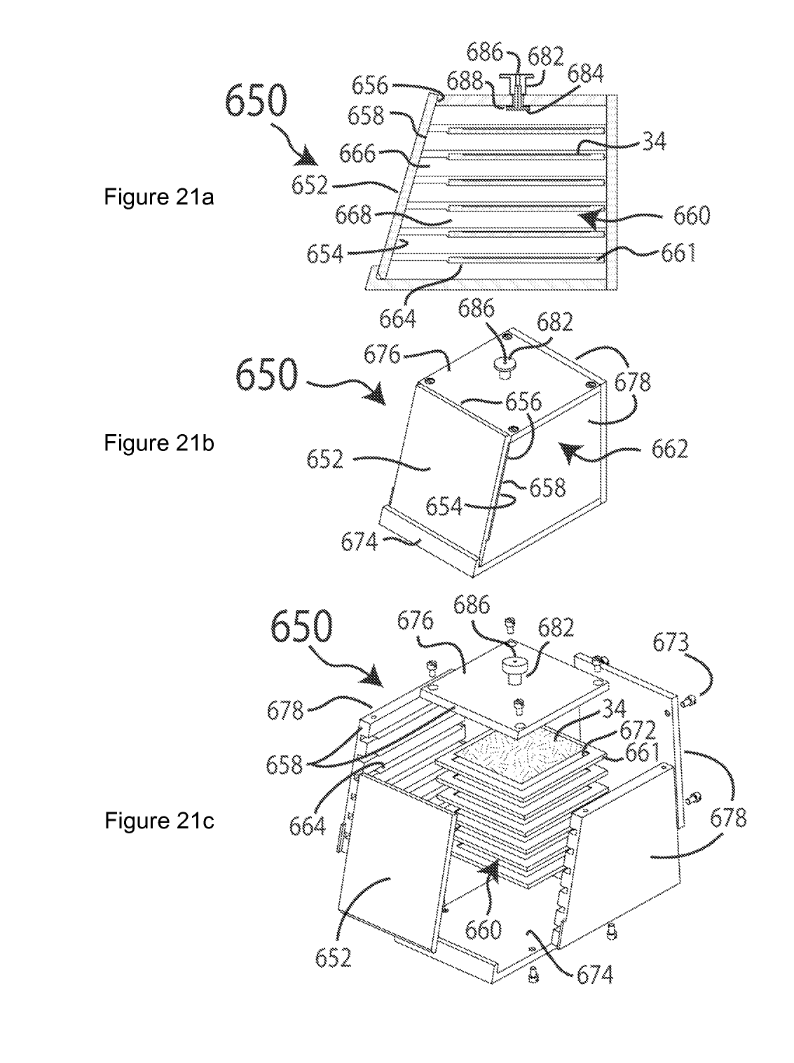

FIGS. 21a-21c show another embodiment of this invention wherein the primary tool is in the form of a TEB 650 having an access port in the form of a side door 652. Side door 652 includes a contact surface 654 that forms a quasi-gas tight seal 656 with a mating surface 658 of a support wall structure 661. Side door 652 allows for the ready loading and unloading of a plurality of individual trays 662 which together form an open tray stack 660. Support wall structure 661 preferably provides a location function, i.e., grooves 664, that locate each tray in a predetermined spatial arrangement with respect to each other and with respect to the TEB 650. The inside volume of TEB 650 forms the respective ESRC 666, which is in parallel communication through a plurality of front (or front and back) gaps 668 with each substrate 34. Each substrate 34 is preferably located inside a countersunk pocket (or lip surrounded area) 672 having a respective substrate support area formed in tray 662. Support wall structure 661 is preferably assembled in a semi-permanent way (e.g., with screws 673) from multiple plates including a bottom support plate 674, a top plate 676 and three side walls 678 in a quasi-gas-tight sealed manner. An optional handle 682 can be attached to top plate lid 676 via a screw 684 (or via a welding process) to facilitate the transport of TEB 650. Additionally, an optional gas port 686 can be included in handle 682 with at least one inside gas channel 688 to allow controlled gas exchange between the inside and outside of the TEB 650, i.e., between the PRC of a respective CVD Systems and ESRC 666. Additional gas ports can also be distributed over the outside of TEB 650 with or without nano particle filters as needed for obtaining a more uniform process outcome for each tray.

FIGS. 21a-21c show the option where side door 652 is gravity sealed along a sloped contact surface, thereby defining a quasi-gas-tight sealed enclosure box with ESRC 666. In an alternative embodiment of this invention, side door 652 is configured to extend perpendicular to bottom support plate 674, and is closed with screws and/or weights and/or with gaskets. In a further embodiment, a standalone open tray stack (e.g., 520 or 550) is put inside a rectangular shaped TEM 650, preferably with location features on base support plate 674.

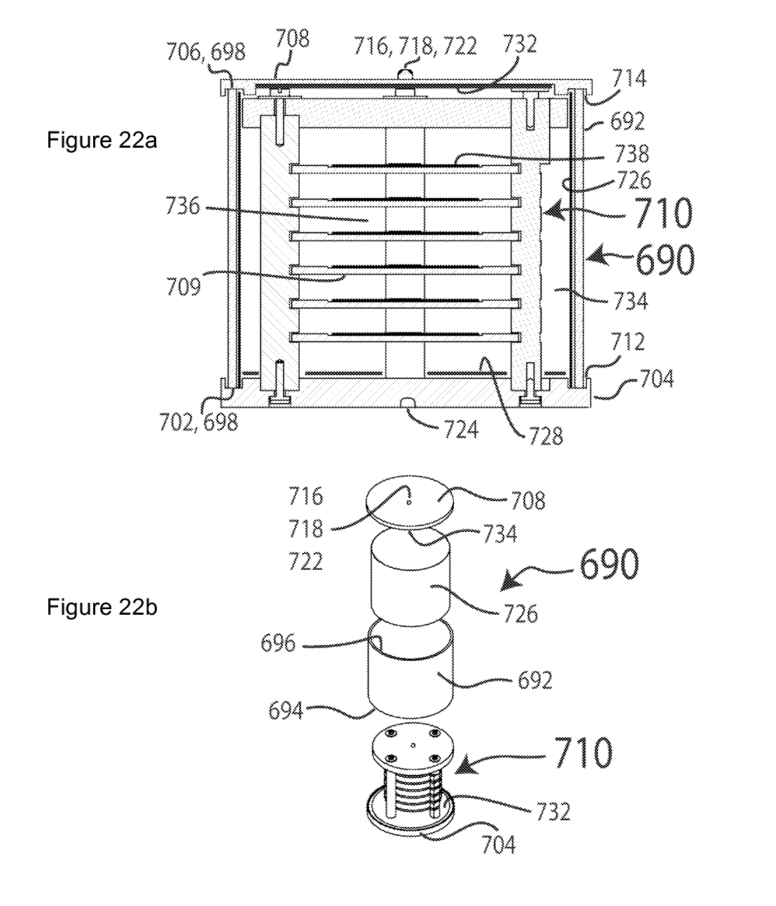

FIGS. 22a-22b show a further embodiment of this invention wherein the primary tool is in the form of a TEB 690 having an access port in the form of a removable side wall structure 692. Side wall structure includes a bottom mating surface 694 and a top mating surface 696 that form a quasi-gas tight seal 698 with a top mating surface 702 of a support plate 704 and a bottom mating surface 706 of a lid 708, respectively. Side wall structure 692 thus allows for the ready loading and unloading of a plurality of trays 709 that form an open tray stack 710 (similar to stack 550) having a support plate, i.e., a dual function support plate 704 being the support plate for both stack 710 and TEM 690. Preferably, mating surfaces 694 and 696 engage grooves 712 and 714, respectively, thereby allowing for ready and confirmable alignment of side wall structure 692 with respect to support plate 704 and to lid 708. Although sidewall structure 692 is shown as an integral tubular structure, it is contemplated herein that other sidewall structures, e.g., oval, square, rectangular, triangular, other poly-faceted, clamshell, etc., could be used instead. Lid 708 can also have optional location feature 716, handle 718 and/or gas port 722, and bottom support plate can also have optional location feature 724, preferably matching location feature 716. Optionally, a side liner 726 can be used that is located inside of side wall structure 692, and optimally is secured thereto so that the combination can be moved together. Bottom liner 728 can optionally cover at least part of the top surface of plate 704 and respectively a top liner 732 can cover at least part of the bottom surface of plate 708. In addition, open tray stack 710 can be replaced with another type of open tray stack, e.g., as shown in FIG. 17-19. The inside volume of TEB 690 forms an ESRC 734, which is in parallel communication through a plurality of gaps 736 with each substrate 738 located on trays 709.

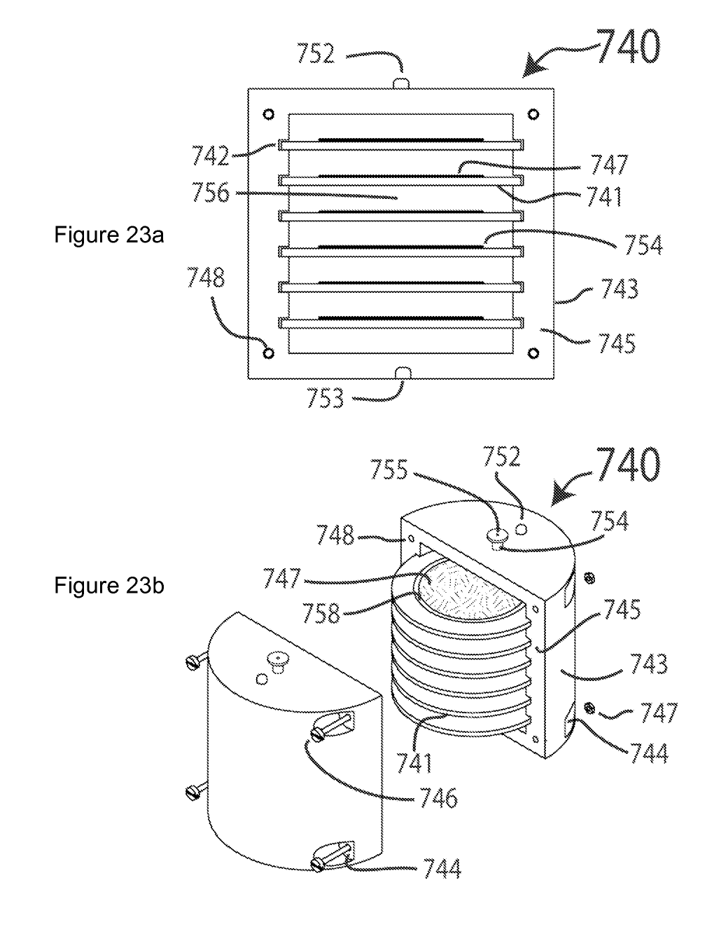

FIGS. 23a-23b show an additional embodiment of this invention wherein the primary tool is in the form of TEB 740, which encloses and supports an open tray stack formed from a plurality of trays 741. Trays 741 are spatially arranged in non-gas-tight slots 742 formed in two cylindrical half shells 743, with one of the shells acting as an access port and both having location features 744 that allow for the closing of shells 743 on mating surfaces 745. Shells 743 may be closed (with optional GraFoil® gaskets) in a quasi-gas tight manner with screws 746 and nuts 747, which extend through holes 748. It is understood that other suitable hardware can be used equivalently to close the half shells 743. At least one of the half shells may include an optional top location feature 752 and/or a matching bottom location feature 753, and/or at least one handle 754 (shown only in FIG. 19 b) to facilitate transport. As discussed above, handle 754 can include a gas port 755, and/or additional gas ports can be distributed thought-out each half shell 743 as needed to increase processing uniformity among all the substrates 747. Location feature 746 and hole 748 can also serve as a gas port, when needed. The inner volume of half shells 743 thus defines an ESRC 756, and each tray 741 is able to communicate freely with ESRC 756 through appropriate grooves cut into the sidewalls of at least one of the half shells 743. Each tray 741 preferably has a lip-enclosed or countersunk substrate support area 758 that is larger than the respective substrate 747 to accommodate linear thermal expansion differences between the material of the tray and of the substrate.

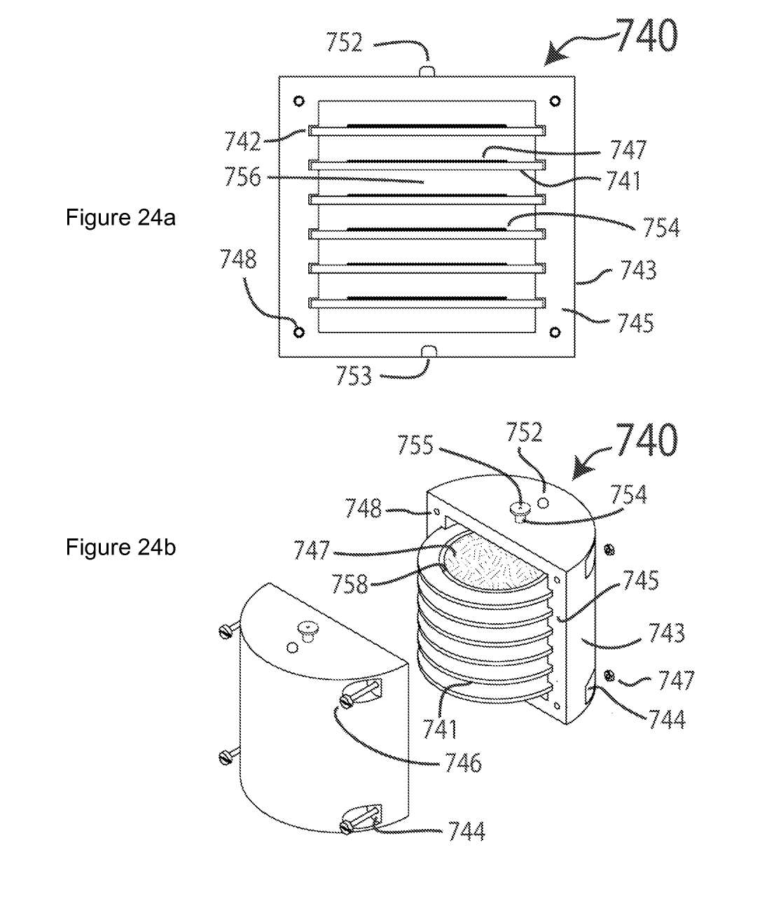

FIGS. 24a-24b show a variation of the concept shown in FIGS. 23a-23b, wherein TEB 760 includes a liner formed from two half cylinders 764, each with a top liner 766 and a bottom liner 768 that together substantially surround an open stack of square trays 762. Trays 762 may be supported by location grooves formed into at least one of shells 763. Each tray 762 preferably includes an oversized countersunk substrate support area 758 for supporting substrate 759. Liners 768 and 766 optionally include bent inner and/or outer tabs 788 that engage the edge of half cylinders 764, with each half cylinder 764 having slots 802 through which the respective corners of the trays 762 engage with the location features formed inside of half shell 763, thus forming an open tray stack. If needed, the top and/or bottom parts of the liner may include at least one screw 804 extending through hole 806, which locates the liner with respect to half shells 763. Alternatively, the liner parts 764, 766 and 768 can be made into a single part with suitable manufacturing means, e.g., welding, riveting, sowing with wire threads, etc.)

### Primary Tools in the Form of a LEB or Open Rolled Tray Stack Allowing Processing of Long Substrates in a Batch Process

This portion of the specification is directed to additional embodiments of the present invention wherein the primary tool in the form of a rolled or folded open tray stack and in the form of a long enclosure box (LEB) for substrates that are longer than the diameter of the respective process tube, and wherein the flexible long substrate has been rolled or folded in the long direction of the substrate in such a manner to form either a self-supported or supported rolled or folded open tray stack which is spaced apart by spacer strips. The LEB includes a quasi-gas-tight sealed enclosure box with an access port for loading and unloading a flexible long substrate, and that encloses and supports the flexible long substrate having one dimension longer than the inner circumference of a respective process tube used for CVD Synthesis. The inner volume of the LEB forms the respective ESRC that is in gaseous communication with the multiple substrate layers forming effectively an open tray stack. An optional liner can further enhance the processing of the long substrate.

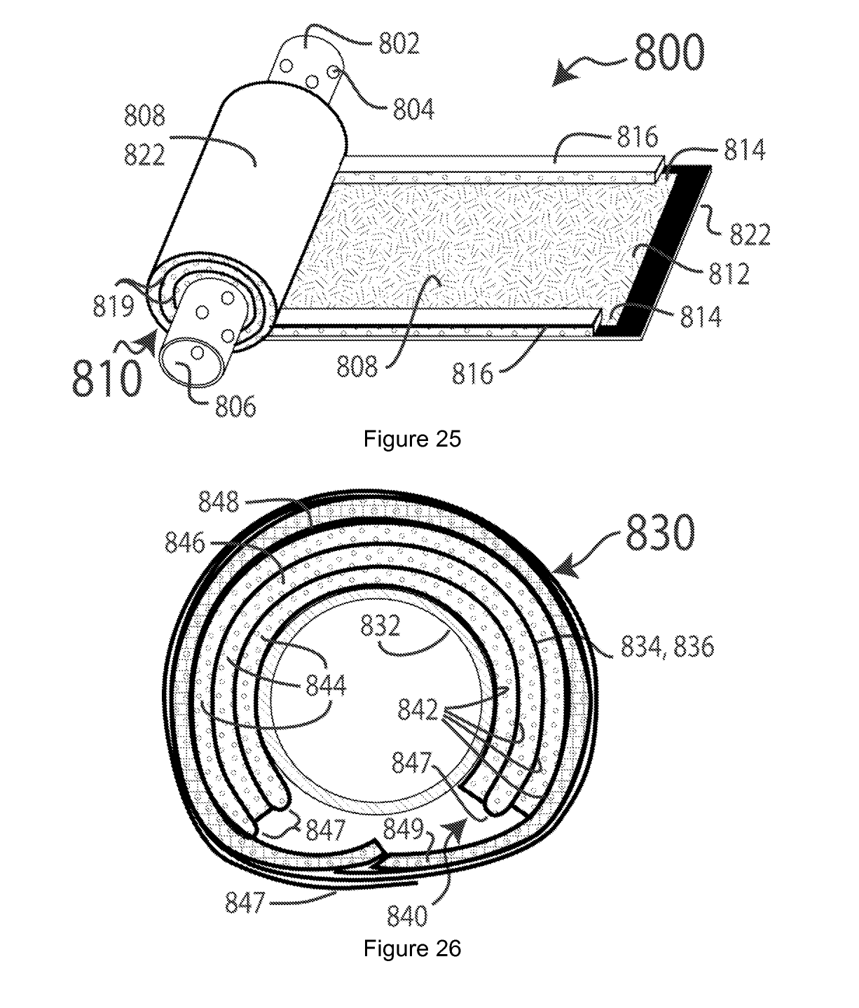

FIG. 25 shows multiple embodiments of this invention in the form of rolled open tray stacks 800, which include an inner support tube 802 having optional gas ports 804 (e.g., holes) to allow gas access to the inside volume 806 of tube 802, a long flexible substrate 808 with a short edge 812 at each respective long end and two long edges 814 along each side, and two spacer strips 816 extending along and intimately contacting at least a portion of edges 814. Together the layered stack formed by spacer strips 816 and substrate 808 are rolled up over inner support tube 802 into a spiral roll having multiple layers 819 (also referred to herein as rolled trays), thus forming rolled self-supported open tray stack 800. If the thickness of the spacer strips 816 is constant along its length, such a spiral roll forms an Archimedes spiral roll.

In an alternative embodiment of this invention, inner tube 802 is replaced by an outer support tube (not shown in FIG. 25) that encloses the respective spiral roll and supports it from the outside. Optionally, the final turn of the respective spiral roll is secured to prevent it from unrolling and/or bending during the CVD Synthesis and/or during transport. In one embodiment of this invention, the inner and/or outer support tubes are made from the same material as substrate 808, thereby having the same thermal expansion coefficient to minimize buckling of the substrate during CVD Synthesis and providing an additional liner function. In another embodiment, the support tubes are made from materials selected from a list including graphite, carbon-carbon composite, quartz, carbon-coated quartz, and nitrite. Optionally, a starting layer and/or ending layer of an inert, minimal wetting material layer can be used between the inner and/or outer support tubes and the first and/or last turn of substrate 808 (e.g., a GraFoil® layer) thereby providing a non-reactive, non-sticky surface between the support tube and the substrate 808 that reduces/eliminates any local bonding of the substrate 808 to the inner and/or outer support tube 802, and that optimally accommodates minor differences in linear thermal expansion between the tube 802 and substrate 808 material.

In one embodiment of this invention, the spacer strips 816 are gas permeable to allow easy gas access to the gap between two adjacent layers 819 from the long edges 814, and can be made from process compatible material, e.g., nano-carbon paper, flat, perforated and/or grooved GraFoil®, non-woven carbon fiber paper, woven carbon fiber cloth, threads of carbon fibers, ceramic cloth etc. Preferably, spacer strips 816 allow for minor movement of the substrate 808 positioned thereunder due to the thermal expansion of the substrate 808, thereby reducing the tendency of kinking in the substrate 808 during the heating and cooling process steps of the CVD Synthesis. The material for spacer strips 816 is preferably chosen to be process compatible and to prevent layers 819 from locally welding to each other, thereby allowing higher temperature processing, especially when used in conjunction with a respective LEB containing most of the substrate 808 and/or respective liner material sublimed vapors. Spacer strips 816 can be made from a single material or be a composite of multiple materials, e.g., a 0.5 mm thick flat or corrugated (for enhanced gas permeability) Cu stripe sandwiched between two flat (e.g., 25-100 μm thick) and substantially gas tight (for minimal Cu vapor penetration) nano carbon papers strips (manufactured for example by CVD Equipment Corporation from 5-25% by weight of mm long carbon nano tubes and the rest form exfoliated graphite, or using strips cut from high density PGS sheets manufactured by Panasonic) to better match the thermal expansion of the substrate 808 and to prevent any welding of the substrate 808 to the inner Cu portion of such composite spacer strips 816.

If two adjacent substrate layers 819 are directly exposed to each other, the spiral roll is referred to as a self-supported rolled open tray stack (e.g., the substrate forms its own tray) where one layer also provides a liner function for two adjacent layers and where the gap between two layers 819 formed by spacer strips 816 forms a local SRC for the corresponding local layer of substrate 808. In an alternative embodiment of this invention, a thin and flexible tray 822 that is preferably wider than the substrate 808 is placed underneath substrate 808 and the resulting triple layer stack formed by the components 822, 808 and 816 is rolled into a respective spiral roll, thus forming what is referred here to as a supported rolled open tray stack 800.

FIG. 26 shows two other embodiments of this invention by depicting both a self-supported and supported folded open tray stack 830, which includes an inner support tube 832, a long flexible substrate 834 and an optional process compatible flexible tray 836 (with the combination of 834 and 836 shown as a single thick line in FIG. 26). Substrate 834 (or pair of substrates 834 and flexible tray 836) are folded forth and back over inner support tube 832 forming layers or folds 842 that are spaced apart (as shown in FIG. 25) near their respective long edges by discontinuous flexible spacer strips 844 that optionally extend somewhat beyond the long edges of the substrate 834 thus forming a respective SRC 846 between two adjacent layers 842. Each SRC 846 is open on either on one or on three sides: the side opposite to the fold 847 and optional through the two gas-porous spacer strips 844. Substrate 834 is folded parallel to the narrow edge of the substrate 834 near the ends of spacer strips 844 creating the folds 847. In one embodiment of this invention each fold 847 has a radius of no less than ½ of the thickness of the spacer strips 844 to minimize the mechanical distortion of substrate 834 after is removed from the support tube 832 and unfolded.

FIG. 26 also shows an embodiment of this invention were the folded open tray stack 830 has been wrapped on its outside with one or more layers 847 of another conforming material that substantially encloses the last fold 848. For example a GraFoil® sheet or another carbon based structure that is quasi-gas-tight can be used to obtain such a function. This enclosure layer is separated from the last fold 848 by two spacer strips 849, and can be made from the same material as the two spacer strips 844 or be a continuation of the spacer strips 844.

Other means to fold a long substrate sheet are considered as well and are intended to be included in this invention. For example, two inter-digiting graphite blocks with suitable dimensioned spacer strips (finger like strips extending at predetermined distances from a common block with the two blocks interlocking) allows for creating a one-dimensional vertically folded self-supported or supported substrate structure (zig-zag style) by pushing the long substrate between two matching and suitably dimensioned inter-digiting blocks, thus forming a serpentine folded open tray stack with the respective layers laying substantially parallel to each other but offset by the height of the spacer strips, thus providing direct access to two adjacent layers from the gap opposite to each respective fold.

In another embodiment of this invention, instead of a single substrate foil or a thin carbon sheet and substrate foil, a composite layer (a thin carbon sheet (e.g., GraFoil®) is sandwiched between two Cu foils) is rolled or folded onto an open tray structure with two spacer strips separating each composite layer. This provides both a liner function, doubles the usable surface area per composite layer (typically only one side of the Cu foil is usable for film harvesting), and improves the mechanical stiffness of the structure for a wider Cu foil substrate, thereby preventing the two Cu foils from welding together during CVD Synthesis and increasing the production rate of graphene and other 2D films.

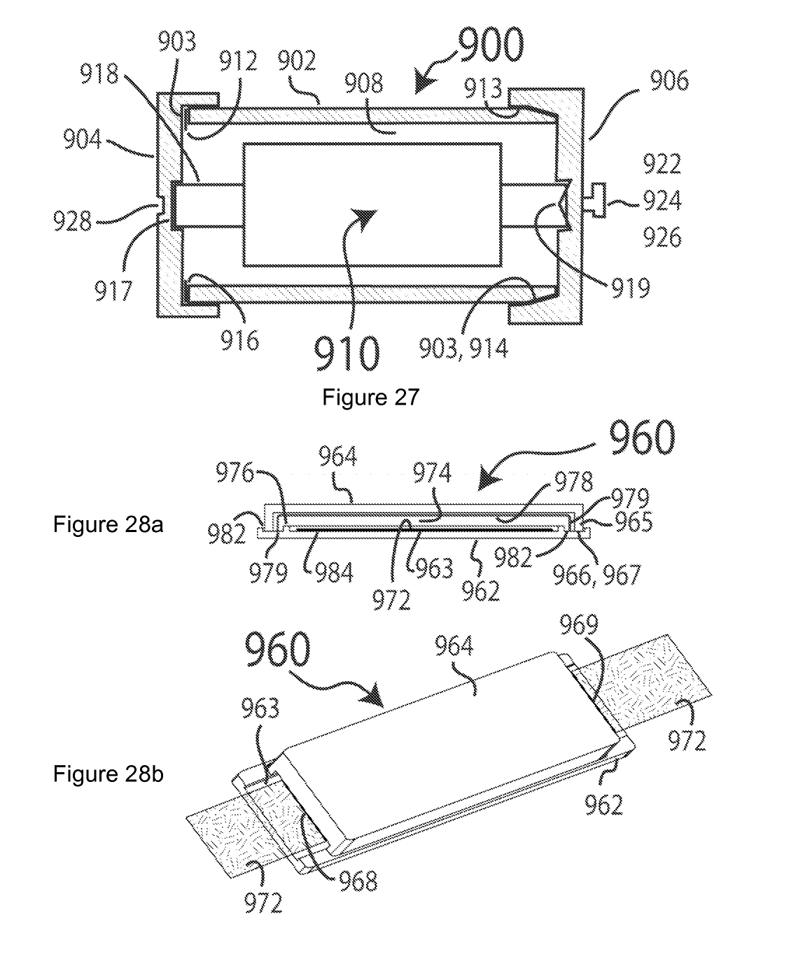

FIG. 27 shows (in a cross-sectional view) another embodiment of this invention wherein the primary tool is in the form of a LEB 900 and includes a support wall 902 having a quasi-gas-tight seal 903 with a left lid 904 and/or a right lid 906 forming at least one access port to an enclosed respective ESRC 908 inside which a rolled or folded open tray stack 910 is supported and located in a fixed spatial relationship with respect to support wall 902 and lids 904 and 906. Several possibly examples of such open tray stacks 910 have been discussed above as open tray stacks 800 and 830.

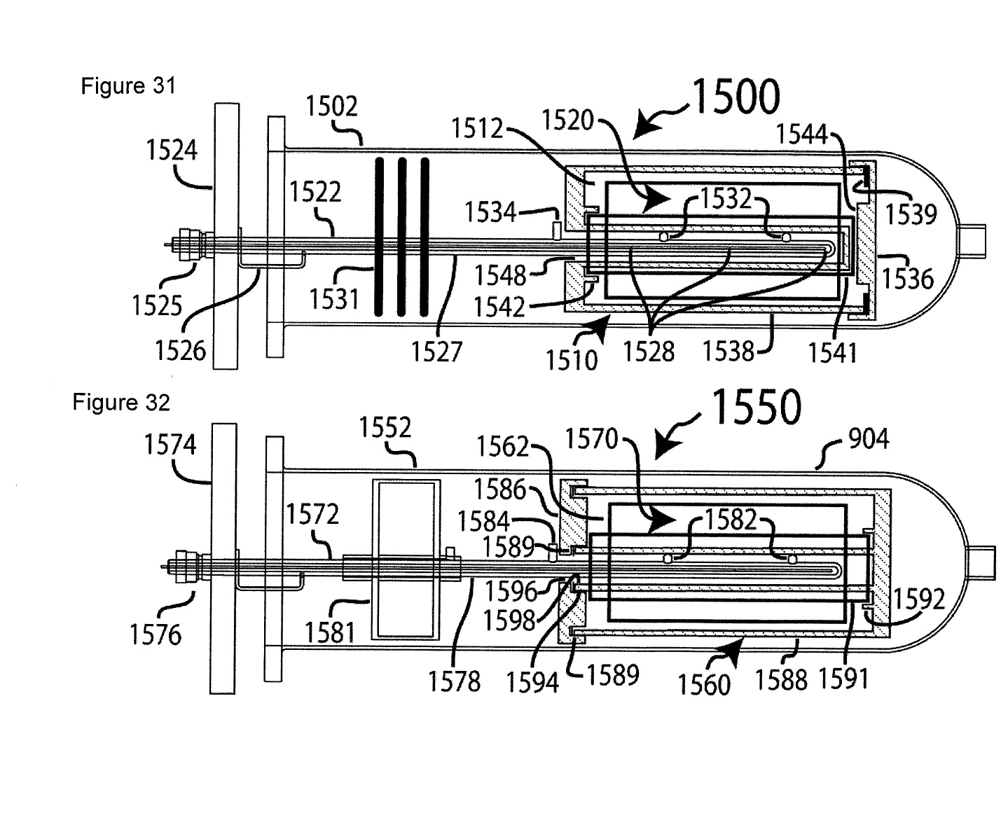

In one implementation of this invention, one of the lids is an integral part of support wall 902 and is either made as a single part (see FIGS. 31 and 32) and/or is permanently or semi-permanently connected or bonded in a quasi-gas-tight manner to one end of the support wall so that only one easy removable lid is available as access port. Lid 904 is shown as a threaded cap seal with an optional gasket 912 between the sealing surface of the lid 904 and the mating rim surface of support wall 902. Lid 906 is shown as having a threaded straight section 913 and a tapered cone seal 914. FIG. 27 shows two locating and support function implementations, namely a countersunk pocket 917 formed in lid 904 that locates a respective end of an inner (or outer) support tube 918 and which allows for some differences in linear thermal expansion between support wall 902 and support tube 918, and a conical feature 919 formed in lid 906 that engages in a self-centering manner with the inner walls of support tube 918. Preferably, the tolerances of the assembly allow for the different linear expansion coefficient of support tube 918, support wall 902, and lids 904 and 906, to prevent distortion of any components and/or loss of any of the quasi-gas-tight seals 903 during CVD Synthesis.

In another preferred embodiment, inner location support functions are built into one of the lids and or support wall 902, enabling the loading/unloading of open tray stack 910 vertically through at least one of the removed lids, thereby facilitating the closing of LEB 900 without losing the relative alignment of the open rolled stack 910 positioned therein.

When loading a folded open tray stack 830 the respective inner support tube 832 is preferably located offset from the lid center to center the respective stack 910 in ESRC 908 and is keyed mechanically on the inside and outside of at least one lid to prevent loss of relative alignment during transport and enable optimum placement of stack 910 into a respective CVD System (see FIGS. 31 and 32) for CVD Synthesis. Optionally, at least one handle 922, with our without gas port 924, is used to locate LEB 900 inside a respective PRC in a substantially thermally isolated manner to minimize temperature induced stress from holding and/or heat sinking an LEB 900 during CVD Synthesis. A keyed handle 926 (shown in FIG. 27 as a round handle with a flat side at it bottom) can be used for example when additional rotational alignment of LEB 900 is desirable for optimum CVD Synthesis outcome (e.g., for folded open tray stacks). A countersunk keyed location feature 928 is shown in FIG. 27 on the exterior of the lid 904 as an example of a rotational alignment keyed location feature allowing for the holding of LEB 900 in a fixed reference position with minimum thermal contact. As required, additional auxiliary gas ports can be distributed over the external surface of the LEB 900.

A semi-flexible support structure can be used to secure the end part of the rolled and/or folded long substrate and prevent it from unrolling. In one embodiment of this invention, the outermost (and/or innermost) layer is wrapped with a layer of carbon-containing material, for example GraFoil™, to minimize Cu material evaporation from such layer. In addition, a Cu wire or strap can be wrapped around the outermost layer. In another embodiment, a Carbon fiber thread is wrapped on the outside of an inside mounted spiral to prevent it from unrolling, thereby preventing any change in the distance between the individual layers. Alternatively, a Cu spring or expanded Cu sheet can be used to push such rolled trays towards an outside support tube. All of these solutions allow for sufficient mechanical expansion to accommodate internal and/or external temperature expansion coefficient differences.

### Primary Tools in the Form of an EEB for Roll-to-Roll CVD Synthesis

FIGS. 28a-28b show another embodiment of this invention wherein the primary tool is in the form of an EEB 960, and includes a support plate 962 that has a substrate support area 963 and a lid 964, wherein lid 964 has a rim 965 forming a quasi-gas-tight seal 966 along the sides of the lid 964 with an optional countersunk mating surface 967 formed on plate 962. The seal 966 is interrupted near two narrow slits 968, one at the front and one at the back narrow side of lid 964 through which a substrate 972 having the form of a flexible metal foil (e.g., Cu foil) can be moved from the entrance slit 968 to the exit slit 969 through a respective SRC 974 defined therein between. Optionally, slits 968 and 969 are built to tight tolerances, or have an optional adjustable wiper blade attached to the narrow side of lid 964 that can be adjusted to tight tolerances such that that substrate 972 forms a nearly quasi-gas-tight-seal with plate 962 and lid 964.

Inside of lid 964, substrate support area 963 is optionally surrounded by a shallow raised lip 976 that confines the motion of substrate 972 and that isolates substrate 972 from an optional liner 978 having optional bent side walls 979 supporting its weight. Alternatively, liner 978 can be held by shoulder screws (or equivalent structure) to the top surface of lid 964 as discussed hereinabove or rest on raised lip 976. The optional groove 982 can also support the sidewalls 979 of the liner 978. Optional gas ports can be distributed along lid 964 as needed. Lid 964 can include handles to provide ready access to SRC 974 for servicing and loading of a new substrate 972 roll. Additionally, substrate support area 963 can have a replaceable surface 984 that can be exchanged when needed to manage its wear.

In another preferred embodiment of this invention, multiple EEBs are stacked on top and/or next to each other to allow growing CVD graphene films on simultaneous multiple rolls of continuously semi-continuous or step wise moving substrates 972 (see FIG. 32).

### CVD System Incorporating at Least One Enclosure Box

This portion of the specification is directed to additional embodiments of the present invention wherein the CVD System incorporate a primary tool in the form of at least one enclosure box, e.g., at least one SEB, TEB, LEB, or EEB. Each enclosure box encloses and supports at least one substrate and isolates it from the remainder of the process chamber through a quasi-gas-tight sealing construction of the enclosure box, with the enclosure box being made in such a way that loading and removal of one or more substrates can be done readily through an access port and with minimal chance of warping and/or kinking any of the processed substrate(s).

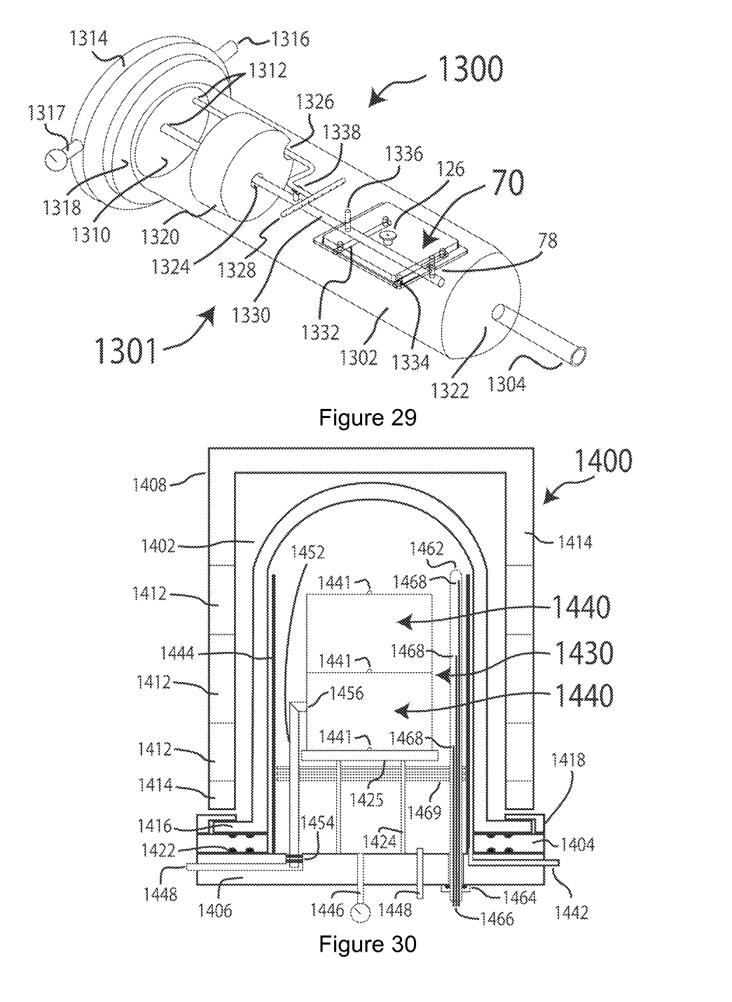

FIG. 29 shows a further implementation of this invention in the form of a CVD System 1300, which includes a horizontal tube CVD System incorporating a primary tool in the form of a SEB 70 that is intended to represent any of the enclosure box primary tool designs of this invention, a process tube 1302 having an exhaust gas port 1304 connected to (not shown in FIG. 29) either a vacuum (LPCVD) or a purge flow system (APCVD), and an auxiliary tool set 1301. A removable end cap 1310, with optional one or more feedthrough ports 1312, is sealed (with o-rings and/or a spring-loaded motion mechanism) to a gas ring 1314 mounted to a support frame (not shown), which can optionally also include one or more gas ports 1316 for various process gas delivery into the process tube 1302 and one or more pressure sensors 1317 (e.g., with different full scale range). On the opposite side of end cap 1310, the gas ring 1314 is sealed to the process tube 1302. Optionally, this can be done with o-rings positioned between quartz flange 1318 and quartz process tube 1302, and with removable locating clamps putting pressure on the respective o-ring seal (or seals if double o-rings are used). Alternative vacuum sealing means (for example, flange-less sealing as commonly used for CVD Synthesis systems with straight quartz tubes) for sealing one or both side of a straight quartz process tube are intended to be included in this invention, although not shown in FIG. 29.

The PRC of the CVD System 1300 is formed by the sealed combination of end cap 1310, gas ring 1314, and process tube 1302. The PRC, together with a respective gas delivery and exhaust system delivering and exhausting the respective process gases, isolates the inside of process tube 1302 from the outside atmosphere during CVD Synthesis, thus creating an isolate processing environment. Auxiliary tool set 1301 may include a structure for limiting the loss of infrared radiation from escaping the PRC. Such a structure may include: 1) a thermal baffle 1320 (e.g., an evacuated quartz volume filled with quartz wool) near end cap 1310, and/or 2) a necked-down end 1322 formed in process tube 1302 near exhaust gas port 1304, with a matching insulation closure near port 1304 of a resistive oven, induction (RF) and/or infrared (IR) heating system surrounding process tube 1302 that provide the energy needed to heat up the primary process tooling located in the PRC to the process conditions needed for CVD Synthesis. Thermal baffle 1320 may include one or more cut-outs 1324 and 1326 for allowing the installation of one or more gas injectors 1336 and/or internal exhaust gas ports (not shown) and allow it to be firmly located on a transfer arm 1330 that is mounted rigidly to the end cap 1310 and moves together with end cap 1310 to allow ready loading/unloading of respective enclosure boxes from/to the PRC. Alternatively, thermal baffle 1320 can be comprised of multiple opaque quartz disks spaced apart 2-10 mm with suitable cutouts 1324 and 1326 having optional additional cutouts to facilitate their ready removal/installation for cleaning/system maintenance purposes. Ideally, thermal baffle 1320 is located near the end or ends of the heating system to minimize radiation heat losses.

In one embodiment of this invention, transfer arm 1330 is mounted to end cap 1310 through a vacuum tight feedthrough port 1312 and is vacuum sealed on the inside. Preferably, arm 1330 is hollow along its length, thereby allowing it to also function as a thermocouple sleeve via the insertion of one or more thermocouples that are located in a fixed location with relationship to the primary tool, e.g., below the center and/or left and right edge of SEB 70. Alternatively, at least one separate, gas-tight thermocouple sleeve can be fixed through port 1312 to end cap 1310 to provide an in-situ temperature measurement for one or more reference process locations inside process tube 1302. This provides feedback for the regulation of a single, or preferably at least a three-zone heating system surrounding process tube 1302 with multiple automatic PID-controlled heating system controllers (one for reach process thermocouple) so a respective enclosure box (e.g., SEB 70) can be heated to a reproducible process temperature, irrespective of the age of its heating system. This allows for more accurate process repeatability than if external furnace thermocouples are used to regulate the temperature of SEB 70 (at least after an initial temperature ramp up that is optionally controlled with paired furnace thermocouples that are located at a matching location outside the process tube 1302). FIG. 29 also shows the example wherein arm 1330 includes side bars 1332 with standoff pins 1334 that provide multiple locating functions, including holding primary tool SEB 70 at a fixed offset distance from the thermocouple sleeve incorporated in arm 1330. This auxiliary locating feature allows for further reduced thermal contact between the bottom surface of the respective enclosure box and arm 1330, thus helping to maximize the thermal uniformity of the respective enclosure box during CVD Synthesis. Additional optional locating features can be provided by pins 1336, which engage with location features 78 of SEB 70, thus providing a repeatable placement function. Handle 126 facilitates the removal of the lid of SEB 70, and helps to protect the respective liner, if one is used as part of SEB 70. Offset pins 1332 also allow SEB 70 to be grasped manually or robotically from the top and bottom with a suitable designed gripping device so that it can be readily unloaded, thereby increasing CVD Systems throughput.

Transfer arm 1330 can also have one or more location features to locate/support an optional gas injector, internal exhaust port, thermal baffle, thermocouple sleeve and/or other auxiliary tools. FIG. 29 shows such a feature in the form of a fork 1338 that supports the other end of a distributed gas injector 1328. In one embodiment, the respective heating system may be removed by either opening a clamp-shell type oven and/or by moving (e.g., rolling) an oven away from the process tube while it is still hot, thus increasing the CVD Systems throughput.

The combination of the various primary tools, with or without one or more of the enclosure boxes of this invention, and with matching auxiliary tools form various CVD Systems of this invention. In the embodiment of FIG. 29, auxiliary tool set 1301 includes transfer arm 1330, thermal baffle 1320 and gas injector 1328.

FIG. 30 shows a high capacity CVD System in accordance with this invention in the form of a vertical tube furnace CVD system 1400 having a PRC enclosed by a process tube 1402, a sealing ring 1404, and an end cap 1406. Process tube 1402 is surrounded by a heating system, i.e., furnace 1408, having at least one individually controllable heating zone 1412 and two end insulating zones 1414. A flange 1416 of process tube 1402 is secured with a clamp 1418 to ring 1404. At least one o-ring 1422 is preferably utilized to form a vacuum tight seal therebetween. At least one o-ring 1422 is also utilized to seal end-cap 1406 to ring 1404. In one embodiment of this invention, the furnace 1408 is vertically liftable and is typically kept at a temperature close to the process temperature of the CVD Synthesis when off-loaded, i.e., when vertically lifted off the process tube 1402, and is preferably closed with a thermal shutter during these standby operations to minimize heat losses. This allows for faster heating and cooling times of a respective CVD System, thereby increasing its throughput. In another embodiment of this invention, the assembly of ring 1404 and process tube 1402 (connected via clamp 1418) is also vertically liftable to allow ready loading and/or offloading of one or more enclosure boxes held at a fixed spatial relationship with respect to end cap 1406 via a plurality of standoffs 1424 and support plate 1425. FIG. 30 shows the example wherein the primary tool is a TEB stack 1430 formed from two TEBs 1440 with location features 1441 facilitating the spatial arrangements of TEBs 1440 with respect to each other and to plate 1425. Alternatively, end-cap 1406 can be lowered, while the process tube-ring assembly remains stationary.

End cap 1406 can include a gas port 1442 for exhausting the process gases between the outer wall of a cylindrical tube 1444 placed inside process tube 1402 and the inner walls of process tube 1402. The optional and removable tube 1444 aids in the uniform gas exhaustion of the internal volume of tube 1444 enclosing primary tool 1430 of the CVD System. Optionally, end cap 1406 also includes a gas port 1446 connected to one or more pressure sensors, at least one gas port 1448 for injecting process gas into TEB 1440, and at least one removable gas injector 1452 connected to a gas port 1448 with o-rings 1454 for delivering additional process gas to at least one auxiliary distributed gas port 1456 of TEB 1440. A thermocouple sheath 1462 is shown as a sealed tube which forms a vacuum tight seal 1464 with end cap 1406, and which internally holds at least one thermocouple 1466 having a sensing tip 1468. Sheath 1462 is placed inside tube 1444, and includes multiple thermocouples 1466 with their respective tips 1468 spaced apart to provide a location dependent feedback signal to a respective thermal controller powering the respective heating zone 1412.

Thermal baffles 1469 (shown as multiple opaque quartz disks) with respective cutouts for standoffs 1424, gas injector 1452 and sheath 1462 minimize the heat loss from underneath primary tool 1430, thus providing a more uniform temperature environment for primary tool 1430. Preferably, the external walls of the enclosure box or boxes forming primary tool 1430 are highly thermal conductive, and not highly transparent to infrared radiation, thereby increasing the internal temperature uniformity of such boxes.

FIG. 31 shows a cross sectional view of a further embodiment of this invention in the form of a CVD System 1500 which includes a horizontal process tube 1502 incorporating a primary tool in the form of a LEB 1510 that has a quasi-gas-tight sealed ESRC 1512 enclosing a rolled or folded open tray stack 1520. An auxiliary tool in the form of a transfer arm 1522 is mounted with a vacuum tight seal 1525 rigidly to an end cap 1524, and is supported with a bracket 1526. Arm 1522 includes a thermocouple sheath 1527 having multiple thermocouples inside with respective tip endings 1528. Arm 1522 further includes thermo baffles 1531 formed of multiple diffusive quartz plates, and location features including standoff posts 1532 and stop post 1534 that locate LEB 1510. LEB 1510 includes a screw on lid 1536 that is quasi-gas-tight sealed to main enclosure body 1538 with an optional gasket 1539.

FIG. 31 shows examples of location features used to locate an inner tube 1541 that supports stack 1520, e.g., a circular lip 1542 on the inside of body 1538 and a shoulder 1544 on the inside of lid 1536. The main body 1538 has a substantially central located hollow sealed cavity 1548 which rests on the standoff posts 1532. The resting location of main body 1538 is defined by stop pin 1534. This design thus provides minimal thermal contact between arm 1522 and LEB 1510.

FIG. 32 shows a cross sectional view of another embodiment of this invention in the form of a CVD System 1550 which includes a horizontal process tube 1552 incorporating a primary tool in the form of a LEB 1560 that has a quasi-gas-tight sealed ESRC 1562 enclosing a rolled or folded open tray stack 1570. A transfer arm 1572 is mounted with a vacuum tight seal 1576 rigidly to an end cap 1574. Arm 1572 includes a thermocouple sheath 1578 having multiple thermocouples inside, a mounted thermo baffle 1581, and location features including standoff posts 1582 and stop post 1584 that locate LEB 1560. LEB 1560 includes a screw on lid 1586 that is quasi-gas-tight sealed to main body 1588 with an optional gasket 1589.

FIG. 32 shows other examples of location features that can be used to support and locate an inner tube 1591 that supports open tray stack 1570, e.g., a circular lip 1592 on the inner side of the lid 1586 and a flat stop surface, together limiting the location of the tube 1591. Main body 1588 is shown having a substantially central located hollow cavity 1596 which seals to a countersunk hole 1598 formed in lid 1586 with outer and inner optional gaskets 1589 in a quasi-gas-tight manner. In one embodiment of this invention, lid 1586 has outer and inner threaded surfaces that interact with the outer and inner top rim of main body 1588 and cavity 1596 and with the gaskets 1589 compensating for mechanical imperfections in the two terminating surfaces of the main body 1588. The inner surface of cavity 1596 rests on standoff posts 1582. The other reference location of lid 1586, and therefore of LEB 1560, is defined by stop post 1584. This design provides minimal thermal contact between arm 1572 and LEB 1560.

Gaskets 1539 and 1589 can be made from GraFoil™ material, and lids 1536 and 1586 and main bodies 1538 and 1588 can be made from graphite and/or carbon-carbon composite material or equivalent process compatible materials. Additional gas ports can be added to LEBs 1500 and 1550 as needed to increase the process gas entry into the respective ESRC 1512 and 1562.

Alternatively, CVD Systems can be built utilizing EEBs 900 disclosed in the embodiment of FIG. 27 that are supported appropriately on a transfer arm with minimal thermal contact to the lid, e.g., by contacting respective handles and/or the lid and/or support wall with respective standoff posts.

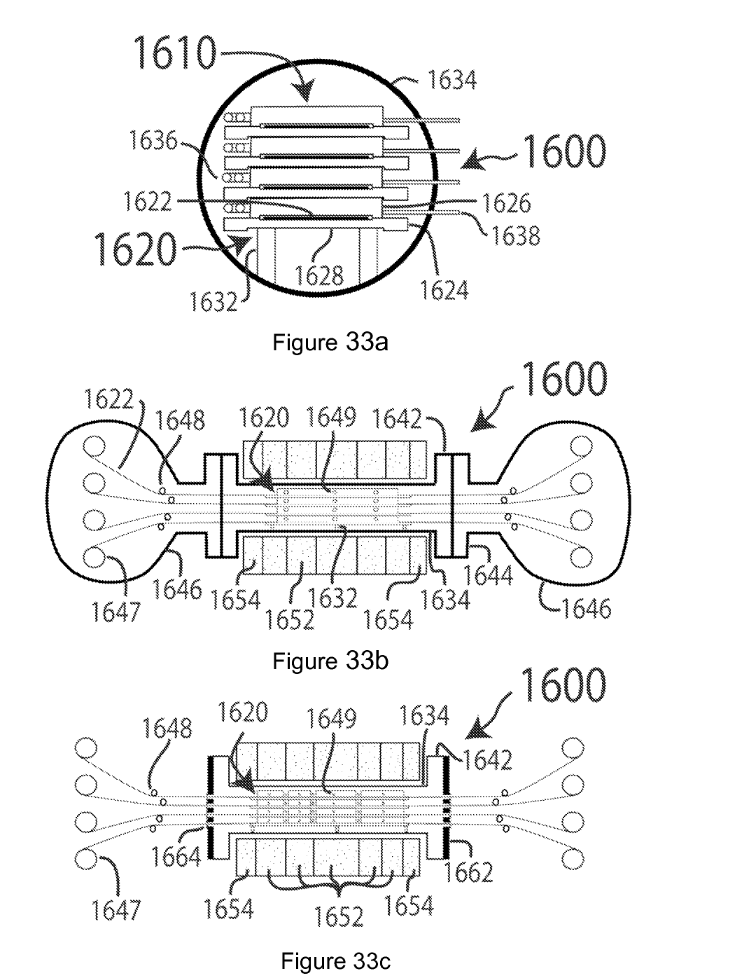

FIG. 33 shows another implementation of this invention in the form of a roll-to-roll CVD system 1600 that utilizes an EEB stack 1610 formed of multiple EEBs 1620 to simultaneously process multiple long flexible substrates 1622 in roll-to-roll format. Each EEB 1620 has a plate 1624 supporting a substrate 1622, e.g., Cu foil, and a lid 1626 that fits into an optional countersunk pocket 1628 on the bottom surface of plate 1624, thereby allowing EEBs 1620 to be stacked in a self-aligning manner on top of each other. The bottom EEB 1620 is supported by standoff posts 1632, preferably of minimum size, to minimize the thermal heat sinking of EEB stack 1610 to process tube 1634. Optional gas injectors 1636 traveling along the process tube connect to optional gas ports of lids 1626. Alternatively, gas injectors 1638 travel through a seal in process tube 1634 to a respective gas port of lids 1626. By stacking one or more EEB on top of each other, a better utilization of the process tubes cross sectional area is achieved, and therefore a lower production cost is achievable for high volume productions.

Even in applications where only a single EEB is utilized in the roll-to-roll CVD System of this invention, quality and productivity improvements is achieved over prior art systems. This is accomplished by both the new practical ability to operate at higher process temperatures (with negligent maintenance penalty) for both LPCVD and APCVD operations thereby increasing the growth rate and grain size of the resulting films and by the improved temperature uniformity across the width of the substrate due to the “integrating sphere” effect of the LEB 1610. This allows a wider process window, and therefore the ability to provide a more cost efficient CVD Synthesis operation tuned for a given targeted application.

FIG. 33b show a cross sectional view of an implementation of this invention as a roll-to-roll LPCVD System with a process tube 1634 having a flange 1642 that seals in a vacuum tight manner to a flange 1644 of a spooling mechanism enclosure 1646 that houses multiple motorized spools 1647 and tension controlling mechanisms 1648 as needed to wind and unwind one or more substrate foils 1622 that travel from one enclosure 1646 through the process tube chamber 1634 to the other enclosure 1646, wherein each substrate 1622 is wound up on a respective spool 1647. A suitable separation layer can be inserted, if desired, during wind up of the foil. Each foil travels through at least one respective EEB 1620 with optional gas ports 1649 through which the local process gas environment can be controlled.

Each EEB 1620 therefore allows independent control of the gas process environment for each substrate 1622 foil. Process tube 1634 is surrounded by a heating system that has multiple heating zones 1652 and insulation zones 1654 that are individually controllable with internal and/or external thermocouple feedback signals to achieve a desired temperature profile along the process tube direction. In addition, system 1600 may include process gas delivery systems, exhaust gas handling systems, and/or a vacuum pressure control system that maintains a set low pressure environment for process tube 1634 and enclosures 1646 while the process gases are delivered to EEB stack 1610.

In one implementation of this invention, the bottom of the substrate material is coated with a Carbon film (or film that decomposes to a carbon film during heating up the substrate) to reduce the tendency of the film to bond to the quartz plate forming the bottom surface of the respective EEB.

FIG. 33c shows another implementation of this invention as a roll-to-roll APCVD System with a process tube 1634 having two flanges 1642 that are closed with a cap 1662 in a vacuum tight manner. Optionally, each cap 1662 has a top and bottom adjustable slit 1664 for each substrate 1622 foil going through cap 1662 that can be adjusted to provide a quasi-gas-tight seal for each substrate 1622 foil, thereby minimizing the gas exchange between the inside and outside of the process tube 1634. Optionally, the combination of a slight over pressurization of process tube 1634, together with well-adjusted slits 1664, minimizes the likelihood of air entering the PRC, i.e., the inside of process tube 1634, and thereby affecting the quality of the produced 2D films. Optional exhaust ports positioned near exit flanges 1642 of the process tube 1632 can capture safely any process gas escaped through the slits 1664. Individually controllable temperature zones 1652, together with insulation zones 1654, allow for the adjusting of the temperature profile along process tube 1634. FIG. 33c shows an additional option (that can also be implemented for LCVD Systems) for stacking multiple EEB 1620 in series, each with optional independent process gas ports 1649, and with different length as needed to increase the productivity rate for a given traveling speed of substrate 1622 for a given CVD Synthesis process. An optional gas delivery and/or exhaust gas ports can be placed between each EEB 1620 to increase the gas isolation between them. Alternatively, baffles with matching exhaust ports (e.g., suction tubes) can be placed between each row of EEBs to improve the gas isolation of each individual EEB stack. Again the additional process window and temperature uniformity achievable with suitable designed EEBs 1620 of this invention provide increased quality and production rate for roll-to-roll LPCVD and APCVD Synthesis systems.

### CVD System Incorporating an Open Tray Stack

This portion of the specification is directed to additional embodiments of the present invention wherein the CVD System incorporates a primary tool in the form of at least one open tray stack or in the form of a rolled and/or folded open tray stack. For example, the enclosure box in the CVD systems disclosed herein can be replaced by a rolled and/or folded open tray stack.

FIG. 34 shows another embodiment of this invention in the form of a CVD System 1700 that uses a rolled and/or folded open tray stack 1710 as the primary tool for CVD Synthesis. However, instead of having a respective lid and main body surrounding the stack 1710 (as disclosed in the embodiment of FIGS. 31 and 32), a rolled or folded open tray stack 1710 is placed directly into the PRC of a respective CVD System. An inner tube 1702 is shown in FIG. 34 that supports an open tray stack 1710 and that is supported by standoff pins 1712 and located by stop pin 1714. As discussed above, inner tube 1702 is optionally made from the same material as the substrate to minimize thermal expansion differences.

In another embodiment of this invention, the last layer of the rolled or folded open tray stack is wrapped or covered with at least one turn of a substantial gas tight flexible sheet (e.g., GraFoil®) that is spaced apart from the outermost layer with two spacer strips, as discussed with respect to the embodiment of FIG. 26. This reduces the exposure of the last layer to the processing environment of the PRC. While this implementation operates in a less than quasi-gas-tight sealed manner, it is still suitable to increase productivity and quality over prior art CVD Systems, in particular for APCVD operation, where the pollution risk by excess substrate material evaporation is reduced. In this manner, a significantly greater surface area of substrate can be batch processed and therefore this implementation of this invention can be competitive when compared to the prior art roll-to-roll CVD systems or batch CVD systems that that do not use spacer rails as separators between the individual layers of a respective rolled or folded open tray stack.

Although the optimum quality characteristics described herein may not be achieved with the non-enclosure box embodiments of this invention, such embodiments nevertheless are capable of improving the productivity of prior art CVD Systems through the utilization of the higher capacity primary tooling (e.g., open tray stacks) of this invention and/or improving at least some of the quality aspects (flatness of substrate) over prior art CVD Systems due to such factors as less sticking to substrate support, less wrinkling of the substrate, less exposure to nano particles contamination, and more processable surface area.

### CVD Synthesis Incorporating a Primary Tool

This portion of the specification is directed to methods for CVD Synthesis utilizing the primary tools disclosed herein.

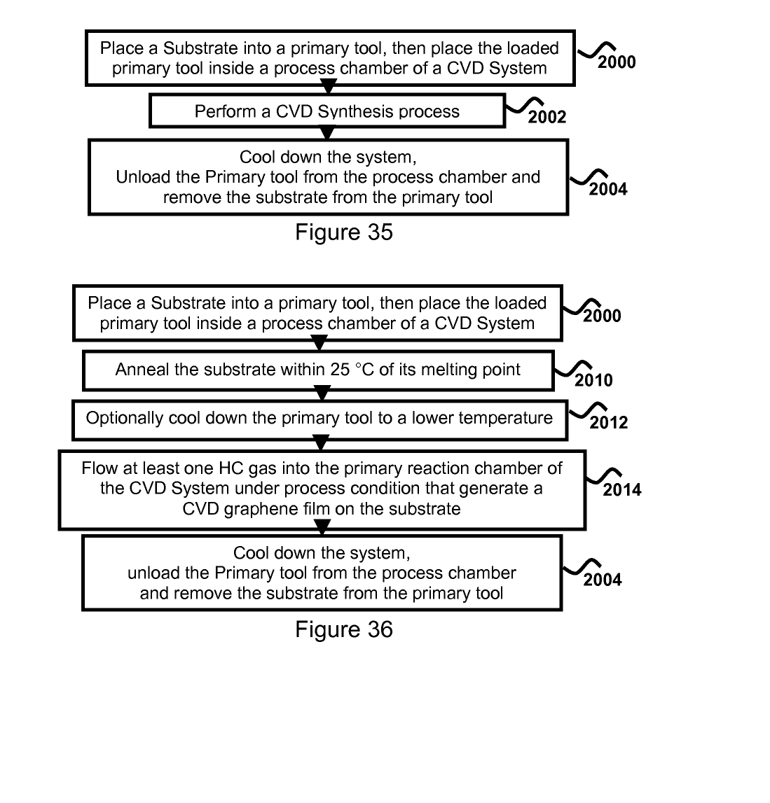

FIG. 35 outlines a basic method for CVD synthesis in accordance with this invention. For purposes of this section, the term primary tool is intended to encompass at least one open tray, a rolled and/or folded open tray, and/or a quasi-gas-tight enclosure box having an access port for easily inserting and removing one or more substrates. In step 2000, at least one substrate is located in at least one such primary tool, and thereafter the loaded tool is inserted into the PRC of a CVD System. In step 2002, a CVD Synthesis is performed, e.g., a graphene film process, and in step 2004 the primary tool is removed from the PRC, and then the substrate is removed from the primary tool.

FIG. 36 outlines a method for CVD synthesis of graphene films in accordance with this invention that enables the growth of larger size grains in the catalytically-active substrate material, in particular a Cu film and foil. This is achieved by annealing the substrate closer to the melting temperature than is typically practical with prior art methods and systems. Steps 2010 describes the step of annealing the substrate to within 25° C. of its melting temperature. Preferably, the substrate is annealed within 10° C. of its melting temperature, and even more preferably within 5° C. of its melting temperature. Optionally there is a slight (e.g., 5-30° C.) temperature gradient along one of the substrate directions to help with driving the crystal growth direction. In the optional process step 2012, the primary tool is cooled to a lower process temperature prior to graphene film deposition. In step 2014, a flow of HC process gas is directed into the PRC (under temperature and flow conditions that generate a graphene film on the substrate inside the primary tooling, and in particular a substantial mono-layer graphene film). If the optional cooling step 2012 is used then the process temperature in step 2014 is similar to the end temperature of the step 2010.

The combination of high temperature annealing and controlled cooling prior to graphene growth for CVD Synthesis both improves the grain size of the substrate and reduces the number of voids in the graphene film caused by catalytically-active seed particles etching the graphene film during subsequent processing. It is believed that at lower process temperatures, fewer seed particles are able to catalytically etch the graphene film. In one embodiment of this invention, during process step 2014, no H₂ gas was flown into the process chamber. As our experiments showed, with a SEB 70, despite only 25 sccm of CH₄ and no H₂ gas (i.e., H₂/CH₄=0), and a process tube having a 5″ diameter, good quality monolayer graphene film was obtained with Cu grain sizes up to the cm range, and graphene grains >50 μm (using the same foil as shown in FIG. 7) with a cool down step 2012 having a linear ramp from 1080° C. to 950° C. over a period of 15 minutes. This is in contrast to the prior art where typically a ratio of H2/CH4=3 to 2000 is needed to obtain reasonable quality of monolayer graphene film on Cu foil. Another test experiment using only H₂ and no CH₄ resulted in no graphene film growth.

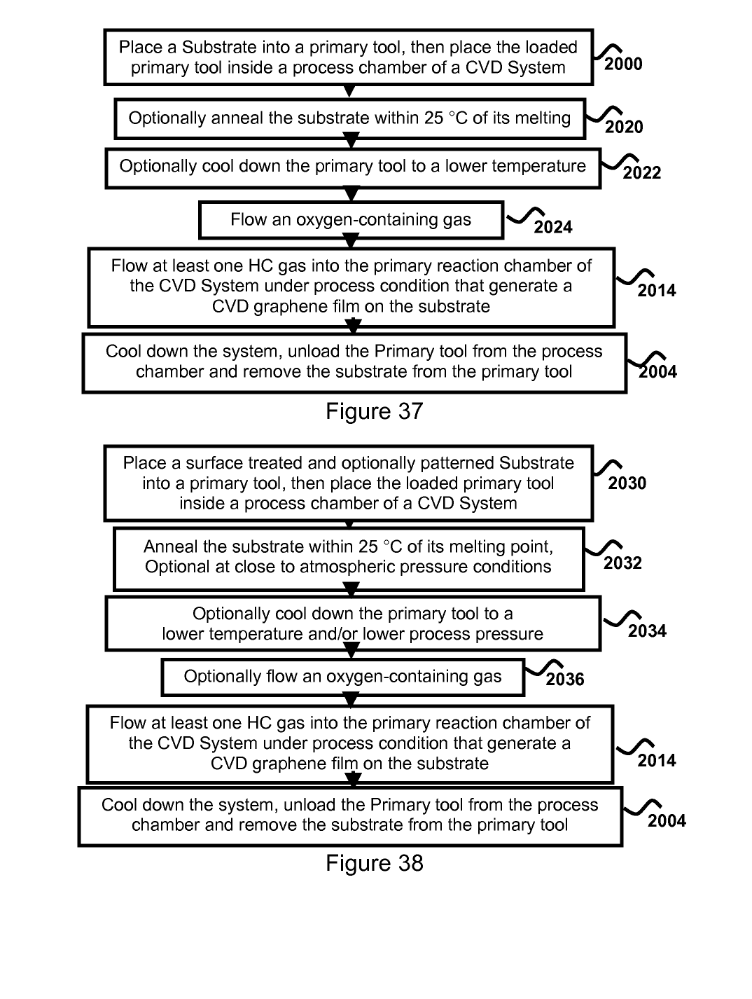

FIG. 37 outlines a method for CVD synthesis of graphene films in accordance with this invention that enables the growth of larger size graphene grains on a substrate, in particular Cu film and foil substrates. This is achieved by optionally loading a substrate in the primary tool that has its top surface layer removed prior to its insertion into the primary tool. For example, a 2-10 μm thick surface layer can be removed from the substrate with electro-polishing and/or chemical etching. As a result, many material impurities (that cause graphene grain seeds) impregnated into the top surface of the Cu foil by the rolling process used to manufacture the thin Cu foils are removed. In the optional process step 2020, the substrate is high temperature annealed, preferably to within 25° C. or less of its melting point, to increase the grain size of the substrate and to drive most of the impurities in the bulk material to the surface. An optional cool down process step 2022 is available as needed. In the process step 2024, an oxygen-containing gas is flown for a period of 1-30 minutes to deactivate the catalytically-active surface impurities. For example, Si impurities on the Cu foil surface are oxidized into primarily SiO₂ impurities, which appear to be less catalytically active than Si—Cu impurities at the desired process temperatures. This may be accomplished with O₂, H₂O, N₂O and/or other oxygen-containing gases. These steps allow for the deactivation of many surface impurities, and a reduction in the rate at which new graphene growth seeds are formed over time. H₂ may or may not be flown during step 2024 because the H₂ may slow down the deactivation process. Graphene growth step 2014 thus results in larger grains because the density of the graphene seed has been reduced. The primary tools of this invention thus provide an increased production rate of graphene by enabling the growth of graphene under process conditions (e.g., higher temperature, different gas ratios, pressures) that were not suitable in a practical manner for prior art systems.

FIG. 38 outlines a method for CVD synthesis of graphene films in accordance with this invention that enables the growth of both larger size Cu grains on the substrate (particularly Cu films and foils) and of graphene grains. This is achieved in process step 2030 by inserting a substrate in the primary tool that has at least one of its surface layer striped, e.g., by chemical etching, electropolishing, etc., and is optionally patterned with graphene seed growth sites. In annealing process step 2032, the substrate is annealed close to its melting point, and optionally close to atmospheric process conditions prior to graphene growth. Depending on the chosen graphene CVD Synthesis, the process temperature and/or process pressure can be lowered subsequently in the optional process step 2034. Again, an optional oxygen exposure process step 2034 can be used to further reduce the active graphene seeds, and preferably not deactivating the optional patterned graphene seed sites, thereby enabling the growth of larger graphene grains in process step 2014. The larger Cu grains, and larger graphene grains enable the manufacture of graphene films with higher material properties in a more practical, scalable and cost-reduced manner than possible with prior art solutions, and in a more usable format for many electronic graphene applications.

While only selective embodiments of this invention have been discussed above, it should be understood that combinations of the above mentioned embodiments, as well as obvious modifications thereof as easily understood by the skilled in the arts are therefore intended to be included in this disclosure.

What is claimed is:

1. A chemical vapor deposition system for synthesizing a two-dimensional film, comprising:
a) a primary reaction chamber;
b) a gas delivery and exhaust system for delivering and exhausting at least one process gas to and from said primary reaction chamber;
c) a heating system for heating said primary reaction chamber; and
d) a primary tool located within said primary reaction chamber, said primary tool including a support plate, said support plate defining a flat planar surface for supporting a substrate thereon, said flat planar surface being exposed to said primary reaction chamber and said process gas flowing therethrough, said support plate being formed from a process compatible inert material having substantial non-wetting material properties when heated near the melting point of said substrate.

2. The system according to claim 1, wherein said support plate is formed from a material selected from the group consisting of graphite, high purity graphite, pyrolytic graphite, graphite which has been subjected to a post-machining baking process, boron nitrite, and carbon-coated quartz.

3. A method for synthesizing a two-dimensional film, the method comprising the steps of:
a) providing a support plate defining a flat planar surface;
b) loading a substrate onto said flat planar surface of said support plate to provide a loaded support plate;
c) positioning said loaded support plate into the primary reaction chamber of a chemical vapor deposition synthesis system;
d) synthesizing a few layer thick film on the surface of said substrate by chemical vapor deposition, said support plate being substantially inert and having substantial non-wetting material properties when heated near the melting point of said substrate;
e) removing said loaded support plate from the primary reaction chamber after completion of said synthesis; and
f) offloading said substrate from said support plate.

4. The method according to claim 3, wherein said support plate is formed from a material selected from the group consisting of graphite, high purity graphite, pyrolytic graphite, graphite which has been subjected to a post-machining baking process, boron nitrite, and carbon-coated quartz.

5. A chemical vapor deposition system for synthesizing a two-dimensional film, comprising:
a) a primary reaction chamber;
b) a gas delivery and exhaust system for delivering and exhausting at least one process gas to and from said primary reaction chamber;
c) a heating system for heating said primary reaction chamber; and
d) a primary tool located within said primary reaction chamber, said primary tool defining a secondary reaction chamber, said primary and secondary reaction chambers communicating via a quasi-gas-tight seal, said primary tool including a short enclosure box for substantially enclosing and supporting a substrate, said box including a support plate defining a support area, said box further including a removable lid sized and configured to contact said support plate about the periphery of said support area to form said quasi-gas-tight seal between said box and said lid whereby said substrate is substantially enclosed therebetween.

6. The system according to claim 5, wherein said lid defines an inside surface, and wherein said box includes a liner covering at least a portion of said inside surface.

7. The system according to claim 6, wherein said substrate and said liner are formed of the same material.

8. The system according to claim 5, wherein said support plate and said lid are manufactured from one or more materials selected from the group consisting of carbon, graphite, pyrolytic graphite, exfoliated graphite sheets, graphene sheets, carbon-carbon composite, pyrolized carbon binder glue, ultra-high purity graphite, purified graphite, graphite which has been subjected to a post-machining baking process, SiC, carbon-coated quartz, quartz, boron nitrate, sapphire, SiO2, Al₂O₃-based ceramic, ZrO₂ ceramic, and high temperature ceramic.

9. The system according to claim 5, wherein said box includes a self-supporting liner sized to cover said substrate and rest against said plate about the periphery of said substrate, and wherein said lid is sized to encloses said liner when positioned on said plate.

10. The system according to claim 9, wherein said substrate and said liner are formed of the same material.

11. The system according to claim 5, wherein said box includes a gas port to provide increased exchange of gas flow between said primary and secondary chambers.

12. The system according to claim 5, wherein said plate includes a groove formed about the periphery thereof, said groove sized and located to receive said lid.

13. The system according to claim 5, wherein said plate includes locating features formed therein to facilitate reproducible placement of said primary tool within said primary reaction chamber.

14. A method for synthesizing a two-dimensional film, the method comprising the steps of:
a) providing a support plate and a lid, both said plate and said lid being formed from a process compatible inert material;
b) loading a substrate onto said support plate to provide a loaded support plate;
c) covering said loaded support plate with said lid to provide a loaded short enclosure box, said lid being sized and configured to contact said plate about the periphery of said substrate, said plate and said lid forming a quasi-gas-tight seal therebetween;
c) positioning said box into the primary reaction chamber of a chemical vapor deposition synthesis system;
d) synthesizing a few layer thick film on the surface of said substrate by chemical vapor deposition;
e) removing said box from the primary reaction chamber after completion of said synthesis;
f) removing said lid from said box; and
g) offloading said substrate from said support plate.

15. The method according to claim 14, wherein said support plate and said lid are manufactured from one or more materials selected from the group consisting of carbon, graphite, pyrolytic graphite, exfoliated graphite sheets, graphene sheets, carbon-carbon composite, pyrolized carbon binder glue, ultra-high purity graphite, purified graphite, graphite which has been subjected to a post-machining baking process, SiC, carbon-coated quartz, quartz, boron nitrate, sapphire, SiO2, Al₂O₃-based ceramic, ZrO₂ ceramic, and high temperature ceramic.

16. The method according to claim 14, further comprising the step of annealing said substrate at a temperature within 20° C. of the melting point of said substrate, said annealing step being performed prior to said synthesizing step.

17. The method according to claim 16, further comprising the step of cooling said primary tool after said annealing and prior to said synthesis.

18. The method according to claim 14, further comprising the step of loading a non-melting substrate wetting material onto said support plate before loading of said substrate thereon, and wherein said deposition occurs at or above the melting point of said substrate thus providing a liquid catalytically-active film that wets said wetting material for the synthesis of said few atom thick film.

19. The method according to claim 18, wherein said wetting material is formed of tungsten, and said substrate is either a Copper film deposited onto a tungsten surface or a Copper foil loaded onto a tungsten foil.

20. The method according to claim 14, wherein the heating of said substrate prior to said synthesizing step is performed at or near atmospheric pressure.
